(19) United States
(12) Patent Application Publication
(10) Pub. No.: US 2014/0302646 A1
(43) Pub. Date: Oct. 9, 2014

(54) METHOD OF MANUFACTURING SEMICONDUCTOR DEVICE

(71) Applicant: Renesas Electronics Corporation, Kawasaki-shi (JP)

(72) Inventors: Yuichi Hirano, Kanagawa (JP); Tatsuyoshi Mihara, Kanagawa (JP); Keisuke Tsukamoto, Kanagawa (JP)

(73) Assignee: Renesas Electronics Corporation, Kawasaki-shi (JP)

(21) Appl. No.: 14/244,952

(22) Filed: Apr. 4, 2014

(30) Foreign Application Priority Data
Apr. 8, 2013 (JP) 2013-080783

(51) Int. Cl. H01L 21/28; H01L 21/8234

(52) U.S. Cl. CPC H01L 21/28008; H01L 21/823418
USPC 438/197; 438/597

(57) ABSTRACT

A performance and reliability of a semiconductor device are improved. On a semiconductor substrate, a gate electrode for a first MISFET and a dummy gate electrode for a second MISFET are formed, and then, an insulating film is partially formed on the gate electrode. Then, on the semiconductor substrate, an insulating film is formed so as to cover the dummy gate electrode, the gate electrode and other insulating film. Then, the dummy gate electrode is exposed by polishing the insulating film. In this polishing, the insulating film is polished under a condition that a polishing speed of the other insulating film is smaller than a polishing speed of the insulating film. Then, after the dummy gate electrode is removed, the gate electrode for the second MISFET is formed in a region where the dummy gate electrode has been removed.

### CROSS-REFERENCE TO RELATED APPLICATION

The present application claims priority from Japanese Patent Application No. 2013-080783 filed on Apr. 8, 2013, the content of which is hereby incorporated by reference into this application.

### TECHNICAL FIELD OF THE INVENTION

The present invention relates to a method of manufacturing a semiconductor device, and can be preferably used for, for example, a method of manufacturing a semiconductor device equipped with a MISFET.

### BACKGROUND

The semiconductor device equipped with the MISFET can be manufactured by forming gate electrode on a semiconductor substrate, and then, forming source and drain regions on the semiconductor substrate and forming an interlayer insulating film so as to cover the gate electrode, and further, forming a multilayer wiring structure.

In addition, a dummy gate electrode is formed on the semiconductor substrate, and then, the source and drain regions are formed on the semiconductor substrate, and the interlayer insulating film is formed so as to cover this dummy gate electrode. Then, by polishing this interlayer insulating film so as to expose the dummy gate electrode therefrom, removing this dummy gate electrode, and replacing this part with another gate electrode, and then, forming the multilayer wiring structure, the semiconductor device equipped with the MISFET can be manufactured.

Japanese Patent Application Laid-Open Publication No. H07-245306 (Patent Document 1) describes a technique relating to a film flattening method in a semiconductor device.

Japanese Patent Application Laid-Open Publication No. 2009-239302 (Patent Document 2) describes a technique of suppressing dishing phenomena.

Japanese Patent Application Laid-Open Publication No. 2007-258463 (Patent Document 3) describes a technique of suppressing dishing phenomena.

### SUMMARY

Also in the semiconductor device having the MISFET, improvement of its performance is desired as much as possible. Alternatively, improvement of a manufacturing yield of the semiconductor device is desired. Alternatively, the improvement of the performance of the semiconductor device and the improvement of the manufacturing yield of the semiconductor device are desired.

Other problems and novel characteristics will be apparent from the description of the present specification and the accompanying drawings.

According to an embodiment, a first gate electrode for a first MISFET and a dummy gate electrode for a second MISFET are formed on a semiconductor substrate, and then, a first film is partially formed on the first gate electrode. Then, an insulating film is formed on the semiconductor substrate so as to cover the first gate electrode, the dummy gate electrode, and the first film, and then, the insulating film is polished, so that the dummy gate electrode is exposed. In this polishing, the insulating film is polished under such a condition that a polishing speed of the first film is smaller than a polishing speed of the insulating film. Then, the dummy gate electrode is removed, and then, a second gate electrode for the second MISFET is formed in a trench which is a region where the dummy gate electrode has been removed.

According to an embodiment, the performance of the semiconductor device can be improved.

Alternatively, the manufacturing yield of the semiconductor device can be improved.

Alternatively, the performance of the semiconductor device and the manufacturing yield of the semiconductor device can be improved.

### BRIEF DESCRIPTIONS OF THE DRAWINGS

FIG. 1 is a process flowchart illustrating a part of a manufacturing process of a semiconductor device according to an embodiment;

FIG. 2 is a process flowchart illustrating a part of the manufacturing process of the semiconductor device according to an embodiment;

FIG. 3 is a process flowchart illustrating a part of the manufacturing process of the semiconductor device according to an embodiment;

FIG. 4 is a cross-sectional view of a principal part in the manufacturing process of the semiconductor device of the embodiment;

FIG. 5 is a cross-sectional view of a principal part in the manufacturing process of the semiconductor device as the same as that of FIG. 4;

FIG. 6 is a cross-sectional view of a principal part in the manufacturing process of the semiconductor device, continued from FIG. 4;

FIG. 7 is a cross-sectional view of a principal part in the manufacturing process of the semiconductor device as the same as that of FIG. 6;

FIG. 8 is a cross-sectional view of a principal part in the manufacturing process of the semiconductor device, continued from FIG. 6;

FIG. 9 is a cross-sectional view of a principal part in the manufacturing process of the semiconductor device as the same as that of FIG. 8;

FIG. 10 is a cross-sectional view of a principal part in the manufacturing process of the semiconductor device, continued from FIG. 8;

FIG. 11 is a cross-sectional view of a principal part in the manufacturing process of the semiconductor device as the same as that of FIG. 10;

FIG. 12 is a cross-sectional view of a principal part in the manufacturing process of the semiconductor device, continued from FIG. 10;

FIG. 13 is a cross-sectional view of a principal part in the manufacturing process of the semiconductor device as the same as that of FIG. 12;

FIG. 14 is a cross-sectional view of a principal part in the manufacturing process of the semiconductor device, continued from FIG. 12;

FIG. 15 is a cross-sectional view of a principal part in the manufacturing process of the semiconductor device as the same as that of FIG. 14;

FIG. 16 is a cross-sectional view of a principal part in the manufacturing process of the semiconductor device, continued from FIG. 14;

FIG. 17 is a cross-sectional view of a principal part in the manufacturing process of the semiconductor device as the same as that of FIG. 16;

FIG. 18 is a cross-sectional view of a principal part in the manufacturing process of the semiconductor device, continued from FIG. 16;

FIG. 19 is a cross-sectional view of a principal part in the manufacturing process of the semiconductor device as the same as that of FIG. 18;

FIG. 20 is a cross-sectional view of a principal part in the manufacturing process of the semiconductor device, continued from FIG. 18;

FIG. 21 is a cross-sectional view of a principal part in the manufacturing process of the semiconductor device as the same as that of FIG. 20;

FIG. 22 is a cross-sectional view of a principal part in the manufacturing process of the semiconductor device, continued from FIG. 20;

FIG. 23 is a cross-sectional view of a principal part in the manufacturing process of the semiconductor device as the same as that of FIG. 22;

FIG. 24 is a cross-sectional view of a principal part in the manufacturing process of the semiconductor device, continued from FIG. 22;

FIG. 25 is a cross-sectional view of a principal part in the manufacturing process of the semiconductor device as the same as that of FIG. 24;

FIG. 26 is a cross-sectional view of a principal part in the manufacturing process of the semiconductor device, continued from FIG. 24;

FIG. 27 is a cross-sectional view of a principal part in the manufacturing process of the semiconductor device as the same as that of FIG. 26;

FIG. 28 is a cross-sectional view of a principal part in the manufacturing process of the semiconductor device, continued from FIG. 26;

FIG. 29 is a cross-sectional view of a principal part in the manufacturing process of the semiconductor device as the same as that of FIG. 28;

FIG. 30 is a cross-sectional view of a principal part in the manufacturing process of the semiconductor device, continued from FIG. 28;

FIG. 31 is a cross-sectional view of a principal part in the manufacturing process of the semiconductor device as the same as that of FIG. 30;

FIG. 32 is a cross-sectional view of a principal part in the manufacturing process of the semiconductor device, continued from FIG. 30;

FIG. 33 is a cross-sectional view of a principal part in the manufacturing process of the semiconductor device as the same as that of FIG. 32;

FIG. 34 is a cross-sectional view of a principal part in the manufacturing process of the semiconductor device, continued from FIG. 32;

FIG. 35 is a cross-sectional view of a principal part in the manufacturing process of the semiconductor device as the same as that of FIG. 34;

FIG. 36 is a cross-sectional view of a principal part in the manufacturing process of the semiconductor device, continued from FIG. 34;

FIG. 37 is a cross-sectional view of a principal part in the manufacturing process of the semiconductor device as the same as that of FIG. 36;

FIG. 38 is a cross-sectional view of a principal part in the manufacturing process of the semiconductor device, continued from FIG. 36;

FIG. 39 is a cross-sectional view of a principal part in the manufacturing process of the semiconductor device as the same as that of FIG. 38;

FIG. 40 is a cross-sectional view of a principal part in the manufacturing process of the semiconductor device, continued from FIG. 36;

FIG. 41 is a cross-sectional view of a principal part in the manufacturing process of the semiconductor device as the same as that of FIG. 40;

FIG. 42 is a cross-sectional view of a principal part in the manufacturing process of the semiconductor device, continued from FIG. 38;

FIG. 43 is a cross-sectional view of a principal part in the manufacturing process of the semiconductor device as the same as that of FIG. 42;

FIG. 44 is a cross-sectional view of a principal part in the manufacturing process of the semiconductor device, continued from FIG. 42;

FIG. 45 is a cross-sectional view of a principal part in the manufacturing process of the semiconductor device as the same as that of FIG. 44;

FIG. 46 is a cross-sectional view of a principal part in the manufacturing process of the semiconductor device, continued from FIG. 44;

FIG. 47 is a cross-sectional view of a principal part in the manufacturing process of the semiconductor device as the same as that of FIG. 46;

FIG. 48 is a cross-sectional view of a principal part in the manufacturing process of the semiconductor device, continued from FIG. 46;

FIG. 49 is a cross-sectional view of a principal part in the manufacturing process of the semiconductor device as the same as that of FIG. 48;

FIG. 50 is a cross-sectional view of a principal part in the manufacturing process of the semiconductor device, continued from FIG. 48;

FIG. 51 is a cross-sectional view of a principal part in the manufacturing process of the semiconductor device as the same as that of FIG. 50;

FIG. 52 is a cross-sectional view of a principal part in the manufacturing process of the semiconductor device, continued from FIG. 50;

FIG. 53 is a cross-sectional view of a principal part in the manufacturing process of the semiconductor device as the same as that of FIG. 52;

FIG. 54 is a cross-sectional view of a principal part in the manufacturing process of the semiconductor device, continued from FIG. 52;

FIG. 55 is a cross-sectional view of a principal part in the manufacturing process of the semiconductor device as the same as that of FIG. 54;

FIG. 56 is a cross-sectional view of a principal part in the manufacturing process of the semiconductor device, continued from FIG. 54;

FIG. 57 is a cross-sectional view of a principal part in the manufacturing process of the semiconductor device as the same as that of FIG. 56;

FIG. 58 is a cross-sectional view of a principal part in the manufacturing process of the semiconductor device, continued from FIG. 56;

FIG. 59 is a cross-sectional view of a principal part in the manufacturing process of the semiconductor device as the same as that of FIG. 58;

FIG. 60 is a cross-sectional view of a principal part of a semiconductor device according to an embodiment;

FIG. 61 is an equivalent circuit diagram of a memory cell;

FIG. 62 is a table illustrating an example of a voltage application condition to each part of a selection memory cell in “writing”, “deleting” and “reading”;

FIG. 63 is a cross-sectional view of a principal part in a manufacturing process of a semiconductor device of a studied example;

FIG. 64 is a cross-sectional view of a principal part in the manufacturing process of the semiconductor device as the same as that of FIG. 63;

FIG. 65 is a cross-sectional view of a principal part in the manufacturing process of the semiconductor device, continued from FIG. 63;

FIG. 66 is a cross-sectional view of a principal part in the manufacturing process of the semiconductor device as the same as that of FIG. 65;

FIG. 67 is a cross-sectional view of a principal part in the manufacturing process of the semiconductor device, continued from FIG. 65;

FIG. 68 is a cross-sectional view of a principal part in the manufacturing process of the semiconductor device as the same as that of FIG. 67;

FIG. 69 is a cross-sectional view of a principal part in the manufacturing process of the semiconductor device, continued from FIG. 67;

FIG. 70 is a cross-sectional view of a principal part in the manufacturing process of the semiconductor device as the same as that of FIG. 69;

FIG. 71 is a cross-sectional view of a principal part in the manufacturing process of the semiconductor device, continued from FIG. 69;

FIG. 72 is a cross-sectional view of a principal part in the manufacturing process of the semiconductor device as the same as that of FIG. 71;

FIG. 73 is a cross-sectional view of a principal part of a semiconductor device of another embodiment;

FIG. 74 is a cross-sectional view of a principal part of a semiconductor device of another embodiment;

FIG. 75 is a cross-sectional view of a principal part of a semiconductor device of another embodiment;

FIG. 76 is a cross-sectional view of a principal part in a manufacturing process of the semiconductor device of another embodiment;

FIG. 77 is a cross-sectional view of a principal part in a manufacturing process of the semiconductor device of another embodiment;

FIG. 78 is a cross-sectional view of a principal part in a manufacturing process of the semiconductor device of another embodiment;

FIG. 79 is a cross-sectional view of a principal part in the manufacturing process of the semiconductor device, continued from FIG. 78;

FIG. 80 is a cross-sectional view of a principal part in the manufacturing process of the semiconductor device, continued from FIG. 79;

FIG. 81 is a cross-sectional view of a principal part in the manufacturing process of the semiconductor device, continued from FIG. 80;

FIG. 82 is a cross-sectional view of a principal part in the manufacturing process of the semiconductor device, continued from FIG. 81; and

FIG. 83 is a cross-sectional view of a principal part in the manufacturing process of the semiconductor device, continued from FIG. 82.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments will be described in detail based on the accompanying drawings. Note that components having the same function are denoted by the same reference symbols throughout all drawings for describing the embodiments, and the repetitive description thereof will be omitted. In addition, the description of the same or similar portions is not repeated in principle unless particularly required in the following embodiments.

Moreover, in the drawings used in the embodiments, hatching may be omitted even in a cross-sectional view so as to make the drawings easy to see. Also, hatching may be used even in a plan view so as to make the drawings easy to see.

### First Embodiment

<Regarding Manufacturing Process of Semiconductor Device>

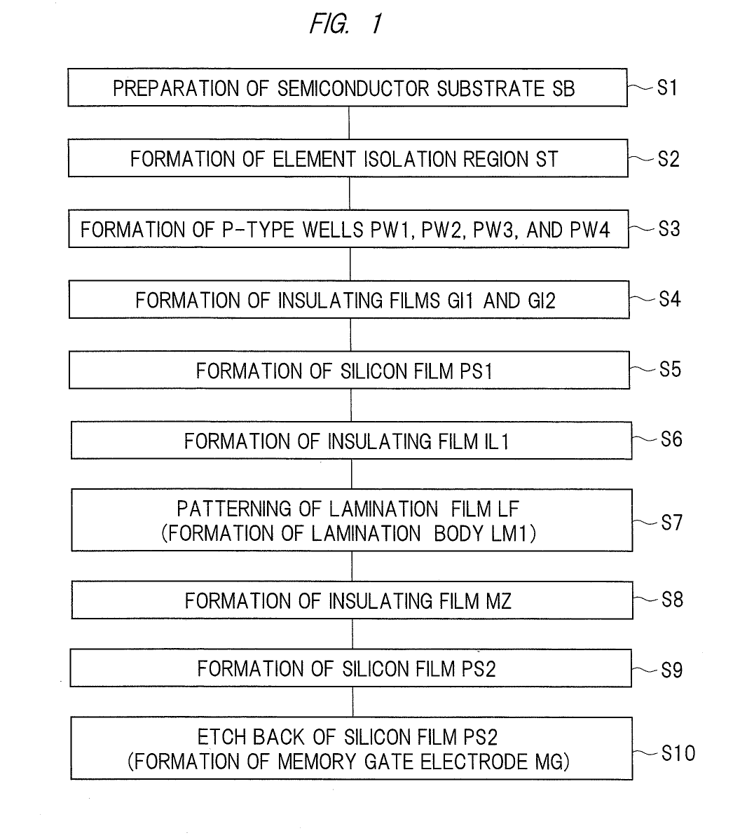

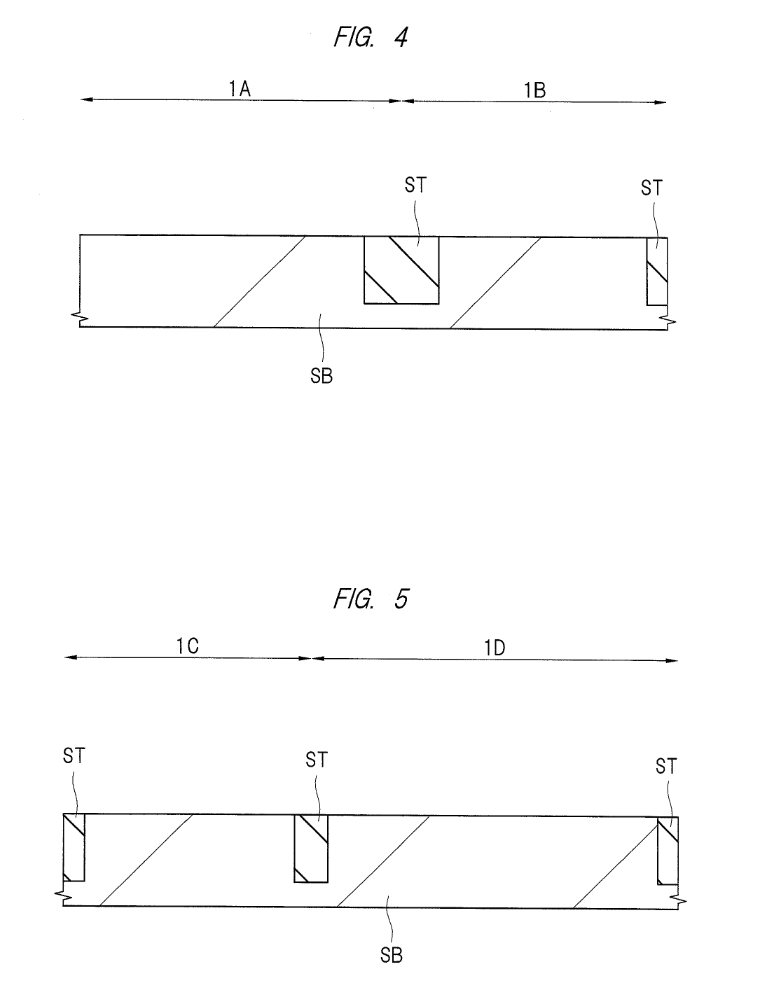

A manufacturing process of a semiconductor device of the present embodiment will be explained with reference to the drawings. Each of FIGS. 1 to 3 is a process flowchart illustrating a part of the manufacturing process of the semiconductor device of the embodiment. Each of FIGS. 4 to 59 is a cross-sectional view of a principal part in the manufacturing process of the semiconductor device of the embodiment.

Note that each of FIGS. 4, 6, 8, 10, 12, 14, 16, 18, 20, 22, 24, 26, 28, 30, 32, 34, 36, 38, 40, 42, 44, 46, 48, 50, 52, 54, 56, and 58 illustrates a cross-sectional view of a principal part of a memory formation region 1A and a metal gate transistor formation region 1B. Also, each of FIGS. 5, 7, 9, 11, 13, 15, 17, 19, 21, 23, 25, 27, 29, 31, 33, 35, 37, 39, 41, 43, 45, 47, 49, 51, 53, 55, 57, and 59 illustrates a cross-sectional view of a principal part of a low breakdown voltage MISFET formation region 1C and a high breakdown voltage MISFET formation region 1D.

First, as illustrated in FIGS. 4 and 5, a semiconductor substrate (semiconductor wafer) SB made of, for example, p-type single crystal silicon or others having a specific resistance of about 1 to 10 Ωcm is prepared (provided) (Step S1 of FIG. 1).

The semiconductor substrate SB has: a memory formation region 1A which is a region where a memory cell of a nonvolatile memory is formed; a metal gate transistor formation region 1B which is a region where the MISFET Q1 having a metal gate electrode is formed; a low breakdown voltage MISFET formation region 1C which is a region where the MISFET Q2 having a low breakdown voltage is formed; and a high breakdown voltage MISFET formation region 1D which is a region where the MISFET Q3 having a high breakdown voltage is formed. The memory formation region 1A, the metal gate transistor formation region 1B, the low breakdown voltage MISFET formation region 1C, and the high breakdown voltage MISFET formation region 1D correspond to regions on a principal surface of the same semiconductor substrate SB which are different from each other. Therefore, FIGS. 4 and 5 illustrate different regions on the same semiconductor substrate SB. In addition, for simply understanding, FIG. 4 illustrates the memory formation region 1A and the metal gate transistor formation region 1B so that they are adjacent to each other, and FIG. 5 illustrates the low breakdown voltage MISFET formation region 1C and the high breakdown voltage MISFET formation region 1D so that they are adjacent to each other. However, it is not required to arrange them so that they are adjacent to each other. A practical positional relation among the memory formation region 1A, the metal gate transistor formation region 1B, the low breakdown voltage MISFET formation region 1C, and the high breakdown voltage MISFET formation region 1D in the semiconductor substrate SB can be modified if needed. Note that the MISFET having the metal gate electrode is referred to as a metal gate transistor below. Therefore, the MISFET Q1 is the metal gate transistor.

Each of MISFETs Q1, Q2 and Q3 is the MISFET for a peripheral circuit. Here, the peripheral circuit is a circuit except for a nonvolatile memory, and is, for example, a processor such as a CPU, a control circuit, a sense amplifier, a column decoder, a row decoder, an input/output circuit, or others. In addition, in the principal surface of the semiconductor substrate SB, a region where the peripheral circuit is formed is referred to as a peripheral circuit formation region below. The peripheral circuit formation regions include the metal gate transistor formation region 1B, the low breakdown voltage MISFET formation region 1C, and the high breakdown voltage MISFET formation region 1D.

Note that an operating voltage of the MISFET Q3 having a high breakdown voltage is higher than an operating voltage of the MISFET Q2 having a low breakdown voltage. In other words, the MISFET Q3 having a high breakdown voltage is the MISFET operated with a first source voltage, and the MISFET Q2 having a low breakdown voltage is the MISFET operated with a second source voltage lower than this first source voltage. As described later, a thickness of a gate insulating film of the MISFET Q3 having a high breakdown voltage is thicker than a thickness of a gate insulating film of the MISFET Q2 having a low breakdown voltage. In addition, as described later, a gate length of the gate electrode of the MISFET Q3 having a high breakdown voltage is larger than a gate length of the gate electrode of the MISFET Q2, and larger than a gate length of the gate electrode of the MISFET Q1.

In addition, an operating voltage of the MISFET Q3 having a high breakdown voltage is higher than an operating voltage of the MISFET Q1 having a metal gate electrode. In other words, the MISFET Q3 having a high breakdown voltage is the MISFET operated with the first source voltage, and the MISFET Q1 having a metal gate electrode is the MISFET operated with a third source voltage lower than this first source voltage. An operating voltage of the MISFET Q1 having a metal gate electrode is the same as or different from an operating voltage of the MISFET Q2 having a low breakdown voltage.

In other words, the above-described second source voltage and the above-described third source voltage are the same as or different from each other.

Note that the present embodiment describes a case of an n-channel type MISFET as each MISFET. However, a p-channel type MISFET can be formed with an opposite conductivity type. In addition, both of the n-channel type MISFET and the p-channel type MISFET can be also formed.

Next, on the principal surface of the semiconductor substrate SB, an element isolation region (inter-element isolation insulating region) ST for specifying (defining) an active region is formed (Step S2 of FIG. 1).

The element isolation region ST is made of an insulator such as silicon oxide, and can be formed by, for example, a STI (Shallow Trench Isolation) method, a LOCOS (Local Oxidization of Silicon) method, or others. For example, the element isolation region ST can be formed by forming a trench for the element isolation in the principal surface of the semiconductor substrate SB, and then, embedding, for example, the insulating film made of the silicon oxide in this trench for the element isolation. More specifically, the trench for the element isolation is formed in the principal surface of the semiconductor substrate SB, and then, an insulating film for forming the element isolation region (for example, silicon oxide film) is formed on the semiconductor substrate SB so as to fill this trench for the element isolation. Then, by removing the insulating film (insulating film for forming the element isolation region) outside the trench for the element isolation, the element isolation region ST made of the insulating film embedded into the trench for the element isolation can be formed.

The active region of the semiconductor substrate SB is defined by the element isolation region ST. In the metal gate transistor formation region 1B, the MISFET (Metal Insulator Semiconductor Field Effect Transistor) Q1 is formed as described later in the active region defined by the element isolation region ST. In addition, in the low breakdown voltage MISFET formation region 1C, the MISFET (Metal Insulator Semiconductor Field Effect Transistor) Q2 is formed as described later in the active region defined by the element isolation region ST. In addition, in the high breakdown voltage MISFET formation region 1D, the MISFET (Metal Insulator Semiconductor Field Effect Transistor) Q3 is formed as described later in the active region defined by the element isolation region ST. In addition, in the memory formation region 1A, the memory cell of the nonvolatile memory (nonvolatile storage element, flash memory) is formed as described later in the active region defined by the element isolation region ST.

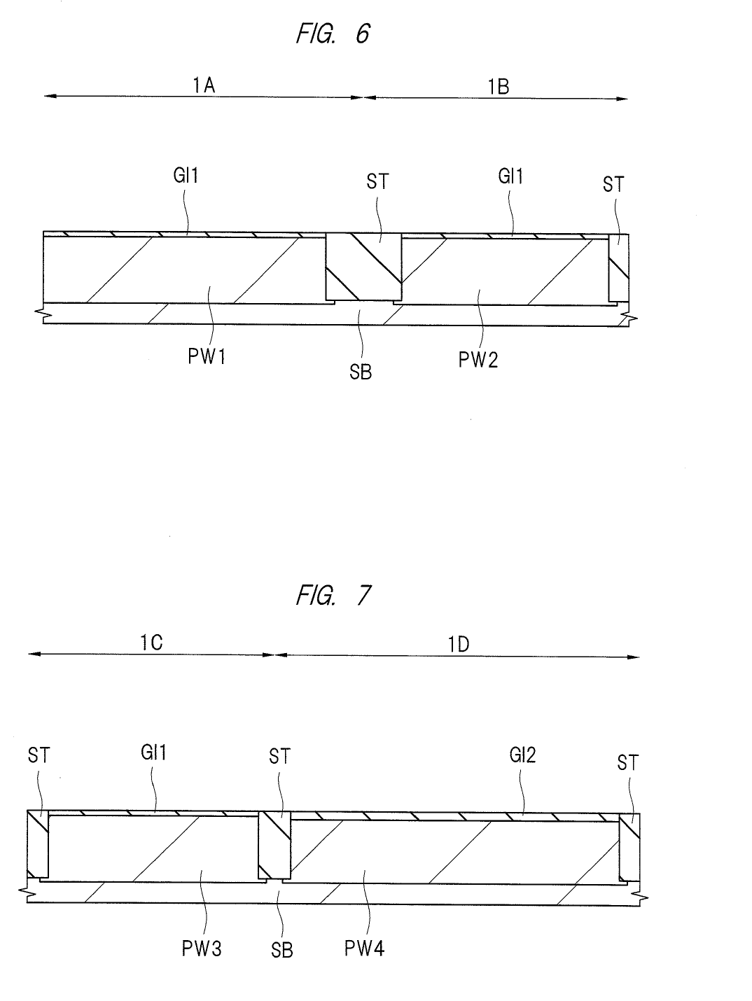

Next, as illustrated in FIGS. 6 and 7, p-type wells (p-type semiconductor regions) PW1, PW2, PW3, and PW4 are formed on the semiconductor substrate SB by using an ion implantation method or others (Step S3 of FIG. 1).

The p-type well PW1 is formed on the semiconductor substrate SB of the memory formation region 1A, the p-type well PW2 is formed on the semiconductor substrate SB of the metal gate transistor formation region 1B, the p-type well PW3 is formed on the semiconductor substrate SB of the low breakdown voltage MISFET formation region 1C, and the p-type well PW4 is formed on the semiconductor substrate SB of the high breakdown voltage MISFET formation region 1D. The p-type wells PW1, PW2, PW3 and PW4 can be formed by ion-implanting a p-type impurity such as boron (B) into the semiconductor substrate SB or others. The p-type wells PW1, PW2, PW3 and PW4 are formed from the principal surface of the semiconductor substrate SB down to a predetermined depth.

The number of processes can be reduced if the same ion implantation process is performed for the ion implantation for forming the p-type well PW1, the ion implantation for forming the p-type well PW2, the ion implantation for forming the p-type well PW3, and the ion implantation for forming the p-type well PW4. However, different ion implantation processes may be performed for them.

Next, on the principal surface (surfaces of the p-type wells PW1, PW2, PW3 and PW4) of the semiconductor substrate SB, insulating films GI1 and GI2 for the gate insulating film are formed (Step S4 of FIG. 1).

The insulating film GI1 is formed on the surfaces (that is, the surfaces of the p-type wells PW1, PW2 and PW3) of the semiconductor substrate SB in the memory formation region 1A, the metal gate transistor formation region 1B and the low breakdown voltage MISFET formation region 1C. On the other hand, the insulating film GI2 is formed on the surface (that is, the surface of the p-type well PW4) of the semiconductor substrate SB in the high breakdown voltage MISFET formation region 1D.

A formation process of the insulating films GI1 and GI2 for the gate insulating film of Step S4 can be performed as, for example, follows.

First, after cleaning (washing) the surface of the semiconductor substrate SB (the p-type wells PW1, PW2, PW3 and PW4) by, for example, wet etching using fluoric acid (HF) solution or others, the insulating film GI2 made of the silicon oxide film or others is formed on the surface (including the surfaces of the p-type wells PW1, PW2, PW3 and PW4) of the semiconductor substrate SB.

The insulating film GI2 is an insulating film for the gate insulating film of the MISFET, which is formed in the high breakdown voltage MISFET formation region 1D. The insulating film GI2 can be formed by using, for example, a thermal oxidation method. However, the insulating film GI2 can be formed also by forming a thermal oxidization film, and then, depositing a CVD film (silicon oxide film formed by a CVD method) on the thermal oxidization film.

Next, by etching the insulating film GI2 by using a photoresist layer (not illustrated) formed by using a photolithography method as an etching mask, the insulating film GI2 in each of the memory formation region 1A, the metal gate transistor formation region 1B, and the low breakdown voltage MISFET formation region 1C is removed, and the insulating film GI2 in the high breakdown voltage MISFET formation region 1D is left.

Next, a silicon oxide film is formed on the principal surface of the semiconductor substrate SB by performing a thermal oxidation process on the semiconductor substrate SB. In this manner, the insulating film GI1 made of the silicon oxide film (the thermal oxidization film) is formed on the semiconductor substrate SB in the memory formation region 1A, the metal gate transistor formation region 1B, and the low breakdown voltage MISFET formation region 1C (that is, on the p-type wells PW1, PW2 and PW3), and besides, the insulating film GI2 in the high breakdown voltage MISFET formation region 1D is thickened. That is, the thickness of the insulating film GI2 in the high breakdown voltage MISFET formation region 1D is increased in the formation of the insulating film GI1. The thickness of the insulating film GI2 formed in the high breakdown voltage MISFET formation region 1D is thicker than the thicknesses of the insulating films GI1 formed in the memory formation region 1A, the metal gate transistor formation region 1B, and the low breakdown voltage MISFET formation region 1C.

In this way, the process of forming the insulating films GI1 and GI2 for the gate insulating film of Step S4 is performed so as to obtain a structure illustrated in FIGS. 6 and 7. This manner provides such a state that the insulating film GI1 is formed on the surface of the semiconductor substrate SB in the memory formation region 1A, the metal gate transistor formation region 1B and the low breakdown voltage MISFET formation region 1C (that is, on the surfaces of the p-type wells PW1, PW2 and PW3), and such a state that the insulating film GI2 is formed on the surface of the semiconductor substrate SB in the high breakdown voltage MISFET formation region 1D (that is, the surface of the p-type well PW4). At this time, the thickness of the insulating film GI2 is larger than the thickness of the insulating film GI1. As an example of the thicknesses of the insulating films GI1 and GI2 at this time, the thickness of the insulating film GI1 can be, for example, about 0.5 to 5 nm, and the thickness of the insulating film GI2 can be, for example, about 10 to 25 nm. On the element isolation region ST, the insulating films GI1 and GI2 may be formed, or may not be formed.

The thickness of the insulating film GI2 in the high breakdown voltage MISFET formation region 1D is larger than the thickness of the insulating film GI1 in the low breakdown voltage MISFET formation region 1C, and therefore, the thickness of the gate insulating film of the MISFET Q3 formed in the high breakdown voltage MISFET formation region 1D is larger than the thickness of the gate insulating film of the MISFET Q2 formed in the low breakdown voltage MISFET formation region 1C. Therefore, a breakdown voltage of the MISFET Q3 formed in the high breakdown voltage MISFET formation region 1D is higher than a breakdown voltage of the MISFET Q2 formed in the low breakdown voltage MISFET formation region 1C.

In addition, the thickness of the insulating film GI2 in the high breakdown voltage MISFET formation region 1D is larger than the thickness of the insulating film GI1 in the memory formation region 1A, and therefore, the thickness of the gate insulating film of the MISFET Q3 formed in the high breakdown voltage MISFET formation region 1D is larger than the thickness of the gate insulating film of the control transistor of the memory cell formed in the memory formation region 1A. Therefore, a breakdown voltage of the MISFET Q3 formed in the high breakdown voltage MISFET formation region 1D is higher than a breakdown voltage of the control transistor of the memory cell formed in the memory formation region 1A.

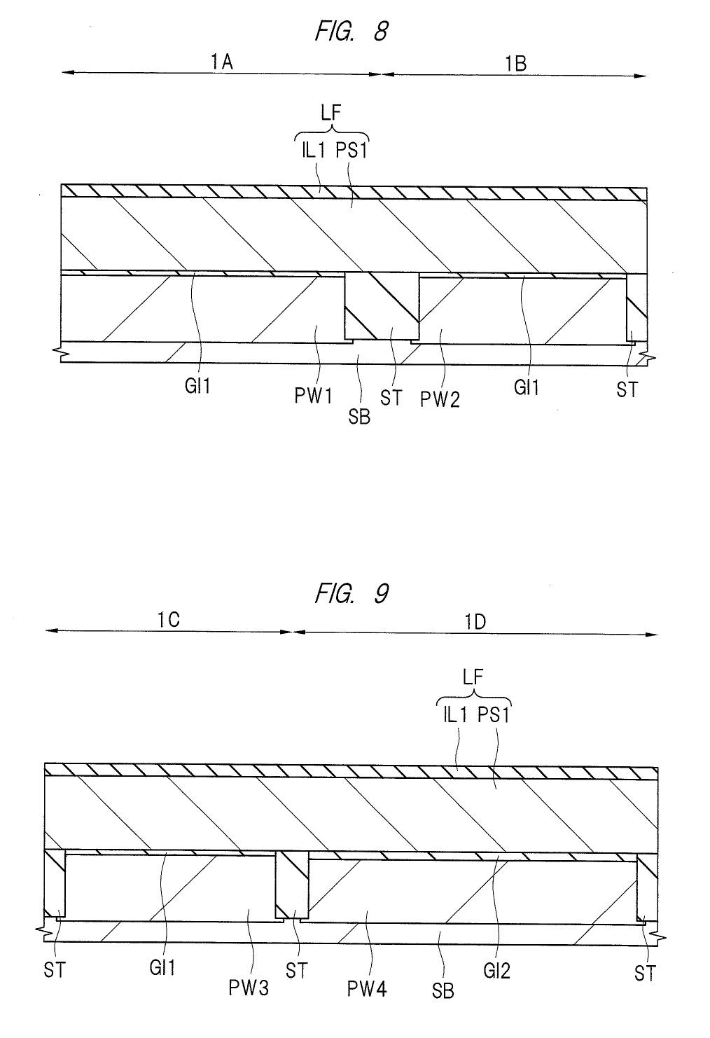

Next, as illustrated in FIGS. 8 and 9, a silicon film PS1 is formed (deposited) as a conductive film for forming the gate electrode on the principal surface (the whole principal surface) of the semiconductor substrate SB, that is, on the insulating films GI1 in the memory formation region 1A, in the metal gate transistor formation region 1B, and in the low breakdown voltage MISFET formation region 1C, and on the insulating film GI2 in the high breakdown voltage MISFET formation region 1D (Step S5 of FIG. 1).

The silicon film PS1 is a conductive film for forming a control gate electrode CG, a dummy gate electrode DG, a gate electrode GE1 and a gate electrode GE2 which are described later. That is, the silicon film PS1 serves as all of a conductive film for forming the below-described control gate electrode CG, a conductive film for forming the below-described dummy gate electrode DG, a conductive film for forming the below-described gate electrode GE1 and a conductive film for forming the below-described gate electrode GE2. Therefore, the below-described control gate electrode CG, the below-described dummy gate electrode DG, the below-described gate electrode GE1 and the below-described gate electrode GE2 are formed by the silicon film PS1.

The silicon film PS1 is made of a polycrystalline silicon film (poly-silicon film), and can be formed by using the CVD (Chemical Vapor Deposition) method or others. A deposited film thickness of the silicon film PS1 can be set to, for example, about 50 to 150 nm. The silicon film PS1 can be also formed by forming this as an amorphous silicon film at the time of film formation, and then, performing a thermal process to the amorphous silicon film so as to change into the polycrystalline silicon film.

In addition, the silicon film PS1 can be formed into a semiconductor film having a low resistance (into a doped poly-silicon film) by introducing an impurity at the time of the film formation, by ion-implanting an impurity after the film formation, or by others. The silicon film PS1 in the memory formation region 1A is preferably an n-type silicon film to which an n-type impurity such as phosphorus (P) or arsenic (As) is introduced.

The impurity can be also introduced by the ion implantation method after forming the silicon film PS1 as a non-doped (un-doped) silicon film. However, in that case, the impurity (here, n-type impurity) can be also selectively introduced to the silicon film PS1 in the memory formation region 1A. This can be performed as follows. That is, after forming the silicon film PS1, a photoresist pattern (not illustrated) is formed on the silicon film PS1 by using a photolithography method. Although not illustrated here, this photoresist pattern is formed so as to exposes the memory formation region 1A and so as to cover the metal gate transistor formation region 1B, the low breakdown voltage MISFET formation region 1C and the high breakdown voltage MISFET formation region 1D. Then, the silicon film PS1 of the memory formation region 1A is made into the n-type silicon film (doped poly-silicon film) by introducing the n-type impurity into the silicon film PS1 in the memory formation region 1A by using the ion implantation method or others using this photoresist pattern as a mask. That is, the n-type impurity is introduced into the silicon film PS1 in the memory formation region 1A, so that the silicon film PS1 in the memory formation region 1A is made into the n-type silicon film to which the n-type impurity is introduced. Then, the photoresist pattern is removed. When the n-type impurity is introduced into the silicon film PS1 in the memory formation region 1A by the ion implantation method, the impurity is not introduced into the silicon films PS1 in the metal gate transistor formation region 1B, the low breakdown voltage MISFET formation region 1C and the high breakdown voltage MISFET formation region 1D because the silicon film has been covered by the photoresist pattern.

Therefore, when the impurity is introduced into the silicon film PS1 in the memory formation region 1A by the ion implantation method after forming the silicon film PS1 as the non-doped silicon film, the silicon films PS1 in the metal gate transistor formation region 1B, the low breakdown voltage MISFET formation region 1C and the high breakdown voltage MISFET formation region 1D are left as the non-doped silicon films. However, in this case, an impurity is introduced into the silicon film PS1 by the ion implantation method at a later process (for example, after a below-described Step S12 but before a below-described Step S13), and therefore, the gate electrode GE1 and the gate electrode GE2 formed later are formed of a silicon film to which an impurity is introduced. In addition, since the dummy gate electrode DG formed later does not function as a gate electrode of a transistor, the impurity may or may not be introduced into the dummy gate electrode DG. Therefore, the impurity may or may not be introduced into the silicon film PS1 in the metal gate transistor formation region 1B.

Next, an insulating film IL1 is formed (deposited) on the principal surface (the whole principal surface) of the semiconductor substrate SB, that is, on the silicon film PS1 (Step S6 of FIG. 1).

The insulating film IL1 is an insulating film for forming below-described cap insulating films CP1, CP2, CP3 and CP4. The insulating film IL1 is made of, for example, a silicon nitride film or others, and can be formed by using the CVD method or others. A deposited film thickness of the insulating film IL1 can be set to, for example, about 10 to 50 nm. By performing Step S5 and S6, a laminated film LF including the silicon film PS1 and the insulating film IL1 on the silicon film PS1 is formed. Here, the laminated film LF is formed of the silicon film PS1 and the insulating film IL1 on the silicon film PS1.

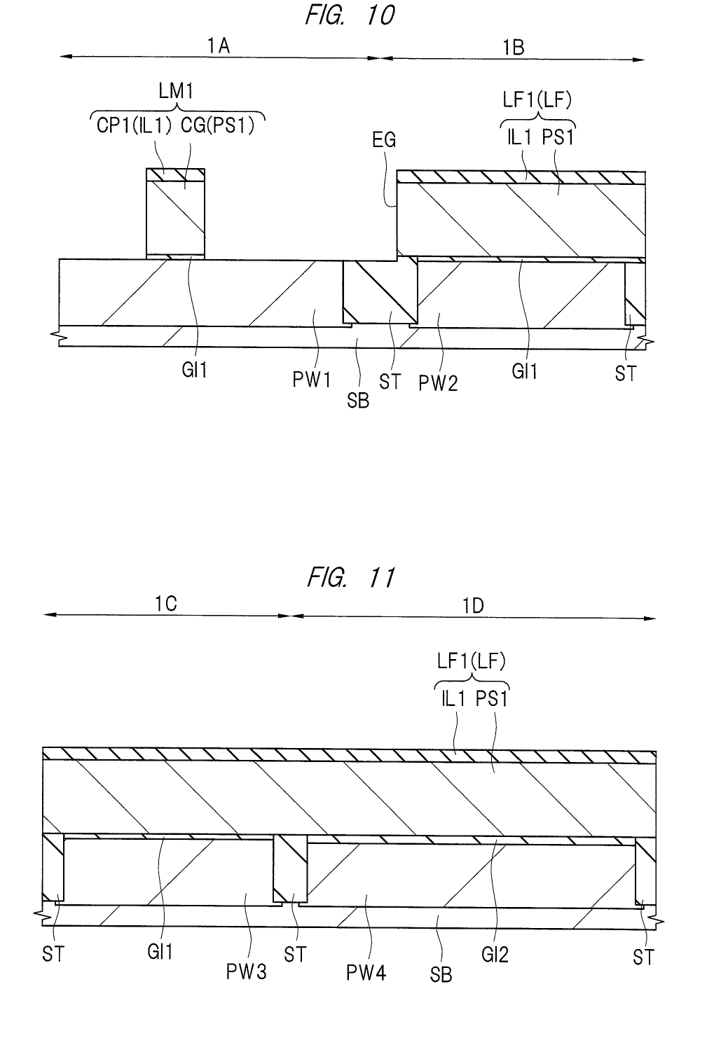

Next, as illustrated in FIGS. 10 and 11, the laminated film LF, that is, the insulating film IL1 and the silicon film PS1 are patterned by using a photolithography technique and an etching technique, so that a laminated body (laminated structure body) LM1 including the control gate electrode CG and a cap insulating film CP1 on the control gate electrode CG is formed in the memory formation region 1A (Step S7 of FIG. 1). Step S7 can be specifically performed as follows.

That is, first, a photoresist pattern is formed on the insulating film IL1 by using the photolithography method. This photoresist pattern is formed on a region where the control gate electrode CG is to be formed in the memory formation region 1A and a whole peripheral circuit formation region. Therefore, in the memory formation region, this photoresist pattern covers the silicon film PS1 in the region where the control gate electrode CG is to be formed, and exposes the silicon film PS1 in other region except for the region where the control gate electrode CG is to be formed. On the other hand, in the metal gate transistor formation region 1B, the low breakdown voltage MISFET formation region 1C and the high breakdown voltage MISFET formation region 1D, the whole silicon film PS1 is covered by this photoresist pattern. Then, the laminated film LF including the silicon film PS1 and the insulating film IL1 in the memory formation region 1A is etched (preferably, dry-etched) and patterned by using this photoresist pattern as an etching mask, and then, this photoresist pattern is removed. As illustrated in FIGS. 10 and 11, this manner forms the laminated body LM1 including the control gate electrode CG made of the patterned silicon film PS1 and the cap insulating film CP1 made of the patterned insulating film IL1.

In addition, as another embodiment, the laminated body LM1 can also be formed as follows. First, the same photoresist pattern as described above is formed on the insulating film IL1, and then, the insulating film IL1 is etched (preferably, dry-etched) and patterned by using this photoresist pattern as an etching mask, so that the cap insulating film CP1 made of the patterned insulating film IL1 is formed in the memory formation region 1A. After that, this photoresist pattern is removed, and then, the silicon film PS1 is etched (preferably, dry-etched) and patterned by using the insulating film IL1 including the cap insulating film CP1 as an etching mask (hard mask). In this manner, the laminated body LM1 including the control gate electrode CG made of the patterned silicon film PS1 and of the cap insulating film CP1 made of the patterned insulating film IL1 is formed.

The laminated body LM1 is formed of the control gate electrode CG and the cap insulating film CP1 on the control gate electrode CG, and is formed on the semiconductor substrate SB (p-type well PW1) in the memory formation region 1A via the insulating film GI1. The control gate electrode CG and the cap insulating film CP1 have the almost same planar shape as each other in a planar view, and overlaps with each other in the planar view.

Note that, when referring to “planar view” or “viewed in a plane”, a case in viewing along a plane parallel to the principal surface of the semiconductor substrate SB is described.

In addition, the photoresist pattern used for the patterning in Step S7 is selectively formed in the region where the control gate electrode CG is to be formed in the memory formation region 1A. Therefore, when Step S7 is performed, the silicon film PS1 and the insulating film IL1 in a portion except for a portion to be the laminated body LM1 are removed in the memory formation region 1A. On the other hand, in the peripheral circuit formation region, this photoresist pattern is formed on the whole peripheral circuit formation region. Therefore, even when Step S7 is performed, the laminated film LF including the silicon film PS1 and the insulating film IL1 on the silicon film PS1 is not removed, and therefore, is not patterned, and is left as it is in the peripheral circuit formation region including the metal gate transistor formation region 1B, the low breakdown voltage MISFET formation region 1C and the high breakdown voltage MISFET formation region 1D. The residual laminated film LF in the peripheral circuit formation region is referred to as a laminated film LF1 with denoting a symbol “LF1”. Therefore, the laminated film LF1 exists also in the metal gate transistor formation region 1B, the low breakdown voltage MISFET formation region 1C and the high breakdown voltage MISFET formation region 1D.

It is preferred to position a side surface (sidewall) EG of the laminated film LF1 on the element isolation region ST. In this manner, an active region of the peripheral circuit formation region (an active region defined by the element isolation region ST) is covered by the laminated film LF1. By this process, it can be prevented to perform unnecessary etching to a substrate region of the semiconductor substrate SB in the peripheral circuit formation region (Si substrate region).

In the memory formation region 1A, the control gate electrode CG made of the patterned silicon film PS1 is formed, and the control gate electrode CG becomes a gate electrode for the control transistor. The residual insulating film GI1 below the control gate electrode CG becomes the gate insulating film for the control transistor. Therefore, in the memory formation region 1A, the control gate electrode CG made of the silicon film PS1 is formed on the semiconductor substrate SB (p-type well PW1) via the insulating film GI1 as the gate insulating film.

In the memory formation region 1A, the insulating film GI1 except for being covered by the laminated body LM1, that is, a part of the insulating film GI1 except for a portion which will be the gate insulating film can be removed by performing dry etching in a patterning process of Step S7 or wet etching after the dry etching.

As described above, via the insulating film GI1 as the gate insulating film on the semiconductor substrate SB, the laminated body LM1 including the control gate electrode CG and the cap insulating film CP1 on the control gate electrode CG is formed.

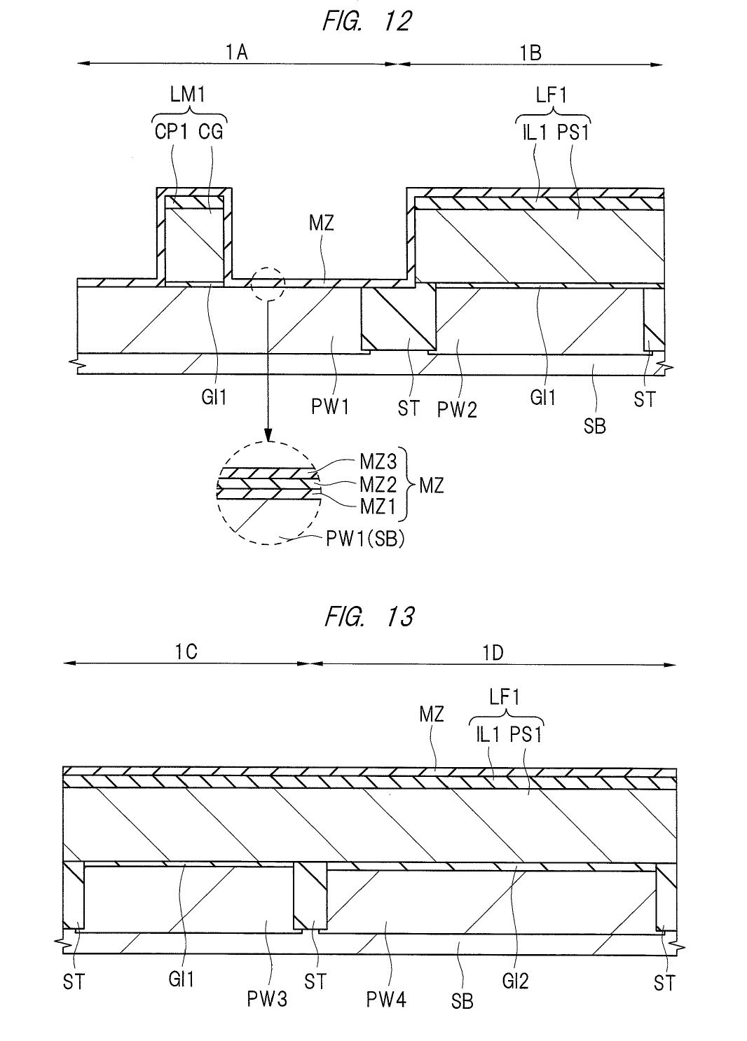

Next, after the principal surface of the semiconductor substrate SB is subjected to the cleaning process by performing the washing process, an insulating film MZ for the gate insulating film of a memory transistor is formed on the whole principal surface of the semiconductor substrate SB, that is, on the principal surface (surface) of the semiconductor substrate SB and on surfaces (an upper surface and a side surface) of the laminated body LM1 as illustrated in FIGS. 12 and 13 (Step S8 of FIG. 1).

Since the laminated film LF1 is left in the peripheral circuit formation region including the metal gate transistor formation region 1B, the low breakdown voltage MISFET formation region 1C and the high breakdown voltage MISFET formation region 1D, the insulating film MZ can be formed also on surfaces (an upper surface and a side surface) of this laminated film LF1. Therefore, in Step S8, the insulating film MZ is formed on the semiconductor substrate SB so as to cover the laminated body LM1 in the memory formation region 1A and the laminated film LF1 in the peripheral circuit formation region.

The insulating film MZ is the insulating film for the gate insulating film of the memory transistor, and is the insulating film which has a charge storage part inside. This insulating film MZ is a laminated film including a silicon oxide film (oxide film) MZ1, a silicon nitride film (nitride film) MZ2 formed on the silicon oxide film MZ1, and a silicon oxide film (oxide film) MZ3 formed on the silicon nitride film MZ2. The laminated film including the silicon oxide film MZ1, the silicon nitride film MZ2 and the silicon oxide film MZ3 can be also regard as an ONO (oxide-nitride-oxide) film.

In order to easily see the drawing, note that FIGS. 12 and 13 illustrate the insulating film MZ formed of the silicon oxide film MZ1, the silicon nitride film MZ2 and the silicon oxide film MZ3 as simply the insulating film MZ. Practically, as illustrated in an enlarged view of a region surrounded by a dotted-line circle in FIG. 12, the insulating film MZ is formed of the silicon oxide film MZ1, the silicon nitride film MZ2 and the silicon oxide film MZ3.

The silicon oxide films MZ1 and MZ3 of the insulating films MZ can be formed by, for example, an oxidation process (thermal oxidation process), the CVD method, or combination of them. In the oxidation process at this time, ISSG (In Situ Steam Generation) oxidization can be also used. The silicon nitride film MZ2 of the insulating film MZ can be also formed by, for example, the CVD method.

In addition, in the present embodiment, the silicon nitride film MZ2 is formed as an insulating film (charge storage layer) which has a trap level. Although the silicon nitride film is preferred in terms of reliability or others, the charge storage layer or the charge storage part is not limited to the silicon nitride film, and, for example, a high dielectric constant film having a dielectric constant higher than that of the silicon nitride film such as an aluminum oxide film (alumina), a hafnium oxide film, or a tantalum oxide film can be also used as the charge storage layer or the charge storage part. In addition, the charge storage layer or the charge storage part can be also formed with silicon nano-dot.

For forming the insulating film MZ, for example, the silicon oxide film MZ1 is formed by the thermal oxidation method (preferably, ISSG oxidization) first, and then, the silicon nitride film MZ2 is deposited on the silicon oxide film MZ1 by the CVD method, and further, the silicon oxide film MZ3 is formed on the silicon nitride film MZ2 by the CVD method, the thermal oxidation method, or both of them. In this manner, the insulating film MZ formed of the laminated film including the silicon oxide film MZ1, the silicon nitride film MZ2 and the silicon oxide film MZ3 can be formed.

A thickness of the silicon oxide film MZ1 can be set to, for example, about 2 to 10 nm, and a thickness of the silicon nitride film MZ2 can be set to, for example, about 5 to 15 nm, and a thickness of the silicon oxide film MZ3 can be set to, for example, about 2 to 10 nm. As the last oxide film, that is, the silicon oxide film MZ3 which is the uppermost layer of the insulating film MZ, a high breakdown voltage film can be also formed by, for example, oxidizing an upper layer part of the nitride film (the silicon nitride film MZ2 which is the intermediate layer of the insulating film MZ).

The insulating film MZ functions as a gate insulating film of a memory gate electrode MG formed later, and has an electric charge retention (charge storage) function. Therefore, the insulating film MZ has a laminated structure with at least three layers so as to function as the gate insulating film having the electric charge retention function of the memory transistor, in which a potential barrier height of an inner layer (here, the silicon nitride film MZ2) which functions as the charge storage part is lower than potential barrier heights of outer layers (here, the silicon oxide films MZ1 and MZ3) which function as the electric charge block layers. This structure can be achieved by forming the insulating film MZ as the laminated film including the silicon oxide film MZ1, the silicon nitride film MZ2 on the silicon oxide film MZ1, and the silicon oxide film MZ3 on the silicon nitride film MZ2 as described in the present embodiment.

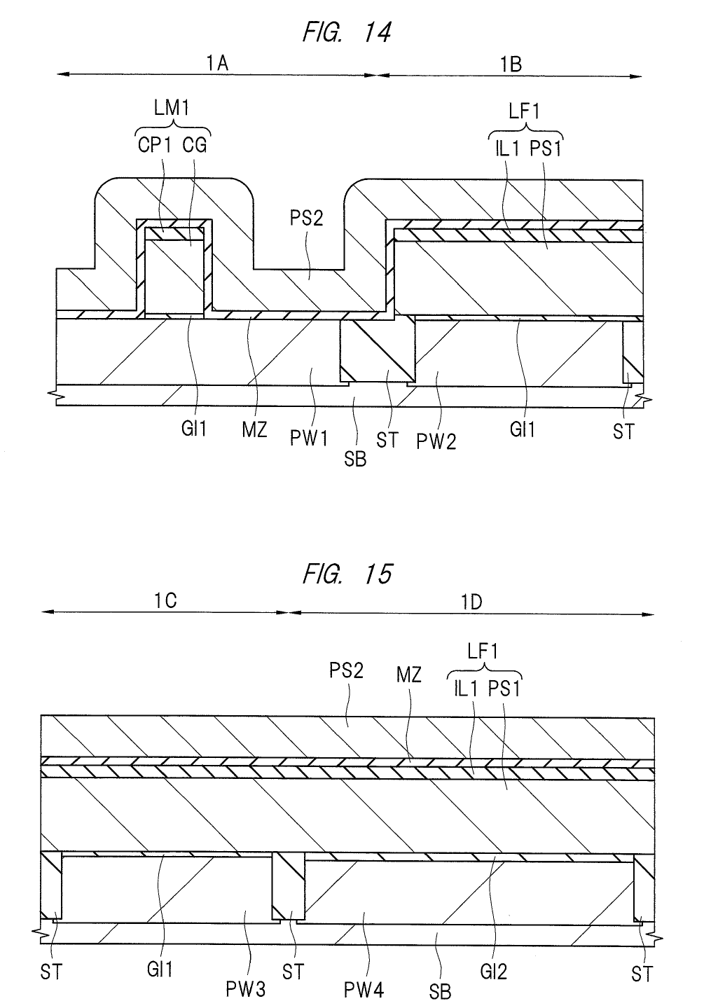

Next, as illustrated in FIGS. 14 and 15, on the principal surface (the whole principal surface) of the semiconductor substrate SB, that is, on the insulating film MZ, a silicon film PS2 is formed (deposited) as the conductive film for forming the memory gate electrode MG so as to cover the laminated body LM1 in the memory formation region 1A and so as to cover the laminated film LF1 in the peripheral circuit formation region (Step S9 of FIG. 1).

The silicon film PS2 is a conductive film for the gate electrode of the memory transistor, that is, a conductive film for forming the below-described memory gate electrode MG. The silicon film PS2 is made of a polycrystalline silicon film, and can be formed by using the CVD method or others. A deposited film thickness of the silicon film PS2 can be set to, for example, about 30 to 150 nm. After forming the silicon film PS2 as the amorphous silicon film at the time of film formation, the amorphous silicon film can be changed into the polycrystalline silicon film by a subsequent thermal process.

In addition, the silicon film PS2 is formed to be a semiconductor film (a doped poly-silicon film) having a low resistance by introducing an impurity at the time of the film formation or by ion-implanting the impurity after the film formation. The silicon film PS2 is preferably an n-type silicon film to which an n-type impurity such as phosphorus (P) or arsenic (As) is introduced. When the n-type impurity is introduced at the time of the film formation of the silicon film PS2, the silicon film PS2 to which the n-type impurity is introduced can be formed by containing doping gas (gas for adding the n-type impurity) in gas for forming the silicon film PS2. It is preferred to introduce the n-type impurity into the silicon film PS2 in the memory formation region 1A. However, into the silicon film PS2 in the peripheral circuit formation region, the n-type impurity may or may not be introduced because the silicon film is removed later.

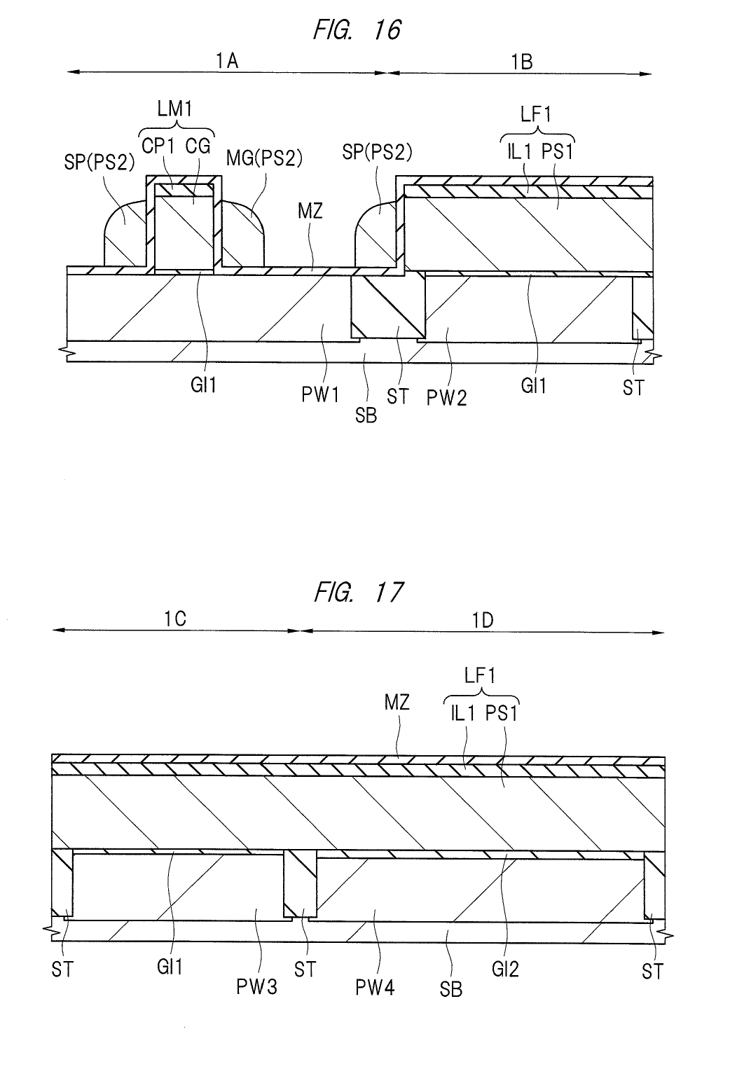

Next, the silicon film PS2 is etched back (etched, dry-etched, anisotropically etched) by an anisotropic etching technique, so that the memory gate electrode MG and a silicon spacer SP are formed as illustrated in FIGS. 16 and 17 (Step S10 of FIG. 1).

In the etch back process of Step S10, the silicon film PS2 is anisotropically etched (etched back) as much as the deposited film thickness of the silicon film PS2, so that the silicon film PS2 is left on both sidewalls of the laminated body LM1 (via the insulating film MZ) so as to have a sidewall spacer shape, and the silicon film PS2 in other regions is removed. In this manner, as illustrated in FIGS. 16 and 17, in the memory formation region 1A, the memory gate electrode MG is formed of the residual silicon film PS2 having the sidewall spacer shape on one sidewall of the both sidewalls of the laminated body LM1 via the insulating film MZ, and the silicon spacer SP is formed by the residual silicon film PS2 having the sidewall spacer shape on the other sidewall thereof via the insulating film MZ. The memory gate electrode MG is formed on the insulating film MZ so as to be adjacent to the laminated body LM1 via the insulating film MZ. Therefore, the control gate electrode CG and the memory gate electrode MG are adjacent to each other via the insulating film MZ. Since the insulating film MZ is interposed between the memory gate electrode MG and the control gate electrode CG, the memory gate electrode MG and the control gate electrode CG are not in contact with each other.

The silicon spacer SP can be also regarded as a sidewall spacer made of a conductive body (here, silicon film PS2), that is, a conductive body spacer. The memory gate electrode MG and the silicon spacer SP are formed on sidewalls of the laminated body LM1 which are opposed to each other, and have an almost symmetrical structure with the laminated body LM1 therebetween. In addition, also on the sidewall of the residual laminated film LF1 in the peripheral circuit formation region, the silicon spacer SP can be formed via the insulating film MZ.

By performing the etch back process to the silicon film PS2 in Step S10, the insulating film MZ in a region not covered by the memory gate electrode MG and the silicon spacer SP is exposed. The insulating film MZ is interposed between the memory gate electrode MG and the semiconductor substrate SB (p-type well PW1) and between the memory gate electrode MG and the control gate electrode CG. The insulating film MZ below the memory gate electrode MG in the memory formation region 1A becomes the gate insulating film of the memory transistor. By adjusting the deposited film thickness of the silicon film PS2 deposited in above-described Step S9, a memory gate length, that is, a gate length of the memory gate electrode MG can be adjusted.

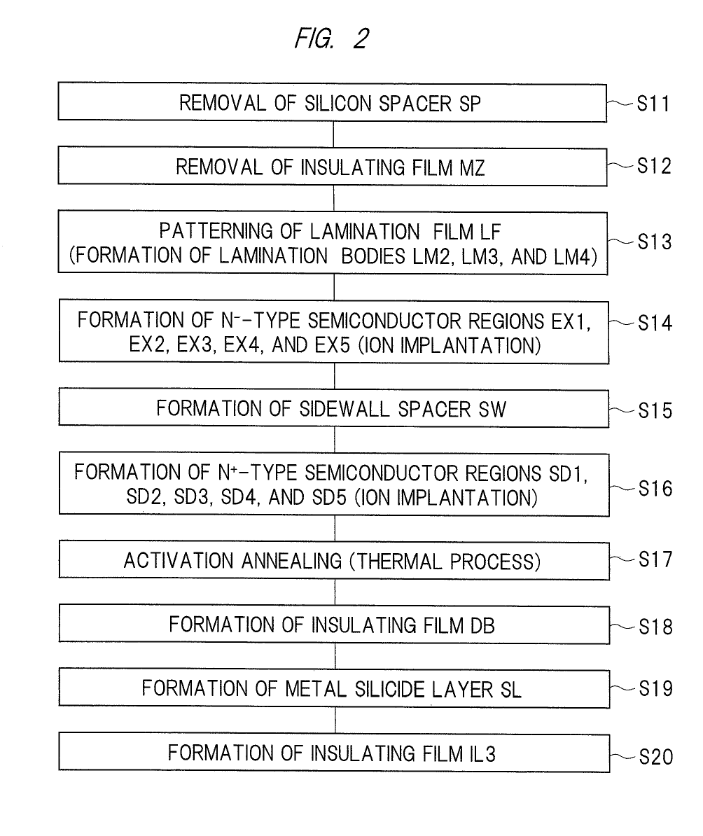

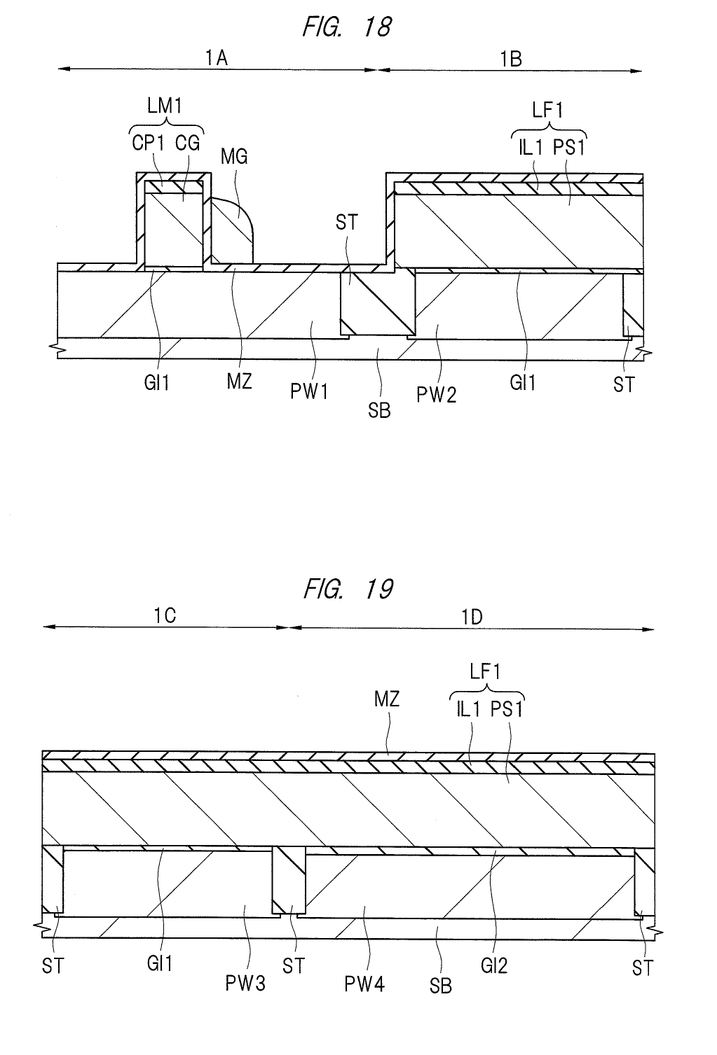

Next, as illustrated in FIGS. 18 and 19, the silicon spacer SP is removed (Step S11 of FIG. 2).

A removal process of the silicon spacer in Step S11 can be performed as, for example, follows. That is, the silicon spacer SP is removed by, on semiconductor substrate SB, forming the photoresist pattern (not illustrated) covering the memory gate electrode MG and exposing the silicon spacer SP by using the photolithography technique, and then, performing the dry etching process using this photoresist pattern as an etching mask, and then, this photoresist pattern is removed. In this manner, while the silicon spacer SP is removed as illustrated in FIGS. 18 and 19, the memory gate electrode MG is not etched and is left because the memory gate electrode has been covered by the photoresist pattern.

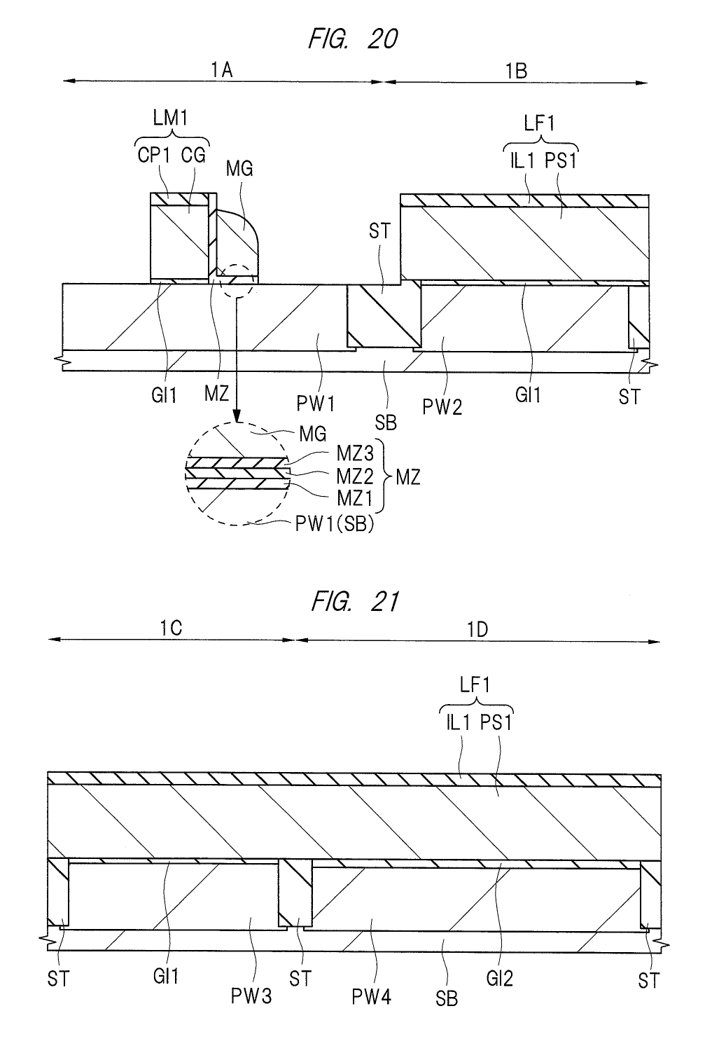

Next, as illustrated in FIGS. 20 and 21, the exposed portion of the insulating film MZ not covered by the memory gate electrode MG is removed by etching (for example, wet etching) (Step S12 of FIG. 2). In this case, in the memory formation region 1A, the insulating film MZ which is below the memory gate electrode MG and between the memory gate electrode MG and the laminated body LM1 is not removed and is left, and the insulating film MZ in the other region is removed. As seen also from FIG. 20, in the memory formation region 1A, the insulating film MZ continuously extends over both of the region between the memory gate electrode MG and the semiconductor substrate SB (p-type well PW1) and the region between the memory gate electrode MG and the laminated body LM1.

Note that, as illustrated in an enlarged view of the region surrounded by a dotted-line circle in FIG. 20, the insulating film MZ is formed of the laminated film including the silicon oxide film MZ1, the silicon nitride film MZ2 formed thereon, and the silicon oxide film MZ3 formed thereon.

Next, by introducing an n-type impurity into the silicon film PS1 in the region where the n-channel type MISFET is to be formed, of the silicon films PS1 in the peripheral circuit formation region by using the ion implantation method, the silicon film PS1 in the region where the n-channel type MISFET is to be formed is made to be an n-type silicon film (a doped poly-silicon film). In the ion implantation at this time, the memory formation region 1A and the silicon films PS1 in the region where the p-channel type MISFET is to be formed in the silicon film PS1 in the peripheral circuit formation region are covered by the photoresist layer. In addition, by introducing a p-type impurity into the silicon film PS1 in the region where the p-channel type MISFET is to be formed, of the silicon film PS1 in the peripheral circuit formation region by using the ion implantation method, the silicon film PS1 in the region where the p-channel type MISFET is to be formed is made to be a p-type silicon film (a doped poly-silicon film). In the ion implantation at this time, the memory formation region 1A and the silicon film PS1 in the region where the n-channel type MISFET is to be formed in the silicon film PS1 in the peripheral circuit formation region are covered by the photoresist layer. In this manner, the silicon films PS1 in the low breakdown voltage MISFET formation region 1C and the high breakdown voltage MISFET formation region 1D is made to be the n-type silicon film (the doped poly-silicon film) when the n-channel type MISFET is formed, and is made to be the p-type silicon film (the doped poly-silicon film) when the p-channel type MISFET is formed. On the other hand, since the dummy gate electrode DG which is to be formed in the metal gate transistor formation region 1B is removed later, the impurity may not be introduced into the silicon film PS1 in the metal gate transistor formation region 1B.

When the impurity is introduced into the silicon film PS1 by performing the ion implantation as described above after Step S12 (the removal process of the insulating film MZ) but before Step S13 (the patterning process of the laminated film LF1), the impurity may be not introduced into the silicon film PS1 before this ion implantation is performed, that is, the silicon film PS1 may be a non-doped (un-doped) silicon film.

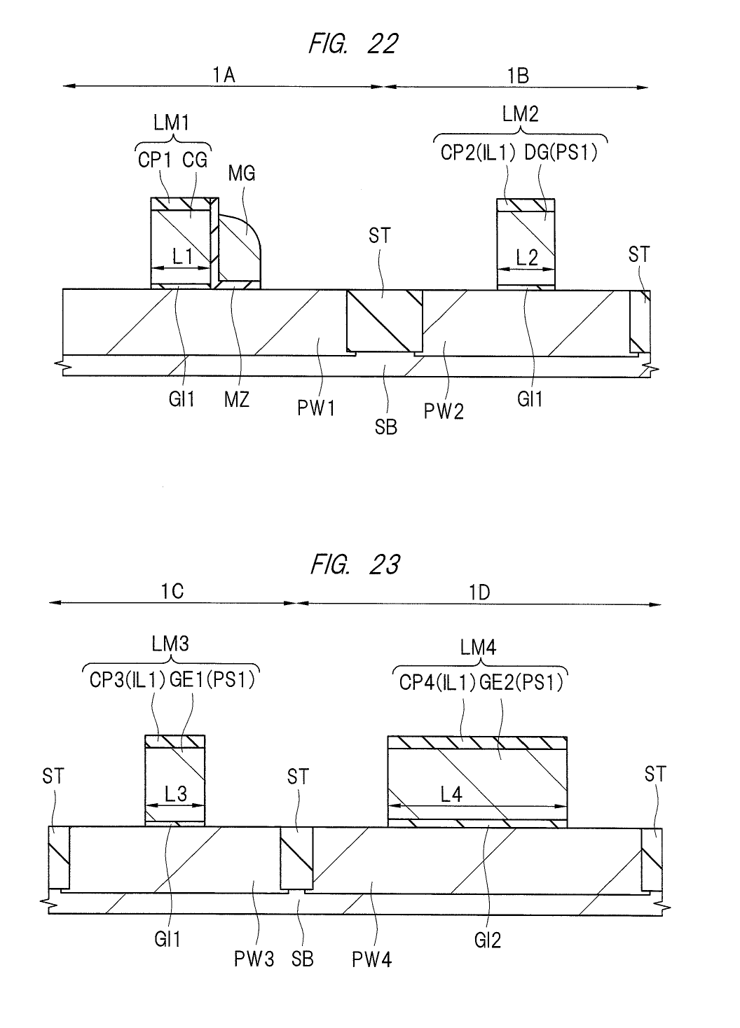

Next, the laminated film LF1 is patterned by using the photolithography technique and the etching technique. As illustrated in FIGS. 22 and 23, this manner forms a laminated body LM2 including a dummy gate electrode DG and a cap insulating film CP2 on the dummy gate electrode DG, a laminated body LM3 including a gate electrode GE1 and a cap insulating film CP3 on the gate electrode GE1, and a laminated body LM4 including a gate electrode GE2 and a cap insulating film CP4 on the gate electrode GE2 (Step S13 of FIG. 2).

The patterning process of Step S13 can be performed as, for example, follows. That is, first, on the principal surface of the semiconductor substrate SB, the photoresist pattern (not illustrated) is formed by using the photolithography method. This photoresist pattern is formed on the whole memory formation region 1A, a region where the dummy gate electrode DG is to be formed in the metal gate transistor formation region 1B, a region where the gate electrode GE1 is to be formed in the low breakdown voltage MISFET formation region 1C, and a region where the gate electrode GE2 is to be formed in the high breakdown voltage MISFET formation region 1D. Therefore, the memory gate electrode MG and the laminated body LM1 are covered by this photoresist pattern. Then, the laminated film LF1 including the silicon film PS1 and the insulating film IL1 is etched (preferably, dry-etched) and patterned by using this photoresist pattern as the etching mask, and then, this photoresist pattern is removed. In this manner, the laminated body LM2 made of the patterned laminated film LF1 is formed in the metal gate transistor formation region 1B, and the laminated body LM3 made of the patterned laminated film LF1 is formed in the low breakdown voltage MISFET formation region 1C, and the laminated body LM4 made of the patterned laminated film LF1 is formed in the high breakdown voltage MISFET formation region 1D.

The laminated body (laminated structure body) LM2 is formed of the dummy gate electrode DG and the cap insulating film CP2 on the dummy gate electrode DG, and is formed via the insulating film GI1 on the semiconductor substrate SB (p-type well PW2) in the metal gate transistor formation region 1B. The dummy gate electrode DG is formed of the patterned silicon film PS1, and the cap insulating film CP2 is formed of the patterned insulating film IL1. The dummy gate electrode DG and the cap insulating film CP2 have the almost same planar shape as each other in a planar view, and overlaps with each other in the planar view. That is, in the metal gate transistor formation region 1B, the dummy gate electrode DG is formed on the semiconductor substrate SB (p-type well PW2) via the insulating film GI1, and the cap insulating film CP2 is formed on the dummy gate electrode DG.

Note that, the dummy gate electrode DG is a dummy gate electrode (pseudo gate electrode) which does not function as the gate electrode of the transistor, and is removed later. In addition, the dummy gate electrode DG is removed later and is replaced by a below-described gate electrode GE3, and therefore, the dummy gate electrode DG can also be regarded as a replacement gate electrode (Replacement Gate Electrode) or a gate electrode for replacement.

The laminated body (laminated structure body) LM3 is formed of the gate electrode GE1 and the cap insulating film CP3 on the gate electrode GE1, and is formed via the insulating film GI1 on the semiconductor substrate SB (p-type well PW3) in the low breakdown voltage MISFET formation region 1C. The gate electrode GE1 is formed of the patterned silicon film PS1, and the cap insulating film CP3 is formed of the patterned insulating film IL1. The gate electrode GE1 and the cap insulating film CP3 have the almost same planar shape as each other in a planar view, and overlaps with each other in the planar view. That is, in the low breakdown voltage MISFET formation region 1C, the gate electrode GE1 is formed via the insulating film GI1 on the semiconductor substrate SB (p-type well PW3), and the cap insulating film CP3 is formed on the gate electrode GE1.

The laminated body (laminated structure body) LM4 is formed of the gate electrode GE2 and the cap insulating film CP4 on the gate electrode GE2, and is formed via the insulating film GI2 on the semiconductor substrate SB (p-type well PW4) in the high breakdown voltage MISFET formation region 1D. The gate electrode GE2 is formed of the patterned silicon film PS1, and the cap insulating film CP4 is formed of the patterned insulating film IL1. The gate electrode GE2 and the cap insulating film CP4 have the almost same planar shape as each other in a planar view, and overlaps with each other in the planar view. That is, in the high breakdown voltage MISFET formation region 1D, the gate electrode GE2 is formed via the insulating film GI2 on the semiconductor substrate SB (p-type well PW4), and the cap insulating film CP4 is formed on the gate electrode GE2.

The above-described photoresist pattern used in the patterning process of Step S13 is formed in the whole memory formation region 1A. Therefore, even when the patterning process of Step S13 is performed, the laminated body LM1 and the memory gate electrode MG in the memory formation region 1A are not removed and are left as they are.

In the metal gate transistor formation region 1B, in the low breakdown voltage MISFET formation region 1C, and in the high breakdown voltage MISFET formation region 1D, the insulating films GI1 and GI2 formed in a portion except for being covered by the laminated bodies LM2, LM3 and LM4 can be removed by the dry etching performed in the patterning process of Step S13 or the wet etching after the dry etching. That is, the insulating film GI1 in the portion except for being covered by the laminated bodies LM2 and LM3 in the metal gate transistor formation region 1B and the low breakdown voltage MISFET formation region 1C and the insulating film GI2 in the portion except for being covered by the laminated body LM4 in the high breakdown voltage MISFET formation region in can be removed.

A gate length of the gate electrode GE2 is larger than a gate length of the control gate electrode CG, a gate length of the dummy gate electrode DG, and a gate length of the gate electrode GE1. That is, a dimension L4 of the gate electrode GE2 in a gate length direction is larger than a dimension L1 of the control gate electrode CG in the gate length direction (L4>L1). In addition, the dimension L4 of the gate electrode GE2 in the gate length direction is larger than a dimension L2 of the dummy gate electrode DG in the gate length direction (L4>L2). In addition, the dimension L4 of the gate electrode GE2 in the gate length direction is larger than a dimension L3 of the gate electrode in the gate length direction GE1 (L4>L3). The dimensions L1, L2, L3 and L4 are illustrated in FIGS. 22 and 23.

In addition, an area of the gate electrode GE2 is larger than an area of the control gate electrode CG. In addition, the area of the gate electrode GE2 is larger than an area of the dummy gate electrode DG. In addition, the area of the gate electrode GE2 is larger than an area of the gate electrode GE1. Note that an area described here is an area in a planar view.

That is, the gate electrode GE2 is a pattern larger than the control gate electrode CG, the dummy gate electrode DG, and the gate electrode GE1.

Here, the dimension L1 of the control gate electrode CG in the gate length direction corresponds to the dimension (length) of the control gate electrode CG when viewing in the gate length direction of the control gate electrode CG. In addition, the dimension L3 of the gate electrode GE1 in the gate length direction corresponds to the dimension (length) of the gate electrode GE1 when viewing in the gate length direction of the gate electrode GE1. In addition, the dimension L4 of the gate electrode GE2 in the gate length direction corresponds to the dimension (length) of the gate electrode GE2 when viewing in the gate length direction of the gate electrode GE2. In addition, the dimension L2 of the dummy gate electrode DG in the gate length direction corresponds to the dimension (length) of the dummy gate electrode DG when viewing in the gate length direction of the gate electrode GE3 obtained by replacing the dummy gate electrode DG later. That is, while the dummy gate electrode DG does not function as the gate electrode of the transistor and is removed later, the dimension of the dummy gate electrode DG when viewing in the direction along the gate length direction of the below-described gate electrode GE3 to be embedded later into a region (corresponding to a below-described trench TR) where the dummy gate electrode DG is removed corresponds to the dimension L2 of the dummy gate electrode DG in the gate length direction.

In addition, since the dimension L4 of the gate electrode GE2 in the gate length direction is larger than the dimension L2 of the dummy gate electrode DG in the gate length direction (L4>L2), the dimension L4 of the gate electrode GE2 in the gate length direction is larger than the dimension of the below-described gate electrode GE3 formed later in the gate length direction. That is, the gate length of the gate electrode GE2 is larger than the gate length of the below-described gate electrode GE3 formed later.

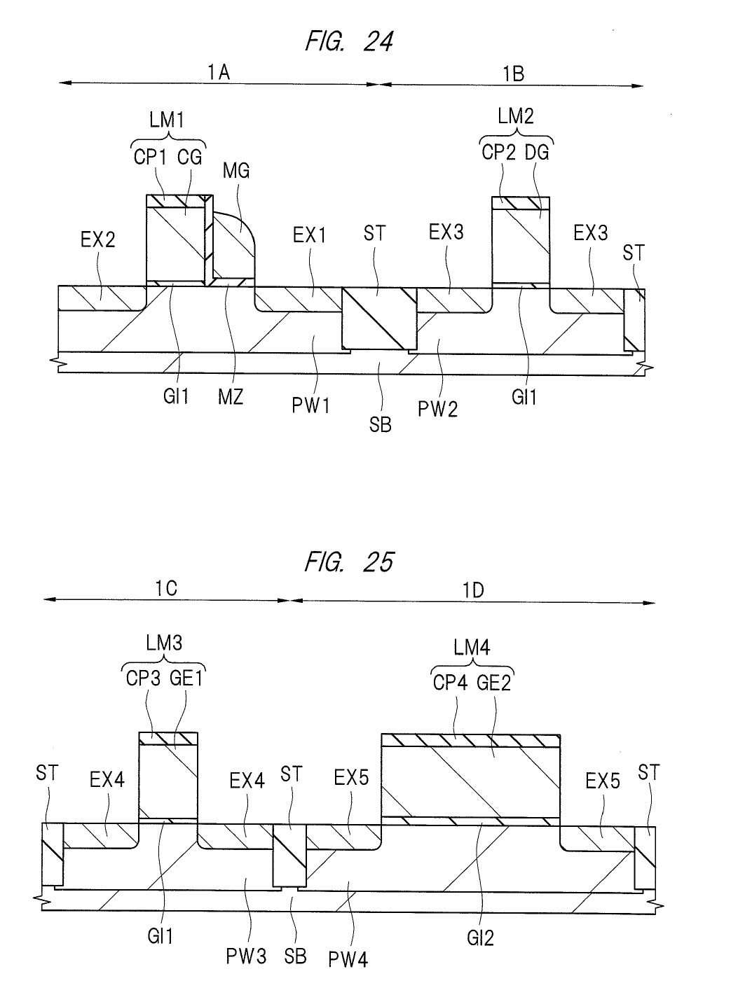

Next, as illustrated in FIGS. 24 and 25, n⁻-type semiconductor regions (impurity-diffused layers) EX1, EX2, EX3, EX4 and EX5 are formed by using the ion implantation method or others (Step S14 of FIG. 2).

In Step S14, the n⁻-type semiconductor regions EX1, EX2, EX3, EX4 and EX5 can be formed by introducing, for example, the n-type impurity such as arsenic (As) or phosphorus (P) by the ion implantation method into the semiconductor substrate SB (p-type wells PW1, PW2, PW3 and PW4) by using the memory gate electrode MG and the laminated bodies LM1, LM2, LM3 and LM4 as a mask (ion implantation prevention mask). At this time, the n⁻-type semiconductor region EX1 is formed in self alignment on the sidewall of the memory gate electrode MG (the sidewall opposite to the side adjusted to the control gate electrode CG via the insulating film MZ) in the memory formation region 1A by functioning the memory gate electrode MG as a mask (ion implantation prevention mask). In addition, the n⁻-type semiconductor region EX2 is formed in self alignment on the sidewall of the control gate electrode CG (the sidewall opposite to the side adjusted to the memory gate electrode MG via the insulating film MZ) in the memory formation region 1A by functioning the laminated body LM1 as a mask (ion implantation prevention mask). In addition, the laminated body LM2 is functioned as a mask (ion implantation prevention mask), so that the n⁻-type semiconductor region EX3 is formed in self alignment on both sidewalls of the dummy gate electrode DG in the metal gate transistor formation region 1B. In addition, the laminated body LM3 is functioned as a mask (ion implantation prevention mask), so that the n⁻-type semiconductor region EX4 is formed in self alignment on both sidewalls of the gate electrode GE1 in the low breakdown voltage MISFET formation region 1C. In addition, the laminated body LM4 is functioned as a mask (ion implantation prevention mask), so that the n⁻-type semiconductor region EX5 is formed in self alignment on both sidewalls of the gate electrode GE2 in the high breakdown voltage MISFET formation region 1D.

The n⁻-type semiconductor region EX1 and the n⁻-type semiconductor region EX2 can be functioned as a part of a source/drain region (source or drain region) of the memory cell formed in the memory formation region 1A. The n⁻-type semiconductor region EX3 can be functioned as a part of a source/drain region (source or drain region) of the MISFET formed in the metal gate transistor formation region 1B. The n⁻-type semiconductor region EX4 can be functioned as a part of a source/drain region (source or drain region) of the MISFET formed in the low breakdown voltage MISFET formation region 1C. The n⁻-type semiconductor region EX5 can be functioned as a part of a source/drain region (source or drain region) of the MISFET formed in the high breakdown voltage MISFET formation region 1D.

While the n⁻-type semiconductor region EX1, the n⁻-type semiconductor region EX2, the n⁻-type semiconductor region EX3, the n⁻-type semiconductor region EX4 and the n⁻-type semiconductor region EX5 can be formed by the same ion implantation process, they can also be formed by a different ion implantation process.

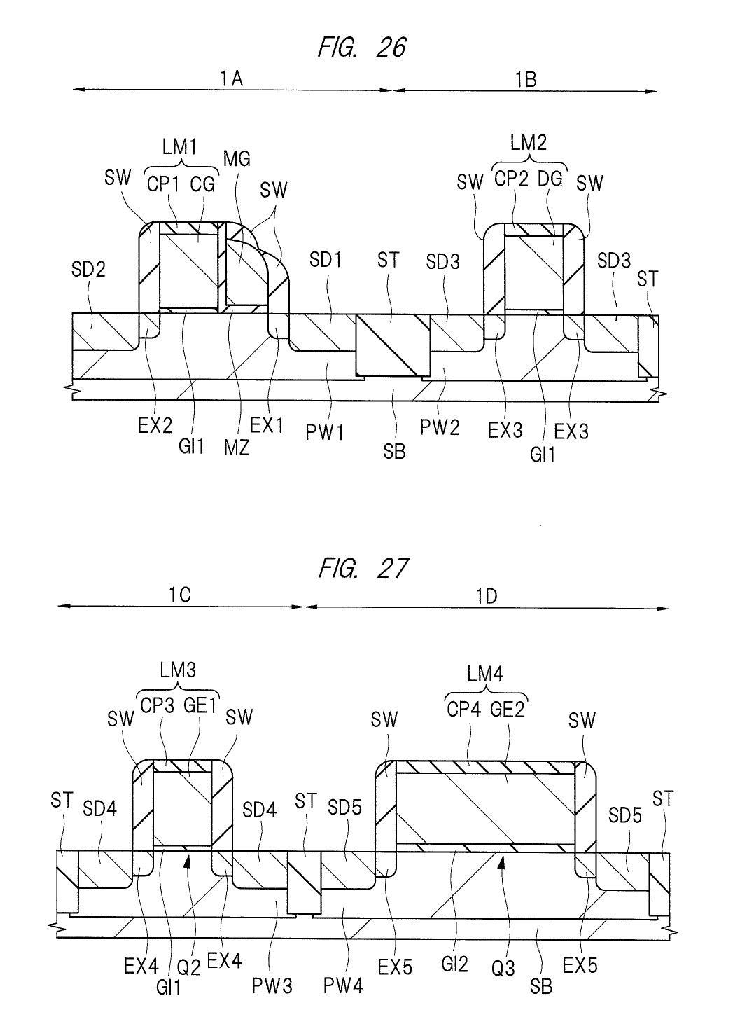

Next, as illustrated in FIGS. 26 and 27, a sidewall spacer (sidewall, sidewall insulating film) SW made of an insulating film is formed on sidewalls of the laminated body LM1 and the memory gate electrode MG (their sidewalls opposite to mutually-adjacent sides via the insulating film MZ), on the sidewall of the laminated body LM2, on the sidewall of the laminated body LM3, and on the sidewall of the laminated body LM4, (Step S15 of FIG. 2). The sidewall spacer SW is regarded as the sidewall insulating film.

A formation process of the sidewall spacer SW in Step S15 can be performed as, for example, follows. That is, first, the insulating film for forming the sidewall spacer SW is formed (deposited) on the whole principal surface of the semiconductor substrate SB. This insulating film (that is, insulating film for forming the sidewall spacer SW) is formed of, for example, a silicon oxide film, a silicon nitride film, a laminated film of them, or others, and can be formed by using the CVD method or others. This insulating film is formed on the semiconductor substrate SB so as to cover the memory gate electrode MG, the laminated body LM1, the laminated body LM2, the laminated body LM3, and the laminated body LM4. Then, this insulating film is etched back (etched, dry-etched, anisotropically etched) by the anisotropic etching technique. In this manner, this insulating film (that is, insulating film for forming the sidewall spacer SW) is selectively left to form the sidewall spacer SW on the sidewalls of the laminated body LM1 and the memory gate electrode MG (their sidewalls opposite to mutually-adjacent sides via the insulating film MZ), on the sidewall of the laminated body LM2, on the sidewall of the laminated body LM3, and on the sidewall of the laminated body LM4. The sidewall spacer SW is formed on both sidewalls of the laminated body LM2, on both sidewalls of the laminated body LM3, on both sidewalls of the laminated body LM4, on a sidewall of the sidewalls of the laminated body LM1 opposite to the adjacent side to the memory gate electrode MG via the insulating film MZ, and on a sidewall of the sidewalls of the memory gate electrode MG opposite to the adjacent side to the laminated body LM1 via the insulating film MZ.

The sidewall spacer SW is formed on a sidewall of the sidewalls of the memory gate electrode MG opposite to the adjacent side to the laminated body LM1 via the insulating film MZ. However, the sidewall spacer SW is formed or is not formed depending on cases on the memory gate electrode MG, that is, above the memory gate electrode MG. FIG. 26 illustrates the case that the sidewall spacer SW is formed also above the memory gate electrode MG.

It is controlled whether the sidewall spacer SW is formed above the memory gate electrode MG or not by a relative relation between a height of the laminated body LM1 and the memory gate electrode MG and an amount of the etch back performed when the insulating film for forming the sidewall spacer SW is etched back.

In a case that the height of the memory gate electrode MG is almost the same as that of the laminated body LM1, when the insulating film for forming the sidewall spacer SW is etched back, the insulating film is left on the sidewall of the memory gate electrode MG to form the sidewall spacer SW, whereas the insulating film for forming the sidewall spacer SW is not left on an upper surface of the memory gate electrode MG. Therefore, the sidewall spacer SW is not formed above the memory gate electrode MG. In this case, a below-described metal silicide layer SL is formed above the memory gate electrode MG in a below-described Step S19.

On the other hand, in a case that the height of the memory gate electrode MG is lower than the height of the laminated body LM1, the sidewall of the laminated body LM1, which is on the adjacent side to the memory gate electrode MG has a portion higher than the memory gate electrode MG. Therefore, when the insulating film for forming the sidewall spacer SW is etched back, the insulating film is left to form the sidewall spacer SW on the portion higher than the memory gate electrode MG in the sidewall of the laminated body LM1, which is on the adjacent side to the memory gate electrode MG, and this sidewall spacer SW is positioned above the memory gate electrode MG. That is, the sidewall spacer SW positioned on the memory gate electrode MG is adjacent to the sidewall of the laminated body LM1 positioned higher than the memory gate electrode MG. The sidewall spacer SW positioned on the memory gate electrode MG may be connected integrally with the sidewall spacer SW adjacent to the sidewall of the memory gate electrode MG (the sidewall being opposite to the sidewall adjacent to the control gate electrode CG). FIG. 26 illustrates a case that an upper surface and a side surface of the memory gate electrode MG (the side surface being opposite to the adjacent side to the control gate electrode CG) are covered by the sidewall spacer SW and are not exposed by forming the sidewall spacer SW also above the memory gate electrode MG. In the case that the sidewall spacer SW is formed also above the memory gate electrode MG, the below-described metal silicide layer SL can be prevented from being formed above the memory gate electrode MG in the below-described Step S19. Note that it is possible to reduce the height of the memory gate electrode MG to be lower than the height of the laminated body LM1 by adjusting the amount of the etching back performed when the silicon film PS2 is etched back to form the memory gate electrode MG in above-described Step S10.

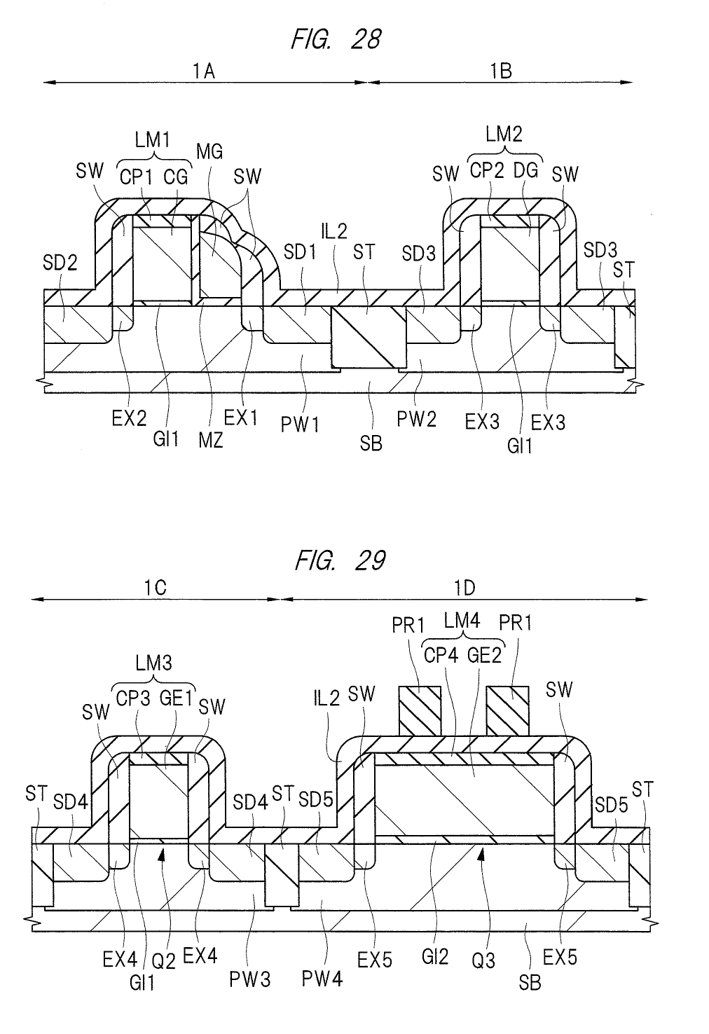

Next, as illustrated in FIGS. 28 and 29, n⁺-type semiconductor regions (impurity-diffused layers) SD1, SD2, SD3, SD4 and SD5 are formed by using the ion implantation method or others (Step S16 of FIG. 2).

In Step S16, the n⁺-type semiconductor regions SD1 to SD5 can be formed by introducing, for example, the n-type impurity such as arsenic (As) or phosphorus (P) by the ion implantation method into the semiconductor substrate SB (p-type wells PW1 to PW4) by using the memory gate electrode MG, the laminated bodies LM1, LM2, LM3 and LM4, and the sidewall spacer SW as a mask (ion implantation prevention mask). At this time, the n⁺-type semiconductor region SD1 is formed in self alignment on the sidewall spacer SW on the sidewall of the memory gate electrode MG in the memory formation region 1A by functioning the memory gate electrode MG, the sidewall spacer SW on the memory gate electrode MG, and the sidewall spacer SW on the sidewall of the memory gate electrode MG as a mask (ion implantation prevention mask). In addition, the laminated body LM1 and the sidewall spacer SW on the sidewall of the laminated body LM1 are functioned as a mask (ion implantation prevention mask), so that the n⁺-type semiconductor region SD2 is formed in self alignment on the sidewall spacer SW on the sidewall of the laminated body LM1 in the memory formation region 1A. In addition, the laminated body LM2 and the sidewall spacer SW on the sidewall of the laminated body LM2 are functioned as a mask (ion implantation prevention mask), so that the n⁺-type semiconductor region SD3 is formed in self alignment on the sidewall spacers SW on both sidewalls of the laminated body LM2 in the metal gate transistor formation region 1B. In addition, the laminated body LM3 and the sidewall spacer SW on the sidewall of the laminated body LM3 are functioned as a mask (ion implantation prevention mask), so that the n⁺-type semiconductor region SD4 is formed in self alignment on the sidewall spacers SW on both sidewalls of the laminated body LM3 in the low breakdown voltage MISFET formation region 1C. In addition, the laminated body LM4 and the sidewall spacer SW on the sidewall of the laminated body LM4 are functioned as a mask (ion implantation prevention mask), so that the n⁺-type semiconductor region SD5 is formed in self alignment on the sidewall spacers SW on both sidewalls of the laminated body LM4 in the high breakdown voltage MISFET formation region 1D. In this manner, the LDD (Lightly Doped Drain) structure is formed.

While the n⁺-type semiconductor region SD1, the n⁺-type semiconductor region SD2, the n⁺-type semiconductor region SD3, the n⁺-type semiconductor region SD4 and the n⁺-type semiconductor region SD5 can be formed by the same ion implantation process, they can be also formed by a different ion implantation process. Any combination of the n⁺-type semiconductor regions SD1, SD2, SD3, SD4, and SD5 can be also formed by the same ion implantation process.

In this manner, an n-type semiconductor region which functions as the source region of the memory transistor is formed by the n⁻-type semiconductor region EX1 and the n⁺-type semiconductor region SD1 having a higher impurity concentration than that of the n⁻-type semiconductor region EX1, and an n-type semiconductor region which functions as the drain region of the control transistor is formed by the n⁻-type semiconductor region EX2 and the n⁺-type semiconductor region SD2 having a higher impurity concentration than that of the n⁻-type semiconductor region EX2. The n⁺-type semiconductor region SD1 is higher in the impurity concentration and deeper in a junction depth than the n⁻-type semiconductor region EX1, and the n⁺-type semiconductor region SD2 is higher in the impurity concentration and deeper in the junction depth than the n⁻-type semiconductor region EX2. In addition, an n-type semiconductor region which functions as the source/drain region of the MISFET Q1 in the metal gate transistor formation region 1B is formed by the n⁻-type semiconductor region EX3 and the n⁺-type semiconductor region SD3 having a higher impurity concentration than that of the n⁻-type semiconductor region EX3. The n⁺-type semiconductor region SD3 is higher in the impurity concentration and deeper in the junction depth than the n⁻-type semiconductor region EX3. In addition, an n-type semiconductor region which functions as the source/drain region of the MISFET Q2 in the low breakdown voltage MISFET formation region 1C is formed by the n⁻-type semiconductor region EX4 and the n⁺-type semiconductor region SD4 having a higher impurity concentration than that of the n⁻-type semiconductor region EX4. The n⁺-type semiconductor region SD4 is higher in the impurity concentration and deeper in the junction depth than the n⁻-type semiconductor region EX4. In addition, an n-type semiconductor region which functions as the source/drain region of the MISFET Q3 in the high breakdown voltage MISFET formation region 1D is formed by the n⁻-type semiconductor region EX5 and the n⁺-type semiconductor region SD5 having a higher impurity concentration than that of the n⁻-type semiconductor region EX5. The n⁺-type semiconductor region SD5 is higher in the impurity concentration and deeper in the junction depth than the n⁻-type semiconductor region EX5.

Next, an activation annealing is performed (Step S17 of FIG. 2), the activation annealing being a thermal processing for activating the impurity which has been introduced into the semiconductor region for the source and drain (the n⁻-type semiconductor regions EX1, EX2, EX3, EX4 and EX5, and the n⁺-type semiconductor regions SD1, SD2, SD3, SD4 and SD5) or others.

In this manner, the memory cell of the nonvolatile memory is formed in the memory formation region 1A. In addition, in the low breakdown voltage MISFET formation region 1C, the MISFET Q2 is formed, the MISFET Q2 having the gate electrode GE1 as a gate electrode, the insulating film GI1 as the gate insulating film, and the n⁻-type semiconductor region EX4 and the n⁺-type semiconductor region SD4 as the source/drain region. In addition, in the high breakdown voltage MISFET formation region 1D, the MISFET Q3 is formed, the MISFET Q3 having the gate electrode GE2 as a gate electrode, the insulating film GI2 as the gate insulating film, and the n⁻-type semiconductor region EX5 and the n⁺-type semiconductor region SD5 as the source/drain region.

On the other hand, although the n⁻-type semiconductor region EX3 and the n⁺-type semiconductor region SD3 are formed in the metal gate transistor formation region 1B as the source/drain region for the MISFET Q1, the dummy gate electrode DG does not function as the gate electrode of the MISFET, and is removed later. Therefore, in this stage, a gate electrode (a below-described gate electrode GE3) to be used as the gate electrode of the MISFET Q1 of the metal gate transistor formation region 1B has not been formed yet.

Next, on the laminated body LM4 in the high breakdown voltage MISFET formation region 1D, the insulating film DB is partially formed (Step S18 of FIG. 2).

A process of forming the insulating film DB in Step S18 has a process of forming the insulating film IL2 and a process of etching and patterning the insulating film IL2. Specifically, the process of forming the insulating film DB in Step S18 can be performed as follows (FIGS. 28 to 31).

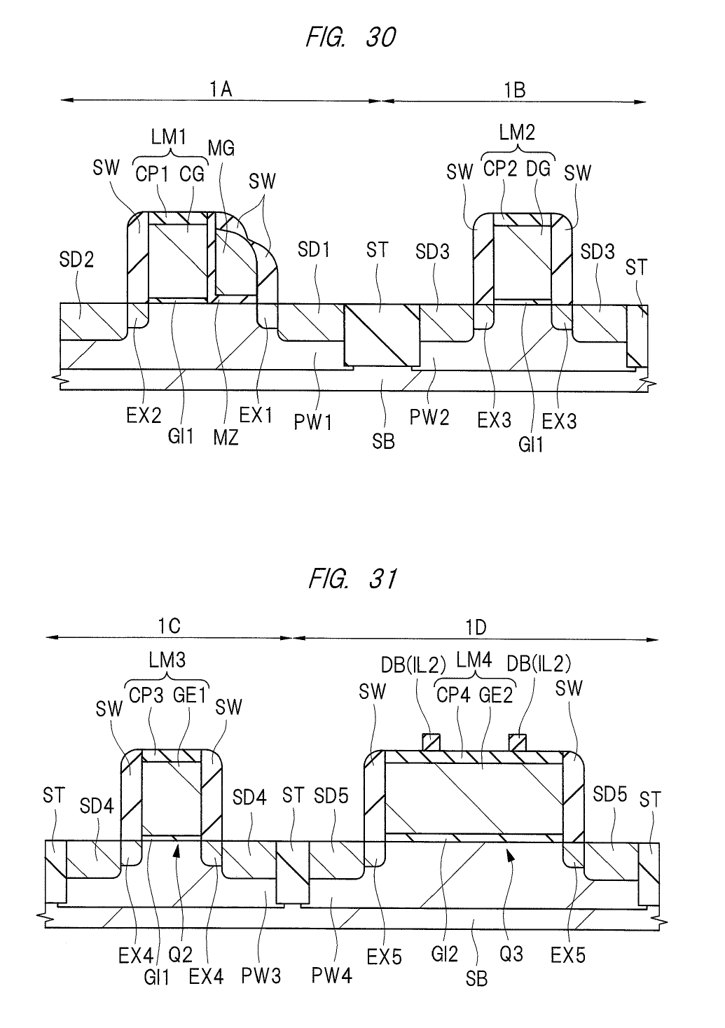

That is, as illustrated in FIGS. 28 and 29, the insulating film IL2 is formed (deposited) on the principal surface of the semiconductor substrate SB (on the whole principal surface) so as to cover the memory gate electrode MG, the laminated bodies LM1, LM2, LM3, and LM4, and the sidewall spacer SW. The insulating film IL2 is formed of the silicon nitride film or others, and can be formed by using the CVD method or others. Then, on the insulating film IL2, the photoresist pattern PR1 is formed as a resist pattern by using the photolithography method. The photoresist pattern PR1 is formed in a region where the insulating film DB is to be formed in the high breakdown voltage MISFET formation region 1D. Then, by etching and patterning the insulating film IL2 by using the photoresist pattern PR1 as an etching mask, the insulating film DB formed of the patterned insulating film IL2 is formed on the laminated body LM4. After that, the photoresist pattern PR1 is removed. FIGS. 30 and 31 illustrate this stage. In this manner, the process of forming the insulating film DB in Step S18 is performed.

The insulating film DB is a pattern for preventing dishing caused on the gate electrode GE2 in a polishing process performed later. The insulating film DB is formed of the patterned insulating film IL2, and is partially formed on the laminated body LM4. That is, the insulating film DB is not formed on the whole upper surface of the laminated body LM4 but partially formed on the upper surface of the laminated body LM4. That is, the insulating film DE is formed not on the whole upper surface of the laminated body LM4, but on a part of the upper surface of the laminated body LM4. Note that the partial formation of the insulating film DB on the laminated body LM4 is synonymous with the local formation of the insulating film DB on the laminated body LM4.

Therefore, the upper surface of the laminated body LM4 has a part where the insulating film DB has been formed, and a part where the insulating film DB has not been formed. That is, the upper surface of the laminated body LM4 has a part which has been covered by the insulating film DB and a part which has not been covered by the insulating film DB. That is, in a planar view, the laminated body LM4 has a part which has been overlapped with the insulating film DB and a part which has not been overlapped with the insulating film DB. The laminated body LM4 is formed of the gate electrode GE2 and the cap insulating film CP4 on the gate electrode GE2. Therefore, in a planar view, the gate electrode GE2 has a part which has been overlapped with the insulating film DB and a part which has not been overlapped with the insulating film DB.

In addition, it is preferred not to form the insulating film DB on the memory gate electrode MG, the laminated body LM1, the laminated body LM2, and the laminated body LM3. That is, the insulating film DB is formed on a part of the upper surface of the laminated body LM4 but not formed on the memory gate electrode MG and the laminated bodies LM1, LM2 and LM3. Therefore, it is required to form the above-described photoresist pattern PR1 on the laminated body LM4 but not to form on the memory gate electrode MG and the laminated bodies LM1, LM2 and LM3.

In addition, when the insulating film IL2 is etched by using the photoresist pattern PR1 as an etching mask, it is preferred to perform isotropic etching. In this manner, the unnecessary insulating film IL2 can be prevented from being left except for a part below the photoresist pattern PR1. For example, the insulating film IL2 can be prevented from being left in a sidewall spacer shape on sidewalls of the memory gate electrode MG and the laminated bodies LM1, LM2, LM3 and LM4.

Therefore, a dimension of the photoresist pattern PR1 is set to be larger than a dimension of the insulating film DB to be formed on the laminated body LM4, and the insulating film DB is formed by isotropically etching the insulating film IL2 by using the photoresist pattern PR1 as an etching mask. In this manner, a planar dimension of the insulating film IL2 is smaller than a planar dimension of the photoresist pattern PR1 by an amount of side etching in the etching. For example, the dimension of the insulating film DB is smaller than the dimension of the photoresist pattern PR1 when viewing in a gate length direction of the gate electrode GE2. And, the insulating film IL2 can be removed so that the unnecessary residual is not left, by isotropically etching the insulating film IL2 except for the part below the photoresist pattern PR1, that is, in the region which has not been covered by the photoresist pattern PR1. As for the process of etching the insulating film IL2, the wet etching, the dry etching, or a combination of both can be used. Therefore, the process of etching the insulating film IL2 can be a case that the isotropic dry etching or wet etching is performed after the anisotropic dry etching.

Next, the metal silicide layer SL is formed (Step S19 of FIG. 2). The metal silicide layer SL can be formed as follows.

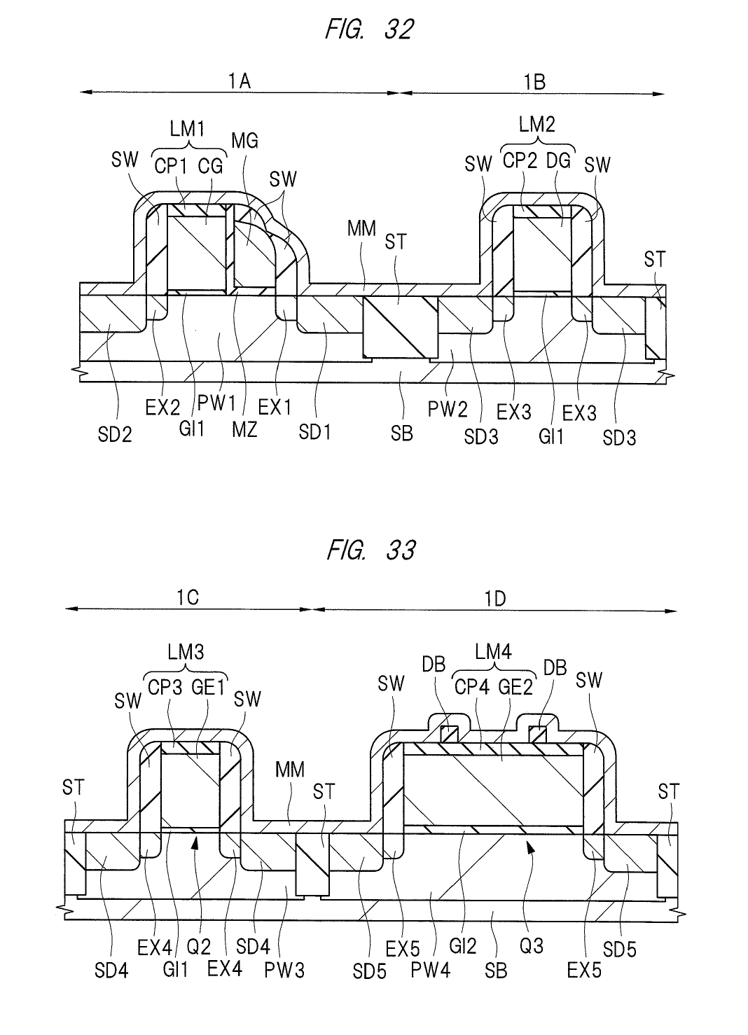

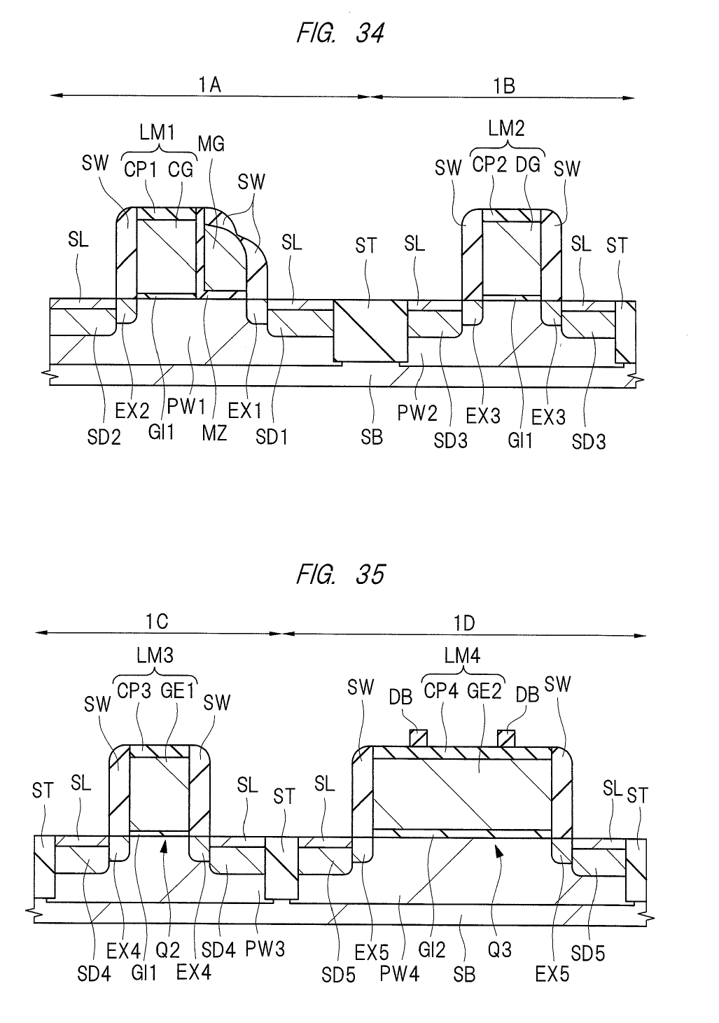

First, as illustrated in FIGS. 32 and 33, a metal film MM is formed (deposited) on the whole principal surface of the semiconductor substrate SB including the upper surfaces (surfaces) of the n⁺-type semiconductor regions SD1, SD2, SD3, SD4 and SD5 so as to cover the memory gate electrode MG, the laminated bodies LM1, LM2, LM3 and LM4, and the sidewall spacer SW. The metal film MM can be formed of a single metal film (pure metal film) or an alloy film, and is preferably formed of a cobalt (Co) film, a nickel (Ni) film or a nickel platinum alloy film. The metal film MM can be formed by using a sputtering method or others.

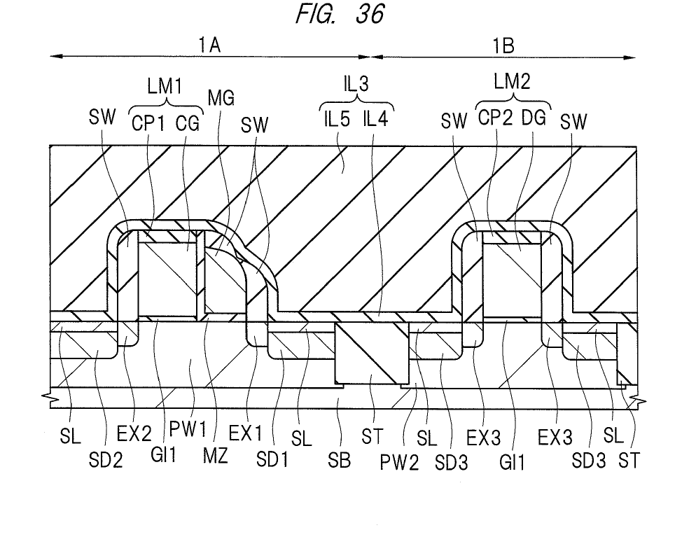

Next, each upper layer part (surface layer part) of the n⁺-type semiconductor regions SD1, SD2, SD3, SD4 and SD5 is reacted with the metal film MM by applying a thermal process onto the semiconductor substrate SB. In this manner, as illustrated in FIGS. 34 and 35, the metal silicide layer SL is formed on each upper part (upper surface, surface, or upper layer part) of the n⁺-type semiconductor regions SD1, SD2, SD3, SD4 and SD5. The metal silicide layer SL can be, for example, a cobalt silicide layer (in which the metal film MM is a cobalt film), a nickel silicide layer (in which the metal film MM is a nickel layer), or a platinum-added nickel silicide layer (in which the metal film MM is a nickel platinum alloy film). Note that the platinum-added nickel silicide layer is a nickel silicide layer to which platinum is added, that is, a nickel silicide layer containing platinum, and can be also referred to as a nickel platinum silicide layer. After that, the unreacted metal film MM is removed by wet etching or others. FIGS. 34 and 35 illustrate a cross-sectional view at this stage. In addition, after removing the unreacted metal film MM, a thermal process is further performed.

In this manner, the metal silicide layer SL is formed on each upper part of the n⁺-type semiconductor regions SD1, SD2, SD3, SD4 and SD5 by performing a so-called salicide (Self Aligned Silicide) process, so that a resistance of the source/drain can be lowered. By using the salicide process, the metal silicide layer SL can each be formed in self alignment on each of the n⁺-type semiconductor regions SD1, SD2, SD3, SD4 and SD5.

Since the cap insulating film CP1 is formed on the control gate electrode CG, the metal film MM does not contact the control gate electrode CG even when the metal film MM is formed, and one corresponding to the metal silicide layer SL is not formed on the control gate electrode CG even when the thermal process is performed. In addition, since the cap insulating film CP2 is formed on the dummy gate electrode DG, the metal film MM does not contact the dummy gate electrode DG even when the metal film MM is formed, and one corresponding to the metal silicide layer SL is not formed on the dummy gate electrode DG even when the thermal process is performed. In addition, since the cap insulating film CP3 is formed on the gate electrode GE1, the metal film MM does contact the gate electrode GE1 even when the metal film MM is formed, and one corresponding to the metal silicide layer SL is not formed on the gate electrode GE1 even when the thermal process is performed. In addition, since the cap insulating film CP4 is formed on the gate electrode GE2, the metal film MM does contact the gate electrode GE2 even when the metal film MM is formed, and one corresponding to the metal silicide layer SL is not formed on the gate electrode GE2 even when the thermal process is performed.

In addition, when the sidewall spacer SW is formed on not only the sidewall of the memory gate electrode MG but also the upper part of the memory gate electrode MG, the metal film MM does contact the memory gate electrode MG even when the metal film MM is formed, and one corresponding to the metal silicide layer SL is not formed on the memory gate electrode MG even when the thermal process is performed.

On the other hand, when the sidewall spacer SW is not formed on the upper part of the memory gate electrode MG while the sidewall spacer SW is formed on the sidewall of the memory gate electrode MG, the metal film MM contacts the upper part of the memory gate electrode MG when the metal film MM is formed, and therefore, the metal silicide layer SL is formed on the upper part of the memory gate electrode MG when the thermal process is performed.

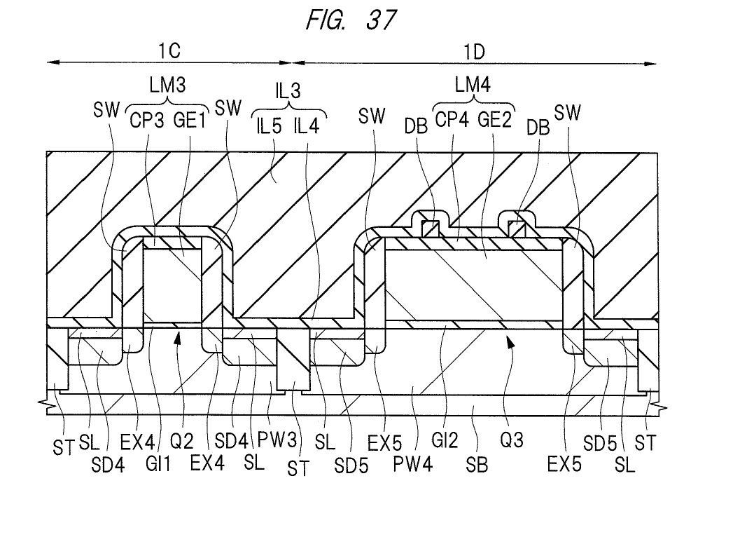

Next, as illustrated in FIGS. 36 and 37, on the principal surface (on the whole principal surface) of the semiconductor substrate SB, the insulating film IL3 is formed (deposited) as an interlayer insulating film so as to cover the memory gate electrode MG, the laminated bodies LM1, LM2, LM3 and LM4, and the sidewall spacer SW (Step S20 of FIG. 2).

At a stage of formation of the insulating film IL3 in Step S20, the upper surface of the insulating film IL3 may have surface irregularity or a level difference which is reflected by the memory gate electrode MG, the laminated bodies LM1, LM2, LM3 and LM4, the sidewall spacer SW, or others may be formed on in some cases.

FIGS. 36 and 37 illustrate a case that the insulating film IL3 is a laminated film including an insulating film IL4 and an insulating film IL5 on the insulating film IL4. In this case, in Step S20, the insulating film IL4 is formed on the principal surface (on the whole principal surface) of the semiconductor substrate SB so as to cover the memory gate electrode MG, the laminated bodies LM1, LM2, LM3 and LM4, and the sidewall spacer SW, and then, the insulating film IL5 is formed on this insulating film IL4. The insulating film IL4 is preferably formed of a silicon nitride film, and the insulating film IL5 is preferably formed of a silicon oxide film. A formed film thickness (deposited film thickness) of the insulating film IL4 is smaller than a formed film thickness (deposited film thickness) of the insulating film IL5. The insulating film IL4 can be formed by using, for example, the CVD method or others, and the insulating film IL5 can be formed by, for example, using the CVD method or others.

In addition, the insulating film IL3 can be a laminated film (laminated insulating film) obtained by stacking a plurality of insulating films, or also can be a single film formed of one layer of insulating film. When the insulating film IL3 is the single film, the insulating film IL3 can be, for example, a single film of a silicon oxide film.

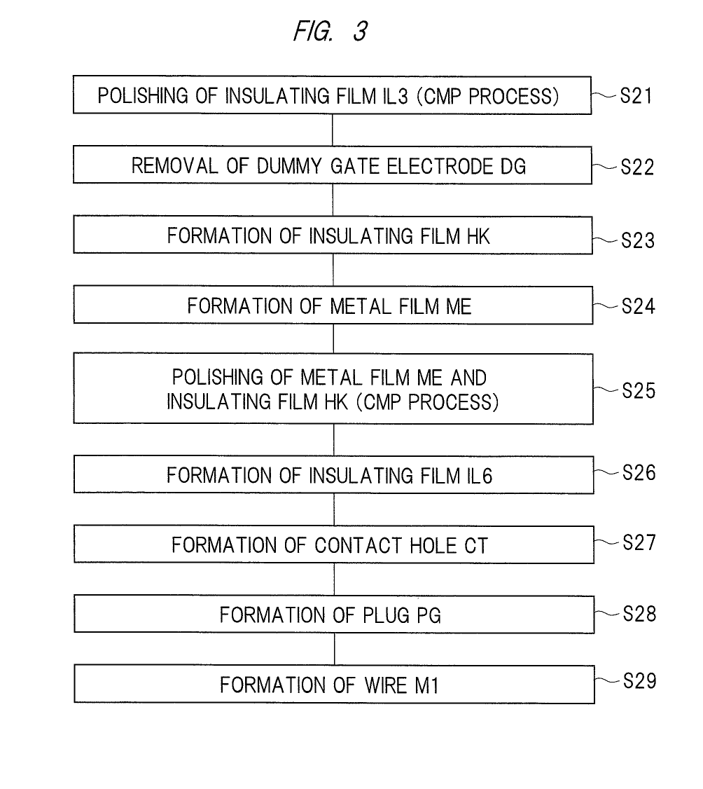

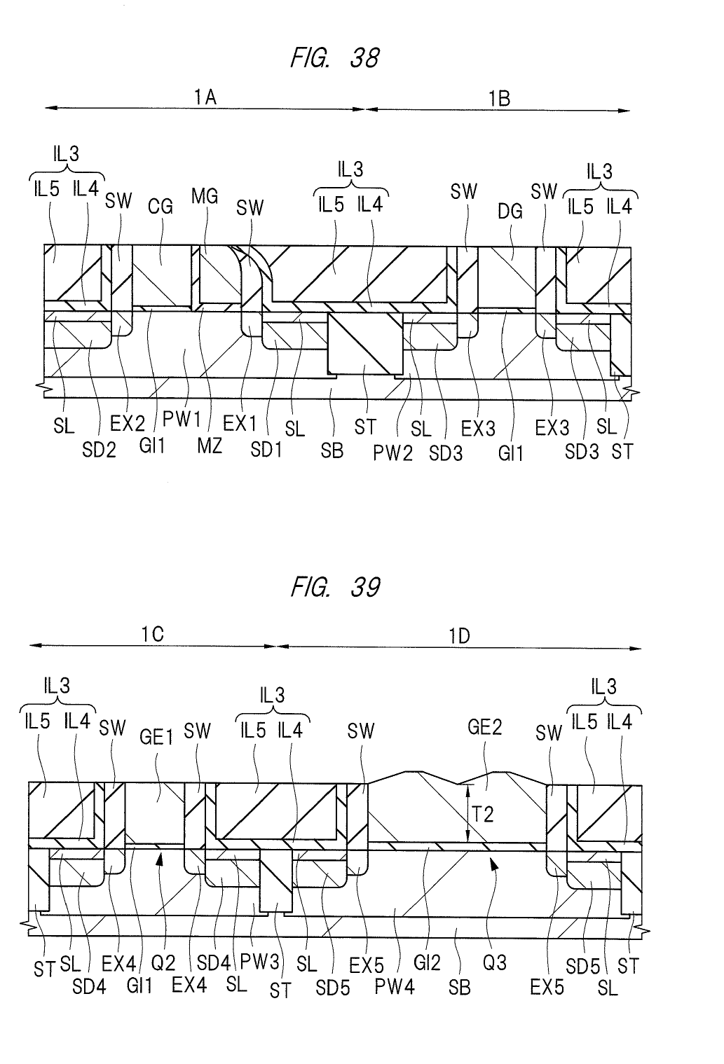

Next, an upper surface of the insulating film IL3 is polished by using a CMP (Chemical Mechanical Polishing) method or others (Step S21 of FIG. 3). By the polishing process of Step S21, an upper surface of the dummy gate electrode DG is exposed as illustrated in FIGS. 38 and 39. That is, in the polishing process of Step S21, the insulating film IL3 is polished until the upper surface of the dummy gate electrode DG is exposed.

At a stage of formation of the insulating film IL3 in Step S20, note that the upper surface of the insulating film IL3 may have surface irregularity or a level difference which is reflected by the memory gate electrode MG, the laminated bodies LM1, LM2, LM3 and LM4, the sidewall spacer SW, or others in some cases. However, the upper surface of the insulating film IL3 is flattened after the polishing process of Step S21.

A reason why the insulating film IL3 is polished at Step S21 is to expose the dummy gate electrode DG. By exposing the dummy gate electrode DG, the dummy gate electrode DG can be selectively removed and can be replaced by a below-described gate electrode GE later.

However, by polishing the insulating film IL3 for exposing the dummy gate electrode DG, the control gate electrode CG, the gate electrode GE1, and the gate electrode GE2 are also exposed. In addition, the memory gate electrode MG may be also further exposed.

That is, the dummy gate electrode DG, the control gate electrode CG, the gate electrode GE1, and the gate electrode GE2 are formed by patterning the conductive film (here, silicon film PS2) which is in the same layer as those described above. Therefore, a height of the dummy gate electrode DG, a height of the control gate electrode CG, a height of the gate electrode GE1, and a height of the gate electrode GE2 are almost the same as each other. Therefore, by polishing the insulating film IL3 until the upper surface of the dummy gate electrode DG is exposed in the polishing process of Step S21, the upper surface of the control gate electrode CG, the upper surface of the gate electrode GE1, and the upper surface of the gate electrode GE2 are also exposed.

The insulating film IL3 is formed at Step S20 in such states that the cap insulating film CP1 is formed on the control gate electrode CG, that the cap insulating film CP2 is formed on the dummy gate electrode DG, that the cap insulating film CP3 is formed on the gate electrode GE1, and that the cap insulating film CP4 is formed on the gate electrode GE2, and then, the polishing process of Step S21 is performed. Therefore, in the polishing process of Step S21, the insulating film IL3 is polished first until each upper surface of the cap insulating films CP1, CP2, CP3 and CP4 is exposed, and then, each upper surface of the dummy gate electrode DG, the control gate electrode CG, the gate electrode GE1 and the gate electrode GE2 is exposed by further etching as illustrated in FIGS. 38 and 39. When the sidewall spacer SW has been formed on the memory gate electrode MG, this sidewall spacer SW on this memory gate electrode MG may be also polished to expose the upper surface of the memory gate electrode MG in some cases. In the polishing after exposing each upper surface of the cap insulating films CP1, CP2, CP3 and CP4, not only the insulating film IL3 but also the cap insulating film CP1 on the control gate electrode CG, the cap insulating film CP2 on the dummy gate electrode DG, the cap insulating film CP3 on the gate electrode GE1, the cap insulating film CP4 on the gate electrode GE2, and the sidewall spacer SW on the memory gate electrode MG are polished.

As different from the present embodiment, there is a risk of the dishing caused on the gate electrode GE2 in a case that the polishing process of Step S21 is performed after the formation of the insulating film IL3 at Step S20 in such a state that the insulating film DB is not formed on the laminated body LM4 (the case corresponding to a studied example described below). More particularly, there is a concern about the dishing on the gate electrode GE2 when the dimension of the gate electrode GE2 (more particularly, the dimension thereof in the gate length direction) is large. On the other hand, in the present embodiment, the insulating film IL3 is formed at Step S20 in the state that the insulating film DB is partially (locally) formed on the laminated body LM4, and then, the polishing process of Step S21 is performed. Therefore, the dishing on the gate electrode GE2 can be suppressed or prevented.

That is, in the present embodiment, the insulating film DE is partially formed on the gate electrode GE2, and besides, the insulating film IL3 is polished under a condition (polishing condition) having a smaller polishing speed of the insulating film DB than a polishing speed of the insulating film IL3 in the polishing process of Step S21. That is, in Step S21, the polishing is performed under such a condition that the insulating film DB is harder to be polished than the insulating film IL3. This is because the polishing of the gate electrode GE2 is suppressed or prevented in a portion where the insulating film DE has been formed (that is, a portion positioned immediately below the insulating film DB) in the polishing process of Step S21. In this manner, even when the gate electrode GE2 is polished in the polishing process of Step S21, the polished amount of the portion positioned immediately below the insulating film DB in the gate electrode GE2 is suppressed more than that of the other portion (the polished amount thereof is reduced). Therefore, in the polishing process of Step S21, phenomena of excessive polishing on a center portion side more than an outer peripheral portion side (that is, dishing) can be suppressed or prevented in the upper surface of the gate electrode GE2. This will be described in more details later.

In addition, in the polishing process of Step S21, the condition having the smaller polishing speed of the insulating film DB than the polishing speed of the insulating film IL3 is adopted. When the insulating film IL3 is a laminated film including the insulating film IL4 and the insulating film IL5 thicker than the insulating film IL4, most of a thickness portion of the insulating film IL3 is the insulating film IL5, and the insulating film IL3 is mainly formed of the insulating film IL5. Therefore, the insulating film DB is made of a different material from the insulating film IL5, and the condition having the smaller polishing speed of the insulating film DB than the polishing speed of the insulating film IL5 is adopted in the polishing of Step S21. That is, in Step S21, the polishing is performed under a condition that the insulating film DB is harder to be polished than the insulating film IL5. The polishing speed can be controlled by, for example, polishing liquid (slurry) to be used or others.

In addition, a case that the insulating film DB and the insulating film IL4 are made of the same material (for example, silicon nitride) as each other can be also considered. However, in that case, the condition having the smaller polishing speed of the insulating film DB than the polishing speed of the insulating film IL5 is adopted in the polishing process of Step S21, so that the polishing speed of the insulating film IL4 and the polishing speed of the insulating film DB are almost the same as each other. Even in such a case, the polishing of the gate electrode GE2 in the portion where the insulating film DB has been formed (that is, the portion positioned immediately below the insulating film DB) can be suppressed or prevented in the polishing process of Step S21 as much as the portion of the insulating film DB which is harder to be polished than the insulating film IL5, so that the dishing can be suppressed or prevented in the gate electrode GE2.

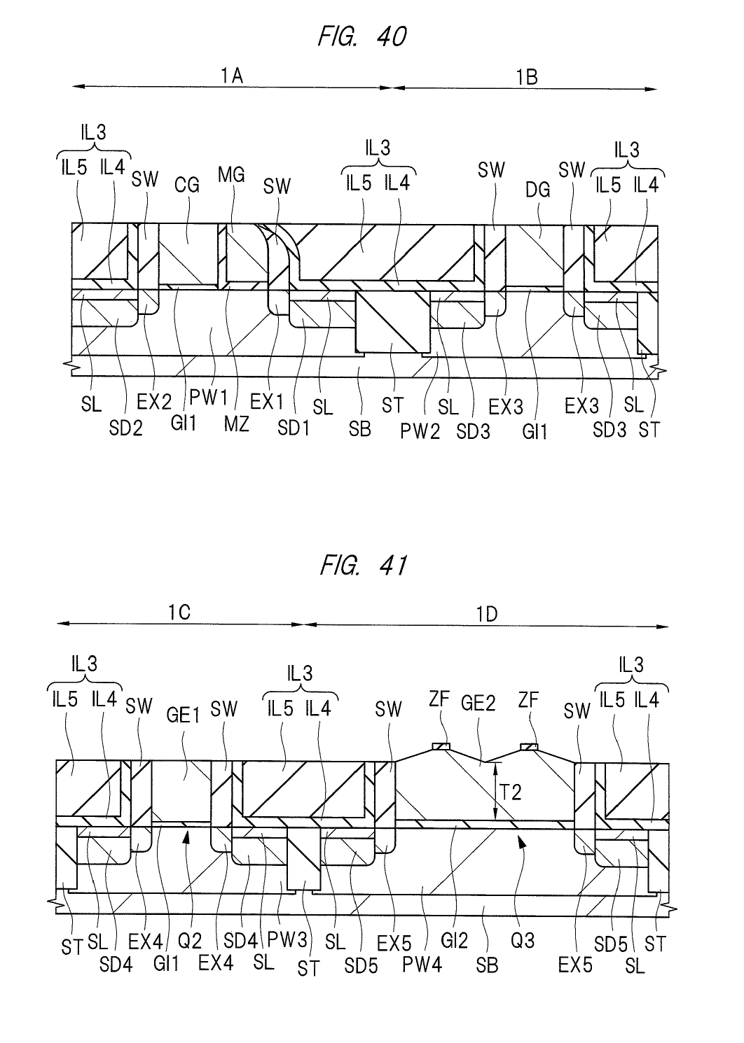

In addition, since the dummy gate electrode DG is removed later, the whole upper surface of the dummy gate electrode DG is exposed at the stage of end of the polishing process of Step S21 so that the cap insulating film CP2 is not left on the dummy gate electrode DG. However, since the polishing process of Step S21 is performed after the insulating film IL3 is formed in Step S20 in the state that the insulating film DB is partially (locally) formed on the laminated body LM4, a case that an insulating film ZF is partially (locally) left on the gate electrode GE2 at the stage of the end of the polishing process of Step S21 may be caused in exchange for the fact that the dishing can be suppressed or prevented in the gate electrode GE2. This case is illustrated in FIGS. 40 and 41.

Here, as similar to FIGS. 38 and 39, FIGS. 40 and 41 illustrate the stage of the end of the polishing process of Step S21. However, FIGS. 38 and 39 correspond to a case that the insulating film DE and the cap insulating film CP4 are not left on the gate electrode GE2 at the stage of the end of the polishing process of Step S21 so that the whole upper surface of the gate electrode GE2 is exposed. On the other hand, FIGS. 40 and 41 correspond to a case that the insulating film DB and the cap insulating film CP4 are not completely removed at the stage of the end of the polishing process of Step S21 so that the insulating film ZF is partially left on the upper surface of the gate electrode GE2. This insulating film ZF is formed of a part of the cap insulating film CP4, more specifically, formed of the cap insulating film CP4 in the portion positioned below the insulating film DB. However, this insulating film may include a part of the insulating film DB in some cases. In the case of FIGS. 40 and 41, not the whole upper surface of the gate electrode GE2 but a part of the upper surface of the gate electrode GE2 is exposed so that the upper surface of the gate electrode GE2 is not exposed in a region where the insulating film ZF is left on the upper surface of the gate electrode GE2. That is, in the case of FIGS. 40 and 41, the upper surface of the gate electrode GE2 includes a part covered by the insulating film ZF and an exposed part which is not covered by the insulating film ZF.

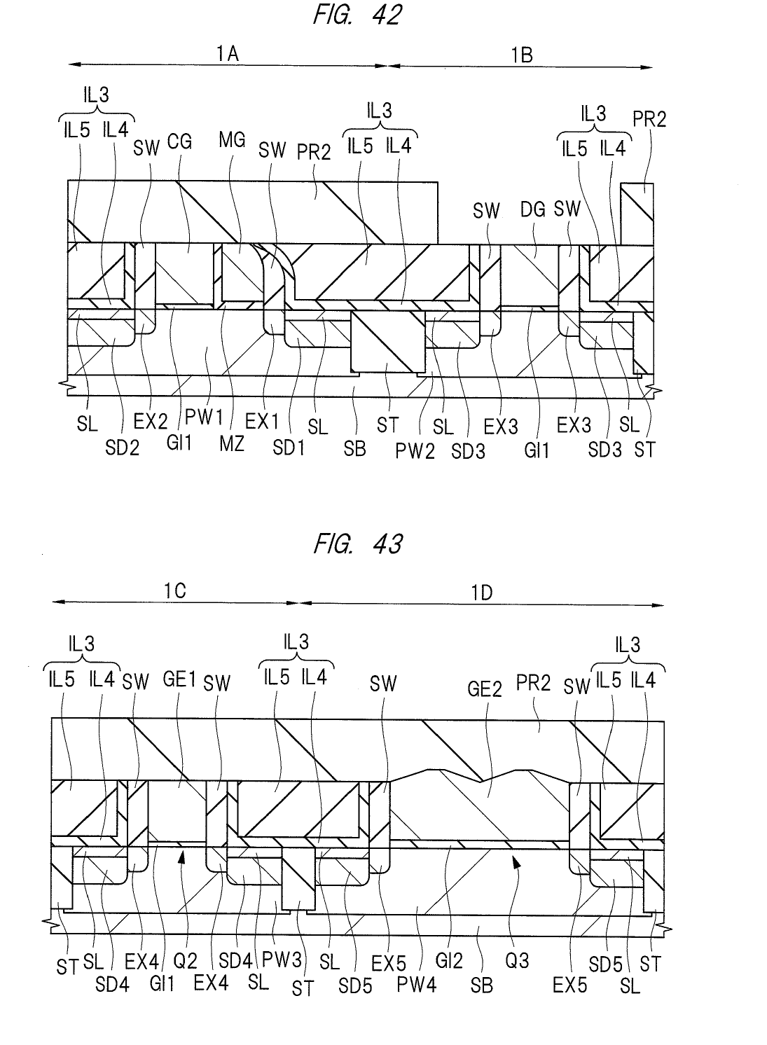

The subsequent processes (that is, processes of FIGS. 42 and 43 and the following processes) are illustrated based on the case of FIGS. 38 and 39. However, in the present embodiment, not only the case of FIGS. 38 and 39 but also the case of FIGS. 40 and 41 are allowable. A reason why the case of FIGS. 40 and 41 is also allowable is that a failure is difficult to occur even when the insulating film ZF is left on the gate electrode GE2 since the gate electrode GE2 is not removed but left to be used as the gate electrode of the transistor. However, it is common between the case of FIGS. 38 and 39 and the case of FIGS. 40 and 41 to expose the whole upper surface of the dummy gate electrode DG at the stage of the end of the polishing process of Step S21 so as not to leave the cap insulating film CP2 on the dummy gate electrode DG.

Next, the dummy gate electrode DG is etched and removed (Step S22 of FIG. 3).

In Step S22, while the dummy gate electrode DG is to be selectively etched and removed, the control gate electrode CG, the memory gate electrode MG, the gate electrode GE1 and the gate electrode GE2 are not to be removed. A removal process of the dummy gate electrode DG in Step S22 can be specifically performed as follows.

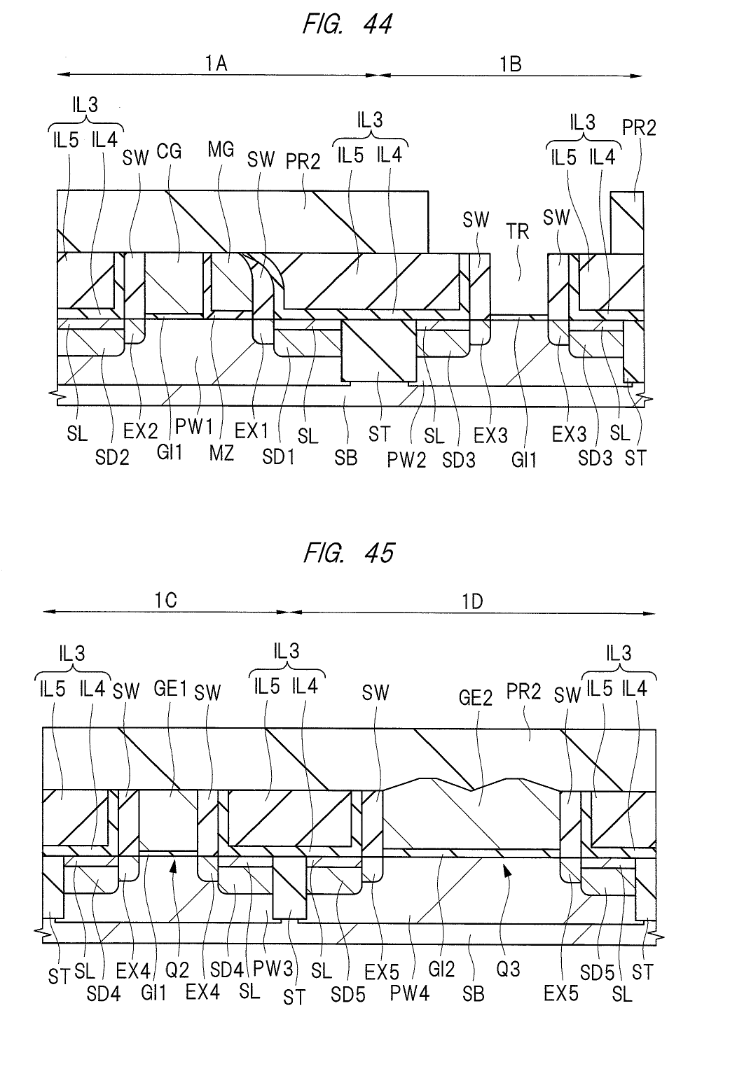

That is, as illustrated in FIGS. 42 and 43, a photoresist pattern PR2 is formed on the semiconductor substrate SB, that is, on the insulating film IL3 first as a resist pattern by using the photolithography method so as to cover the control gate electrode CG, the memory gate electrode MG, and the gate electrodes GE1 and GE2. This photoresist pattern PR2 is such a photoresist pattern as covering the control gate electrode CG, the memory gate electrode MG, the gate electrode GE1 and the gate electrode GE2 but exposing the dummy gate electrode DG. Therefore, the photoresist pattern PR2 is formed so as to cover the whole memory formation region 1A, the whole low breakdown voltage MIFET formation region 1C and the whole high breakdown voltage MISFET formation region 1D in a planar view and so as to expose the dummy gate electrode DG in the metal gate transistor formation region 1B. Then, as illustrated in FIGS. 44 and 45, the dummy gate electrode DG is etched and removed. As for this etching, the dry etching, the wet etching, or combination of both can be used. In this etching, the control gate electrode CG, the memory gate electrode MG, the gate electrode GE1 and the gate electrode GE2 are not etched but left since they are covered by the photoresist pattern PR2. After that, the photoresist pattern PR2 is removed.

By removing the dummy gate electrode DG in Step S22, a trench (recessed part, hollowed part) TR is formed. The trench TR is a region where the dummy gate electrode DG has been removed, and corresponds to a region where the dummy gate electrode DG has existed until the dummy gate electrode DG is removed. A bottom part (bottom surface) of the trench TR is formed of the upper surface of the insulating film GI1, and a sidewall (side surface) of the trench TR is formed of the side surface of the sidewall spacer SW (side surface having contacted the dummy gate electrode DG until the dummy gate electrode DG is removed).

As for an etching process of the dummy gate electrode DG in Step S22, it is preferred to perform the etching under a condition that the insulating film IL3 (insulating film IL4 and insulating film IL5), the insulating film GI1 and the sidewall spacer SW are more difficult to be etched than the dummy gate electrode DG. That is, it is preferred to perform the etching under a condition that each etching rate of the insulating film IL3 (insulating film IL4 and insulating film IL5), the insulating film GI1 and the sidewall spacer SW is smaller than an etching rate of the dummy gate electrode DG. In this manner, the dummy gate electrode DG can be selectively etched. When the dummy gate electrode DG is etched, the control gate electrode CG, the memory gate electrode MG, the gate electrode GE1 and the gate electrode GE2 are not etched in Step S22 since the control gate electrode CG, the memory gate electrode MG, the gate electrode GE1 and the gate electrode GE2 are covered by the above-described photoresist pattern PR2.

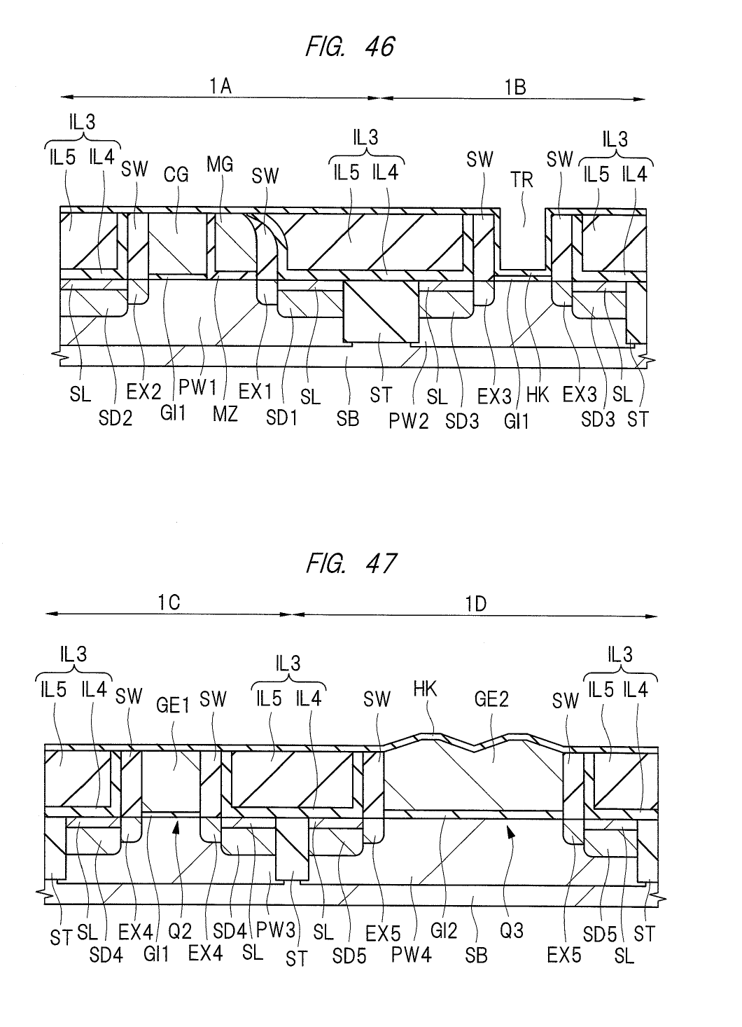

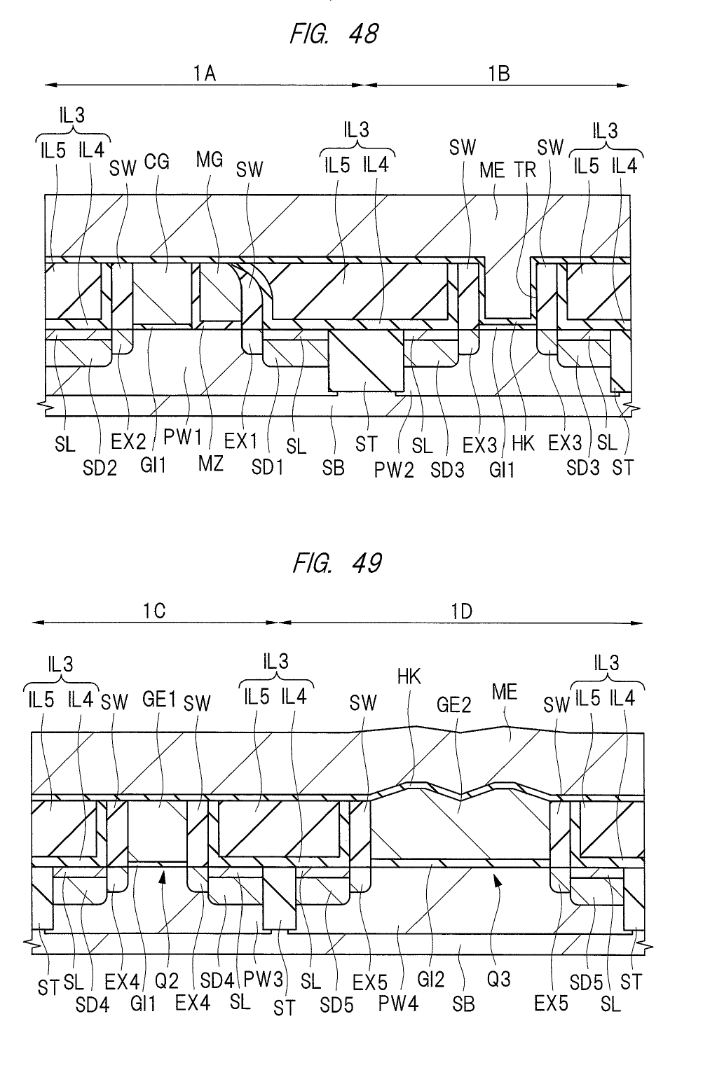

Next, as illustrated in FIGS. 46 and 47, an insulating film HK is formed on the semiconductor substrate SB, namely on the insulating film IL3 including an inside (on a bottom part and a sidewall) of the trench TR, (Step S23 of FIG. 3). Then, as illustrated in FIGS. 48 and 49, a metal film ME is formed on the semiconductor substrate SB, that is, on the insulating film HK as a conductive film so as to fill the inside of the trench TR (Step S24 of FIG. 3).

In the trench TR, although the insulating film HK is formed on the bottom part (bottom surface) of the trench TR and the sidewall (side surface) thereof in Step S23, the trench TR is not completely filled by the insulating film HK. The trench TR is completely filled by the insulating film HK and the metal film ME by forming the metal film ME in Step S24.

The insulating film HK is an insulating film for the gate insulating film, and the metal film ME is a conductive film for the gate electrode. Specifically, the insulating film HK is the insulating film for the gate insulating film of the MISFET formed in the metal gate transistor formation region 1B, and the metal film ME is the conductive film for the gate electrode of the MISFET formed in the metal gate transistor formation region 1B.

The insulating film HK is an insulating material film whose dielectric constant (relative permittivity) is higher than that of silicon nitride, that is, so-called High-k film (high dielectric constant film). Note that description of a High-k film, a high dielectric constant film, or a high dielectric constant gate insulating film in the present application means a film whose dielectric constant (relative permittivity) is higher than that of silicon nitride.

As the insulating film HK, a metal oxide film such as a hafnium oxide film, a zirconium oxide film, an aluminum oxide film, a tantalum oxide film or a lanthanum oxide film can be used, and these metal oxide films can further contain either one or both of nitrogen (N) and silicon (Si). The insulating film HK can be formed by, for example, an ALD (Atomic Layer Deposition) method or the CVD method. A physical film thickness of the gate insulating film can be increased more in a case that the high dielectric constant film (here, insulating film HK) is used for the gate insulating film than a case that the silicon oxide film is used, and therefore, an advantage of reduction in a leakage current can be obtained.

As the metal film ME, a metal film such as a titanium nitride (TiN) film, a tantalum nitride (TaN) film, a tungsten nitride (WN) film, a titanium carbide (TiC) film, a tantalum carbide (TaC) film, a tungsten carbide (WC) film, a tantalum carbonitride (TaCN) film, a titanium (Ti) film, a tantalum (Ta) film, and a titanium aluminum (TiAl) film, or an aluminum (Al) film can be used. Note that the metal film described here is referred to as a conductive film showing metal conduction, and is not only a single metal film (pure metal film) and an alloy film but also includes a metal compound film showing metal conduction (such as a nitride metal film and a carbide metal film). Therefore, the metal film ME is the conductive film showing the metal conduction which is not limited to the single metal film (pure metal film) and the alloy film, and may be the metal compound film showing the metal conduction (such as the nitride metal film and the carbide metal film). In addition, the metal film ME can be also a laminated film (a laminated film obtained by stacking a plurality of films). However, in that case, the lowest layer of the laminated film is formed of a metal film (a conductive film showing metal conduction). In addition, the laminated film can be also as a laminated film including a plurality of metal films (conductive films showing metal conduction). The metal film ME can be formed by using, for example, a sputtering method or others. In addition, as the metal film ME, a laminated film including a metal film (a conductive film showing metal conduction) and a silicon film (polycrystalline silicon film) on the metal film can be also used. A threshold voltage of the MISFET provided with the gate electrode GE3 can be controlled by a work function of a material of a part contacting the gate insulating film in the gate electrode GE3 formed later.

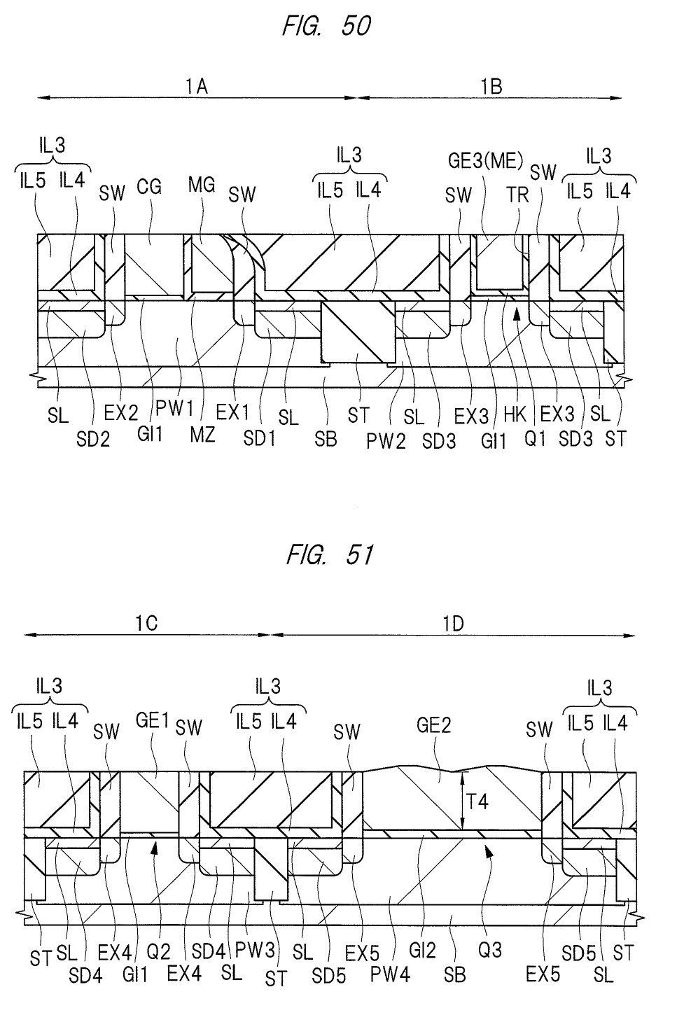

Next, as illustrated in FIGS. 50 and 51, by polishing and removing the unnecessary metal film ME and insulating film HK outside the trench TR by using the CMP method or others, the insulating film HK and the metal film ME are embedded inside the trench TR (Step S25 of FIG. 3).

That is, by polishing the metal film ME and the insulating film HK by using the CMP method or others in Step S25, the metal film ME and the insulating film HK outside the trench TR are removed, and the insulating film HK and the metal film ME are left inside the trench TR. This manner causes a state that the insulating film HK and the metal film ME are left and embedded inside the trench TR. In Step S25, by polishing the metal film ME and the insulating film HK by the polishing process such as the CMP method, the metal film ME and the insulating film HK outside the trench TR are removed.

The metal film ME embedded inside the trench TR becomes the gate electrode GE3 of the MISFET Q1, and the insulating film HK embedded inside the trench TR functions as the gate insulating film of the MISFET Q1.

In the present embodiment, the dummy gate electrode DG is removed and replaced by the gate electrode GE3, and this gate electrode GE3 is used as the gate electrode of the MISFET Q1 in the metal gate transistor formation region 1B. Therefore, the dummy gate electrode DG is a dummy gate electrode (a virtual gate electrode), and can be regarded as a replacement gate electrode or a gate electrode for replacement, and the gate electrode GE3 can be regarded as the gate electrode which configures the MISFET.

In addition, since the gate electrode GE3 is formed by using the metal film ME, the gate electrode GE3 can be used as the metal gate electrode. By using the gate electrode GE3 as the metal gate electrode, such an advantage as suppression of a depletion phenomenon of the gate electrode GE3 so as to remove a parasitic capacitance can be obtained. In addition, such an advantage that the MISFET element can be downsized (the gate insulating film can be thinned) is also obtained.

The insulating film HK is formed on the bottom part (bottom surface) of the trench TR and the sidewall thereof, and the bottom part (bottom surface) of the gate electrode GE3 and the sidewall (side surface) thereof are adjacent to the insulating film HK. The insulating film GI1 and the insulating film HK are interposed between the gate electrode GE3 and the semiconductor substrate SB (p-type well PW2), and the insulating film HK is interposed between the gate electrode GE3 and the sidewall spacer SW. While the insulating films GI1 and HK immediately below the gate electrode GE3 function as the gate insulating films of the MISFET Q1, the insulating film HK functions as the high dielectric constant gate insulating film because of a high dielectric constant film.

If the unnecessary metal film ME outside the trench TR is left, there is a concern about reduction in the reliability of the manufactured semiconductor device because the residual part has conductivity. Therefore, in the polishing process of Step S25, the residual of the polishing of the metal film ME should not to occur outside the trench TR.

In addition, by performing the polishing process of Step S25, the metal film ME and the insulating film HK are removed also on the control gate electrode CG, the memory gate electrode MG, the gate electrode GE1, and the gate electrode GE2. Therefore, the upper surface of the control gate electrode CG, the upper surface of the gate electrode GE1, and the upper surface of the gate electrode GE2 are exposed. Moreover, the memory gate electrode MG may be exposed in some cases.

In addition, the present embodiment describes the case that the dummy gate electrode DG is etched and removed in Step S22, and then, the insulating film HK is formed in Step S23 without removing the insulating film GI1 on the bottom part of the trench TR. In this case, the insulating film GI1 is interposed as an interfacial layer (on an interface) between the insulating film HK and the semiconductor substrate SB (p-type well PW2) in the metal gate transistor formation region 1B. As the insulating film GI1 serving as the interfacial layer, a silicon oxide film or a silicon oxynitride film is preferred.

As another embodiment, the insulating film GI1 on the bottom part of the trench TR can be removed after etching and removing the dummy gate electrode DG in Step S22 but before forming the insulating film HK in Step S23. In this case, it is more preferred to form the interfacial layer formed of the silicon oxide film or the silicon oxynitride film on the surface of the semiconductor substrate SB (p-type well PW2) exposed from the bottom part of the trench TR after removing the insulating film GI1 on the bottom part of the trench TR, and then, form the insulating film HK in Step S23. In this manner, the interfacial layer formed of the silicon oxide film or the silicon oxynitride film is interposed (on the interface) between the insulating film HK and the semiconductor substrate SB (p-type well PW2) in the metal gate transistor formation region 1B.

The following advantages can be obtained when the interfacial layer formed of the thin silicon oxide film or silicon oxynitride film is provided on the interface between the insulating film HK and the semiconductor substrate SB (p-type well PW2) in the metal gate transistor formation region 1B without forming the insulating film HK which is the high dielectric constant film directly on the surface (silicon surface) of the semiconductor substrate SB (p-type well PW2) in the metal gate transistor formation region 1B. That is, the number of defects such as a trap level is reduced by forming a SiO₂/Si (alternatively, SiON/Si) structure for the interface between the gate insulating film and (the silicon surface of) the semiconductor substrate in the MISFET formed in the metal gate transistor formation region 1B, so that driving ability and reliability can be enhanced.

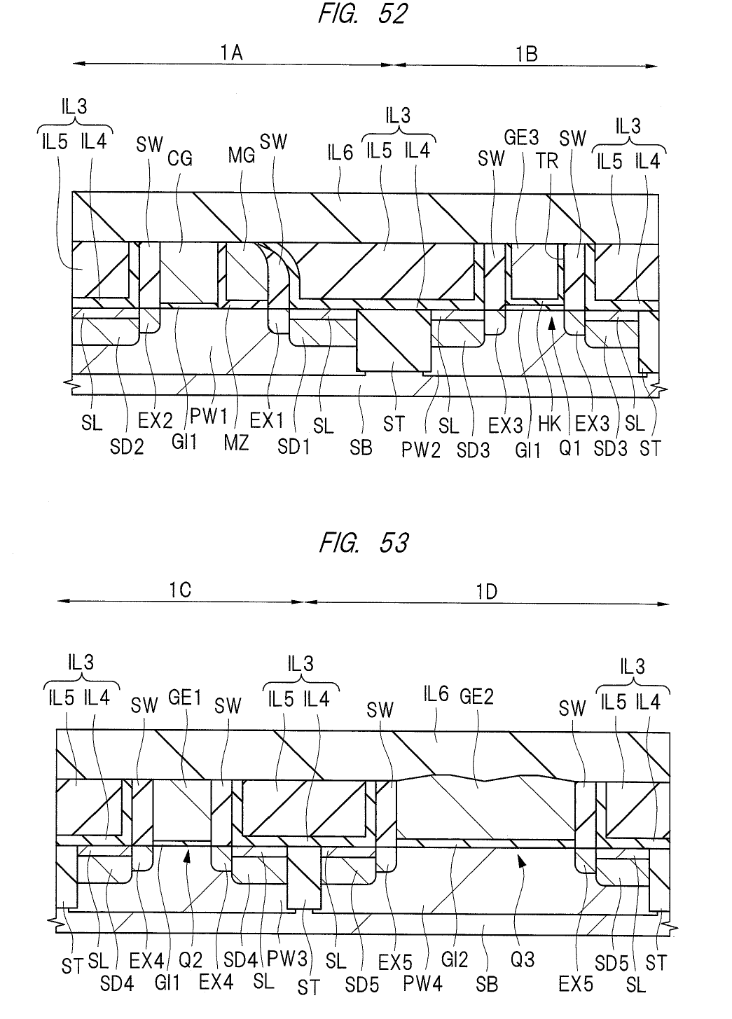

Next, as illustrated in FIGS. 52 and 53, an insulating film (interlayer insulating film) IL6 is formed on the semiconductor substrate SB (Step S26 of FIG. 3).

The insulating film IL6 can be formed of, for example, a silicon oxide film or others by using the CVD method or others. Since the insulating film IL6 is formed on the whole principal surface of the semiconductor substrate SB, the insulating film is formed on the insulating film IL3 so as to cover the control gate electrode CG, the memory gate electrode MG and the gate electrodes GE1, GE2 and GE3.

By polishing an upper surface of the insulating film IL6 or others by using the CMP method after forming the insulating film IL6, flatness of the upper surface of the insulating film IL6 can be also enhanced.

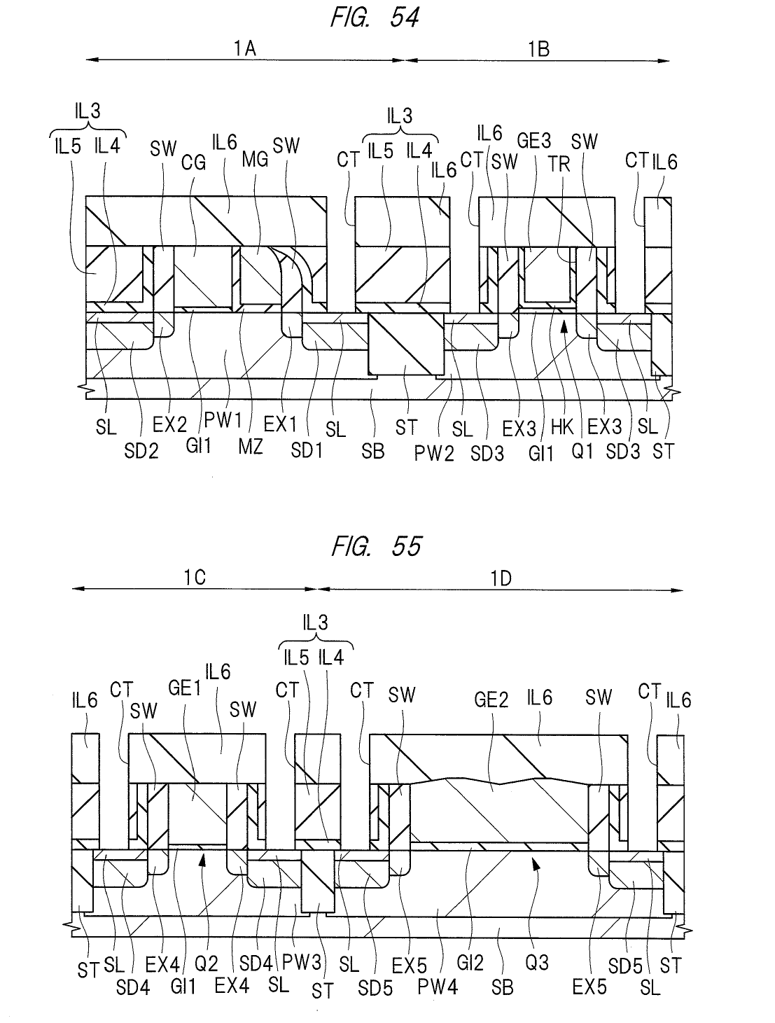

Next, the insulating film IL6 and the insulating film IL3 are dry-etched by using the photoresist pattern (not illustrated) formed by the photolithography method on the insulating film IL6 as an etching mask, so that a contact hole (opening part, through-hole) CT is formed in the insulating film IL6 and the insulating film IL3 as illustrated in FIGS. 54 and 55 (Step S27 of FIG. 3).

The contact holes CT formed on the n⁺-type semiconductor regions SD1, SD2, SD3, SD4, and SD5 are formed so as to penetrate through the insulating film IL6 and the insulating film IL3. In addition, contact holes CT formed on the control gate electrode CG, the memory gate electrode MG, and the gate electrodes GE1, GE2 and GE3 are formed so as to penetrate through the insulating film IL6 although not illustrated.

When the insulating film IL3 is formed of a laminated film including the insulating film IL4 and the insulating film IL5, the insulating film IL4 can be also used as an etching stopper film when the contact hole CT is formed. In this case, the contact hole CT can be formed as follows. That is, the above-described photoresist pattern (not illustrated) to be used as an etching mask is formed on the insulating film IL6 by using the photolithography method. Then, first, the insulating film IL6 and the insulating film IL5 are dry-etched under such a condition that the insulating film IL5 and the insulating film IL6 which are the silicon oxide film are easier to be etched than the insulating film IL4 which is the silicon nitride film, and the insulating film IL4 is functioned as the etching stopper film, so that the contact hole CT is formed in the insulating film IL6 and the insulating film IL5. Then, by dry-etching and removing the insulating film IL4 on the bottom part of the contact hole CT under such a condition that the insulating film IL4 is easier to be etched than the insulating film IL6 and the insulating film IL5, the contact hole CT serving as a through hole is formed. By functioning the insulating film IL4 as the etching stopper film when the contact hole CT is formed, too much digging of the contact hole CT and damage of the substrate can be suppressed or prevented.

The metal silicide layer SL on the n⁺-type semiconductor region SD1 is exposed from the bottom part of the contact hole CT formed on the upper part of the n⁺-type semiconductor region SD1, and the metal silicide layer SL on the n⁺-type semiconductor region SD2 is exposed from the bottom part of the contact hole CT formed on the upper part of the n⁺-type semiconductor region SD2. In addition, the metal silicide layer SL on the n⁺-type semiconductor region SD3 is exposed from the bottom part of the contact hole CT formed on the upper part of the n⁺-type semiconductor region SD3, and the metal silicide layer SL on the n⁺-type semiconductor region SD4 is exposed from the bottom part of the contact hole CT formed on the upper part of the n⁺-type semiconductor region SD4. In addition, the metal silicide layer SL on the n⁺-type semiconductor region SD5 is exposed from the bottom part of the contact hole CT formed on the upper part of the n⁺-type semiconductor region SD5.

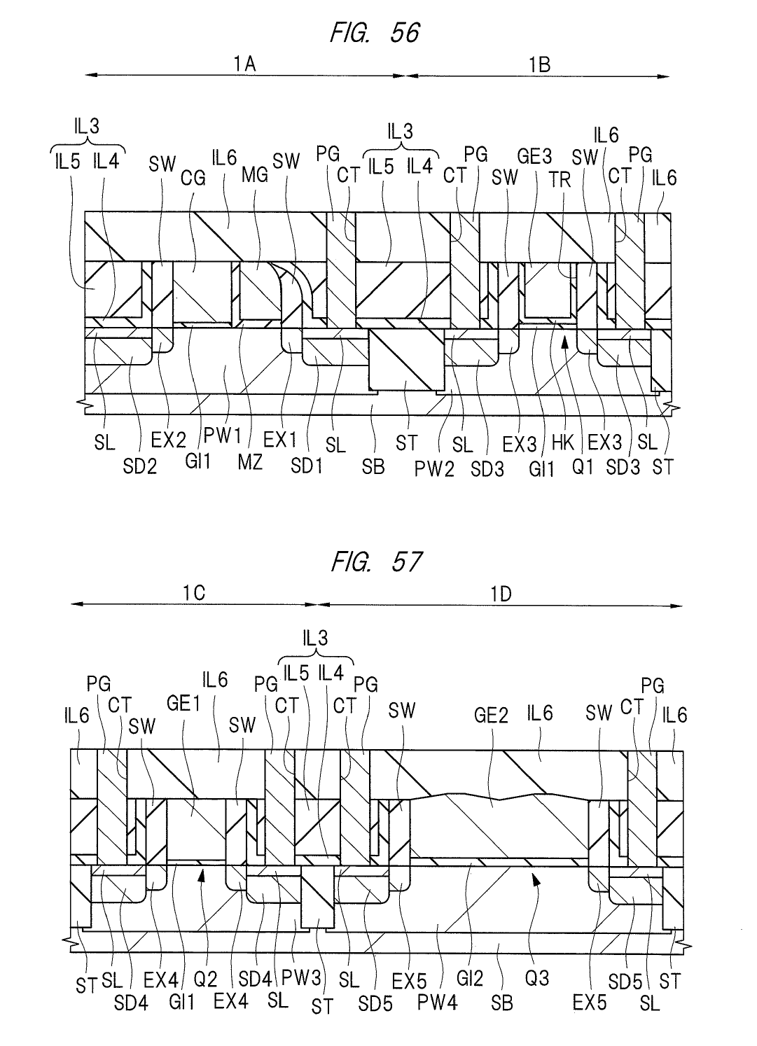

Next, as illustrated in FIGS. 56 and 57, a conductive plug PG made of tungsten (W) or others is formed inside the contact hole CT as a conductor part for connection (Step S28 of FIG. 3).

For forming the plug PG, for example, a barrier conductor film (for example, a titanium film, a titanium nitride film, or a laminated film of them) is formed on the insulating film IL6 including the inside (on the bottom part and the sidewall) of the contact hole CT. Then, a main conductor film formed of a tungsten film or others is formed on this barrier conductor film so as to fill the contact hole CT. Then, the unnecessary main conductor film and barrier conductor film outside the contact hole CT by using the CMP method, an etch back method, or others are removed so as to form the plug PG formed of the main conductor film and the barrier conductor film which are embedded and left inside the contact hole CT. Note that FIGS. 56 and 57 illustrate the barrier conductor film and the main conductor film (tungsten film) forming the plug PG so as to be an integral form for simplification of drawings.

The contact hole CT and the plug PG embedded therein are formed on the upper part of the n⁺-type semiconductor regions SD1, SD2, SD3, SD4 and SD5, the control gate electrode CG, the memory gate electrode MG, the gate electrode GE1, the gate electrode GE2 and the gate electrode GE3 or others. From the bottom part of contact hole CT, a part of the principal surface of the semiconductor substrate SB, a part of, for example, (the metal silicide layers SL on the surfaces of) the n⁺-type semiconductor regions SD1, SD2, SD3, SD4 and SD5, a part of the control gate electrode CG, a part of the memory gate electrode MG, a part of the gate electrode GE1, and a part of the gate electrode GE2, a part of the gate electrode GE3, or others, is exposed. Note that FIGS. 56 and 57 illustrate cross-sectional views in which a part of (the metal silicide layers SL on the surfaces of) the n⁺-type semiconductor regions SD1, SD2, SD3, SD4 and SD5 is exposed from the bottom part of the contact hole CT, and is electrically connected with the plug PG which is embedded in the contact hole CT.

Next, a wiring (wiring layer) M1 which is the first-layer wiring is formed on the insulating film IL6 in which the plug PG is embedded (Step S29 of FIG. 3). A case that this wiring M1 is formed by using a damascene technique (here, single damascene technique) will be described.

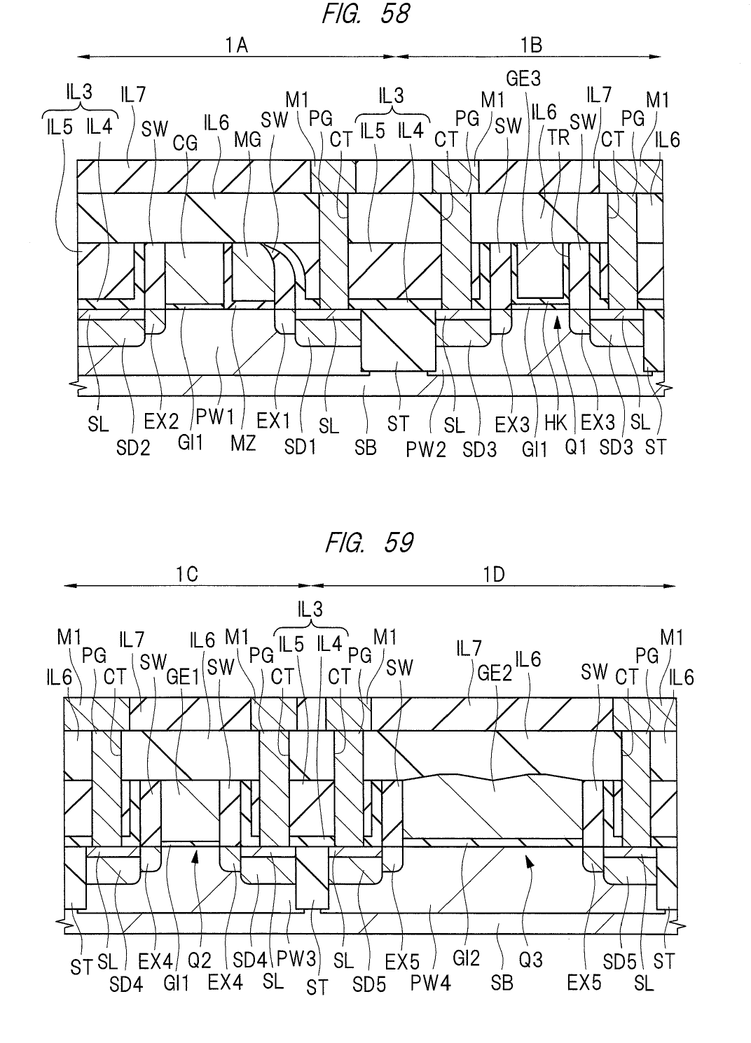

First, as illustrated in FIGS. 58 and 59, an insulating film IL7 is formed on the insulating film IL6 in which the plug PG is embedded. The insulating film IL7 can be also formed of a laminated film including a plurality of insulating films. Then, a wiring trench (trench for wiring) is formed in a predetermined region of the insulating film IL7 by the dry etching using a photoresist pattern (not illustrated) as an etching mask, and then, a barrier conductor film (for example, a titanium nitride film, a tantalum film, a tantalum nitride film, or others) is formed on the insulating film IL7 including on a bottom part of the wiring trench and a sidewall thereof. Then, a copper seed layer is formed on the barrier conductor film by the CVD method, the sputtering method, or others, and further, a copper plating film is formed on the seed layer by using an electrolytic plating method or others, so that the inside of the wiring trench is filled by the copper plating film. Then, the main conductor film (the copper plating film and the seed layer) and the barrier conductor film in a region except for the wiring trench are removed by the CMP method so as to form the first-layer wiring M1 containing the copper embedded in the wiring trench as a main conductive material. FIGS. 58 and 59 illustrate the wiring M1 so that the barrier conductor film, the seed layer, and the copper plating film are in an integral form for simplification of drawings.

The wiring M1 is electrically connected via the plug PG with the n⁺-type semiconductor region SD1, the n⁺-type semiconductor region SD2, the n⁺-type semiconductor region SD3, the n⁺-type semiconductor region SD4, the n⁺-type semiconductor region SD5, the control gate electrode CG, the memory gate electrode MG, the gate electrode GE1, the gate electrode GE2, the gate electrode GE3, or others. After that, the second- or subsequent-layer wiring is formed by a dual damascene method or others. However, illustration and description thereof are omitted here. In addition, the wiring M1 and the upper-layer wiring are not limited to the damascene wiring, and can be also formed by patterning a conductor film for wiring so as to form, for example, a tungsten wiring, an aluminum wiring, or others.

As described above, the semiconductor device of the present embodiment is manufactured.

<Regarding Structure of Semiconductor Device>

Next, a structure of the semiconductor device of the present embodiment will be described.

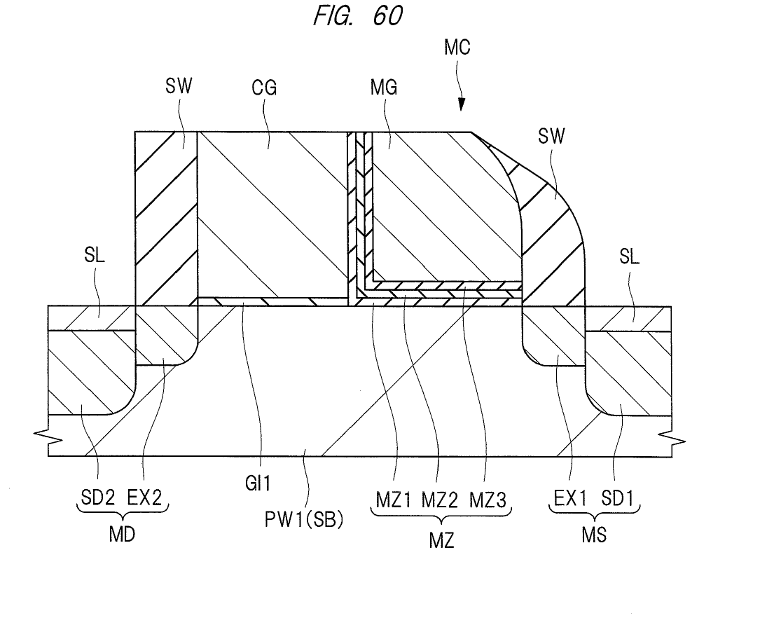

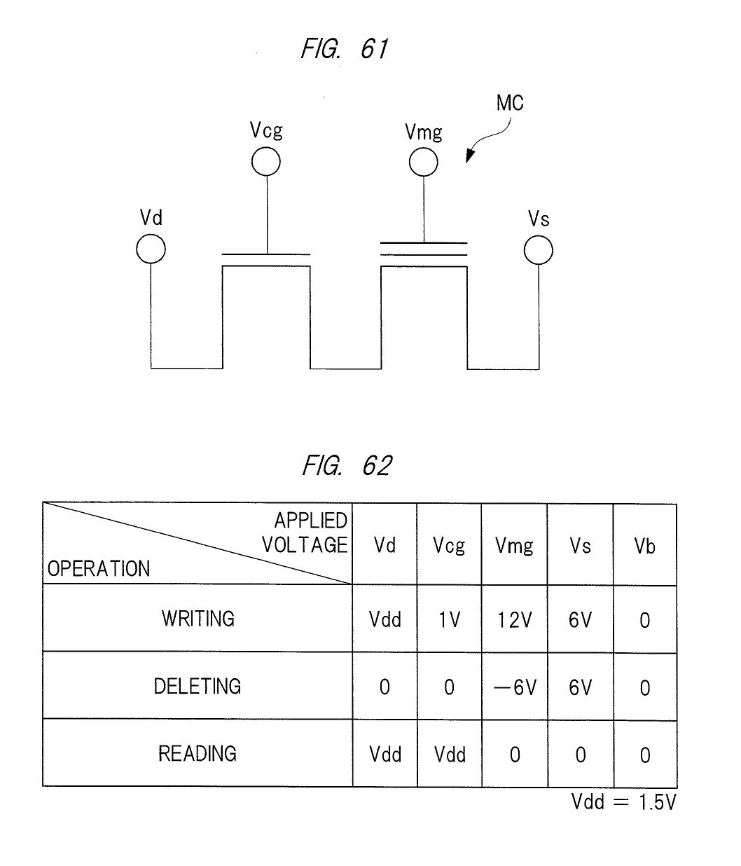

First, a configuration example of a memory cell of a nonvolatile memory in the semiconductor device of the present embodiment will be described with reference to FIGS. 60 and 61.

FIG. 60 is a cross-sectional view of a principal part of the semiconductor device of the present embodiment, and illustrates the cross-sectional view of the principal part of the memory formation region 1A. FIG. 61 is an equivalent circuit diagram of the memory cell. In FIG. 60, note that the illustration of the insulating film IL3, the insulating film IL6, the contact hole CT, the plug PG, and the wiring M1 in the structure of FIG. 58 described above is omitted for simplification of the drawing.

As illustrated in FIG. 60, the memory cell MC of the nonvolatile memory formed of a memory transistor and a control transistor is formed on the semiconductor substrate SB in the above-described memory formation region 1A. Practically, on the semiconductor substrate SB in the memory formation region 1A, a plurality of memory cells MC are formed in an array form.

As illustrated in FIGS. 60 and 61, the memory cell MC of the nonvolatile memory is a split-gate type memory cell which is obtained by connecting two MISFETs of the control transistor having the control gate electrode CG and the memory transistor having the memory gate electrode MG.

Here, the MISFET provided with the gate insulating film including the charge storage part (charge storage layer) and the memory gate electrode MG is referred to as the memory transistor, and the MISFET provided with the gate insulating film and the control gate electrode CG is referred to as the control transistor. Therefore, the memory gate electrode MG is a gate electrode of the memory transistor, and the control gate electrode CG is a gate electrode of the control transistor, and the control gate electrode CG and the memory gate electrode MG are gate electrodes forming the memory cell of the nonvolatile memory.

Note that the control transistor is a transistor for selecting the memory cell, and therefore, can be regarded also as a selective transistor. Therefore, the control gate electrode CG can also be regarded as a selective gate electrode. The memory transistor is a transistor for memory.

Hereinafter, a configuration of the memory cell MC will be specifically described.

As illustrated in FIG. 60, the memory cell MC of the nonvolatile memory includes: the n-type semiconductor regions MS and MD for the source and drain formed inside the p-type well PW1 of the semiconductor substrate SB; the control gate electrode CG formed on the upper part of the semiconductor substrate SB (p-type well PW1); and the memory gate electrode MG formed on the upper part of the semiconductor substrate SB (p-type well PW1) so as to be adjacent to the control gate electrode CG. Then, the memory cell MC of the nonvolatile memory further includes: the insulating film (gate insulating film) GI1 formed between the control gate electrode CG and the semiconductor substrate SB (p-type well PW1); and the insulating films MZ formed between the memory gate electrode MG and the semiconductor substrate SB (p-type well PW1) and between the memory gate electrode MG and the control gate electrode CG.

The control gate electrode CG and the memory gate electrode MG are extended along the principal surface of the semiconductor substrate SB so as to be next to each other in a state that the insulating film MZ is interposed between their facing side surfaces. The control gate electrode CG and the memory gate electrode MG are formed via the insulating film GI1 or the insulating film MZ on the upper part of the semiconductor substrate SB (p-type well PW1) between the semiconductor region MD and the semiconductor region MS so that the memory gate electrode MG is positioned on the semiconductor region MS side and so that the control gate electrode CG is positioned on the semiconductor region MD side. However, the control gate electrode CG is formed on the semiconductor substrate SB via the insulating film GI1, and the memory gate electrode MG is formed thereon via the insulating film MZ.

The control gate electrode CG and the memory gate electrode MG are adjacent to each other so as to interpose the insulating film MZ between them. The insulating film MZ extends over both regions of a region between the memory gate electrode MG and the semiconductor substrate SB (p-type well PW1) and a region between the memory gate electrode MG and the control gate electrode CG.

The insulating film GI1 formed between the control gate electrode CG and the semiconductor substrate SB (p-type well PW1), that is, the insulating film GI1 below the control gate electrode CG functions as the gate insulating film of the control transistor. In addition, the insulating film MZ between the memory gate electrode MG and the semiconductor substrate SB (p-type well PW1), that is, the insulating film MZ below the memory gate electrode MG functions as the gate insulating film (the gate insulating film having the charge storage part inside) of the memory transistor. Note that, while the insulating film MZ between the memory gate electrode MG and the semiconductor substrate SB (p-type well PW1) functions as the gate insulating film of the memory transistor, the insulating film MZ between the memory gate electrode MG and the control gate electrode CG functions as an insulating film for insulating (electrically separating) the memory gate electrode MG from the control gate electrode CG.

The silicon nitride film MZ2 of the insulating films MZ is an insulating film for storing electric charge, and functions as the charge storage layer (charge storage part). That is, the silicon nitride film MZ2 is a trapping insulating film formed inside the insulating film MZ. Therefore, the insulating film MZ can be regarded as an insulating film having the charge storage part (the silicon nitride film MZ2 here) inside.

The silicon oxide film MZ3 and the silicon oxide film MZ1 which are positioned above and below the silicon nitride film MZ2 can function as a charge capture layer or a charge trap layer. The electric charge can be accumulated in the silicon nitride film MZ2 by interposing the silicon nitride film MZ2 between the silicon oxide film MZ3 and the silicon oxide film MZ1 in the insulating film MZ between the memory gate electrode MG and the semiconductor substrate SB.

Each of the semiconductor region MS and the semiconductor region MD is the semiconductor region for the source or the drain. That is, the semiconductor region MS is a semiconductor region which functions as either one of a source region and a drain region, and the semiconductor region MD is a semiconductor region which functions as the other of the source region and the drain region. Here, the semiconductor region MS is the semiconductor region which functions as the source region, and the semiconductor region MD is the semiconductor region which functions as the drain region. Each of the semiconductor regions MS and MD is formed of a semiconductor region to which an n-type impurity is introduced, and is provided with a LDD structure. That is, the semiconductor region MS for the source has an n⁻-type semiconductor region EX1 (extension region) and an n⁺-type semiconductor region SD1 (source region) which has an impurity concentration higher than that of the n⁻-type semiconductor region EX1. In addition, the semiconductor region MD for the drain has an n⁻-type semiconductor region EX2 (extension region) and an n⁺-type semiconductor region SD2 (drain region) which has an impurity concentration higher than that of the n⁻-type semiconductor region EX2.

The semiconductor region MS is formed on the semiconductor substrate SB at a position adjacent to the memory gate electrode MG in the gate length direction (the gate length direction of the memory gate electrode MG). In addition, the semiconductor region MD is formed on the semiconductor substrate SB at a position adjacent to the control gate electrode CG in the gate length direction (the gate length direction of the control gate electrode CG).

The sidewall spacer SW made of the insulator (insulating film) is formed on sidewalls of the memory gate electrode MG and the control gate electrode CG on sides not adjacent to each other.

The n⁻-type semiconductor region EX1 of the source part is formed in self alignment with respect to the memory gate electrode MG, and the n⁺-type semiconductor region SD1 is formed in self alignment with respect to the sidewall spacer SW on the sidewall of the memory gate electrode MG. Therefore, in the manufactured semiconductor device, the n⁻-type semiconductor region EX1 having a low concentration is formed below the sidewall spacer SW on the sidewall of the memory gate electrode MG, and the n⁺-type semiconductor region SD1 having a high concentration is formed at outside of the n⁻-type semiconductor region EX1 having a low concentration. Therefore, the n⁻-type semiconductor region EX1 having the low concentration is formed so as to be adjacent to a channel region of the memory transistor, and the n⁺-type semiconductor region SD1 having the high concentration is formed so as to be adjacent to the n⁻-type semiconductor region EX1 having the low concentration and so as to be separated as much as the n⁻-type semiconductor region EX1 from the channel region of the memory transistor.

The n⁻-type semiconductor region EX2 of the drain part is formed in self alignment with respect to the control gate electrode CG, and the n⁺-type semiconductor region SD2 is formed in self alignment with respect to the sidewall spacer SW on the sidewall of the control gate electrode CG. Therefore, in the manufactured semiconductor device, the n⁻-type semiconductor region EX2 having a low concentration is formed below the sidewall spacer SW on the sidewall of the control gate electrode CG, and the n⁺-type semiconductor region SD2 having a high concentration is formed at outside of the n⁻-type semiconductor region EX2 having a low concentration. Therefore, the n⁻-type semiconductor region EX2 having the low concentration is formed so as to be adjacent to a channel region of the control transistor, and the n⁺-type semiconductor region SD2 having the high concentration is formed so as to be adjacent to the n⁻-type semiconductor region EX2 having the low concentration and so as to be separated as much as the n⁻-type semiconductor region EX2 from the channel region of the control transistor.

The channel region of the memory transistor is formed below the insulating film MZ below the memory gate electrode MG, and the channel region of the control transistor is formed below the insulating film GI1 below the control gate electrode CG.

On the upper parts of the n⁺-type semiconductor regions SD1 and SD2, the metal silicide layer SL is formed by the salicide technique or others.

In addition, although illustration is omitted in FIG. 60, the above-described insulating films IL3 and IL6 are formed as the insulating films on the semiconductor substrate SB so as to cover the control gate electrode CG, the memory gate electrode MG, and the sidewall spacer SW as illustrated in above-described FIG. 58. Then, the above-described contact hole CT is formed in the insulating film IL6 and the insulating film IL3, and the above-described plug PG is embedded inside the contact hole CT. The above-described insulating film IL7 and the above-described wiring M1 are formed on the insulating film IL6 in which the plug PG is embedded.

In addition, in the semiconductor device of the present embodiment, the MISFET Q1 having the gate electrode GE3 is formed in the metal gate transistor formation region 1B as illustrated in above-described FIG. 58. This gate electrode GE is the metal gate electrode. As described above, by removing the dummy gate electrode DG formed of the silicon film PS1 and embedding the metal film ME in the removed part, the gate electrode GE3 which is the metal gate electrode is formed. The gate electrode GE3 is formed via the gate insulating films (here, the insulating film GI1 and the insulating film HK) on the semiconductor substrate SB (p-type well PW2). The source/drain region of the MISFET Q1 having the gate electrode GE3 is formed of the above-described n⁻-type semiconductor region EX3 and the n⁺-type semiconductor region SD3 having the higher impurity concentration than that of the n⁻-type semiconductor region EX3, and the insulating film GI1 and the insulating film HK below the gate electrode GE function as the gate insulating film of the MISFET Q1. Since the insulating film HK is the high dielectric constant film, the gate insulating film of the MISFET Q1 is the gate insulating film having the high dielectric constant.

In addition, in the semiconductor device of the present embodiment, the MISFET Q2 having the gate electrode GE1 is formed in the low breakdown voltage MISFET formation region 1C as illustrated in above-described FIG. 59. This gate electrode GE1 is formed of the silicon film PS1 used for forming the control gate electrode CG and the gate electrode GE2. Therefore, the gate electrode GE1 is formed of the conductive film (here, silicon film PS1) which is in the same layer as the control gate electrode CG and the gate electrode GE2. The gate electrode GE1 is formed via the gate insulating film (here, insulating film GI1) on the semiconductor substrate SB (p-type well PW3). The source/drain region of the MISFET Q2 having the gate electrode GE1 is formed of the above-described n⁻-type semiconductor region EX4 and the n⁺-type semiconductor region SD4 having the higher impurity concentration than that of the n⁻-type semiconductor region EX4, and the insulating film GI1 below the gate electrode GE1 functions as the gate insulating film of the MISFET Q2.

In addition, in the semiconductor device of the present embodiment, the MISFET Q3 having the gate electrode GE2 is formed in the high breakdown voltage MISFET formation region 1D as illustrated in above-described FIG. 59. This gate electrode GE2 is formed of the silicon film PS1 used for forming the control gate electrode CG and the gate electrode GE1. Therefore, the gate electrode GE2 is formed of the conductive film (here, silicon film PS1) which is in the same layer as the control gate electrode CG and the gate electrode GE1. The gate electrode GE2 is formed via the gate insulating film (here, insulating film GI2) on the semiconductor substrate SB (p-type well PW4). The source/drain region of the MISFET Q3 having the gate electrode GE2 is formed of the above-described n⁻-type semiconductor region EX5 and the n⁺-type semiconductor region SD5 having the higher impurity concentration than that of the n⁻-type semiconductor region EX5, and the insulating film GI2 below the gate electrode GE2 functions as the gate insulating film of the MISFET Q3.

A gate length of the gate electrode GE2 is larger than each gate length of the gate electrode GE1, the gate electrode GE3 and the control gate electrode CG. That is, a dimension (L4) of the gate electrode GE2 in a gate length direction is larger than a dimension (L3) of the gate electrode GE1 in a gate length direction, a dimension of the gate electrode GE3 in a gate length direction, and a dimension (L1) of the control gate electrode CG in a gate length direction.

<Regarding Operation of Nonvolatile Memory>

Next, an operation example of the nonvolatile memory will be described with reference to FIG. 62.

FIG. 62 is a table illustrating one example of a condition of voltage application to each part of the selection memory cell in “writing”, “deleting” and “reading” in the present embodiment. In the table of FIG. 62, a voltage “Vmg” applied to the memory gate electrode MG in the memory cell (selection memory cell) as illustrated in FIGS. 60 and 61, a voltage “Vs” applied to the source region (semiconductor region MS), a voltage “Vcg” applied to the control gate electrode CG, a voltage “Vd” applied to the drain region (semiconductor region MD), and a voltage “Vb” applied to the p-type well PW1 are shown for each of the “writing”, the “deleting” and the “reading”. Note that the example illustrated in the table of FIG. 62 is one preferable example of the voltage applying condition, and therefore, is not limited to this, and can be variously modified if needed. In addition, in the present embodiment, injection of electrons to the silicon nitride film MZ2 which is the charge storage layer (charge storage part) in the insulating film MZ of the memory transistor is defined as the “writing”, and injection of holes (electron holes) thereto is defined as the “deleting”.

As for a method for the writing, a writing method (hot electron injection writing method) which is so-called SSI (Source Side Injection) method of writing by hot electron injection based on source side injection can be used. The writing is performed by applying, for example, the voltage as shown in a “writing” section of FIG. 62 to each part of the selection memory cell to be written, and injecting electrons into the silicon nitride film MZ2 in the insulating film MZ of the selection memory cell. In this case, hot electrons are generated in the channel region (between the source and the drain) below the part between two gate electrodes (between the memory gate electrode MG and the control gate electrode CG), and the hot electrons are injected into the silicon nitride film MZ2 which is the charge storage layer (charge storage part) in the insulating film MZ below the memory gate electrode MG. The injected hot electrons (electrons) are captured at the trap level in the silicon nitride film MZ2 in the insulating film MZ, and, as a result, a threshold voltage of the memory transistor is increased. That is, the memory transistor is in a writing state.

As for a method for the deleting, a deleting method (hot hole injection deleting method) which is so-called BTBT method of deleting by hot hole injection based on the BTBT (Band-To-Band Tunneling: interband tunneling phenomenon) can be used. That is, the deleting is performed by injecting holes (electron holes) generated by the BTBT (interband tunneling phenomenon) into the charge storage part (in the silicon nitride film MZ2 in the insulating film MZ). The holes (electron holes) are generated and accelerated by an electric field by the BTBT phenomenon caused by applying, for example, a voltage as shown in a “deleting” section of FIG. 62, so that the holes are injected into the silicon nitride film MZ2 in the insulating film MZ of the selection memory cell, and, as a result, a threshold voltage of the memory transistor is decreased. That is, the memory transistor is in a deleting state.

In the reading, for example, a voltage as shown in a “reading” section of FIG. 62 is applied to each part of the selection memory cell to be read. The writing state and the deleting state can be distinguished by setting the voltage Vmg to be applied to the memory gate electrode MG in the reading as a value between the threshold voltage of the memory transistor in the writing state and the threshold voltage of the memory transistor in the deleting state.

<Regarding Studied Example>

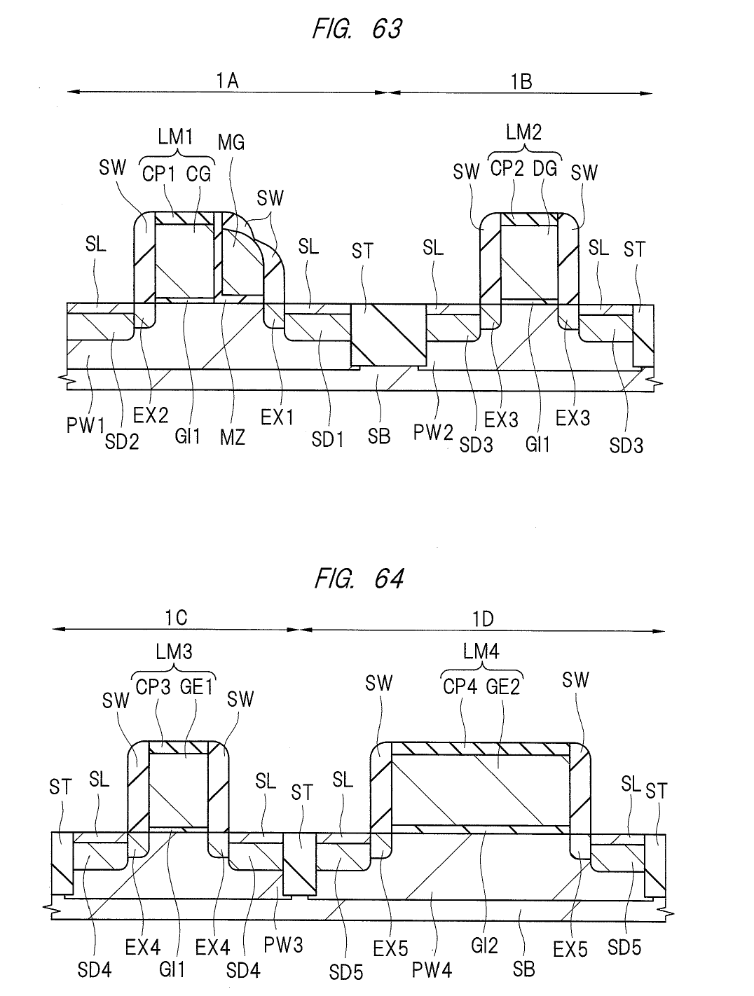

Next, a studied example made by the present inventors will be described with reference to FIGS. 63 to 72. Each of FIGS. 63 to 72 is a cross-sectional view of a principal part in the manufacturing process of the semiconductor device of the studied example.

As different from the present embodiment, in the studied example, the above-described insulating film DB is not formed on the laminated body LM4. That is, the above-described Step S18 is not performed in the studied example. Except for this difference, the processes up to the formation process of the metal silicide layer SL in Step S19 are also performed in the studied example as similar to the present embodiment, so that the structures of FIGS. 63 and 64 are obtained. FIG. 63 corresponds to the above-described FIG. 34, and FIG. 64 corresponds to the above-described FIG. 35. However, while the insulating film DB is formed on the laminated body LM4 in the case of FIGS. 34 and 35, the insulating film DB is not formed on the laminated body LM4 in the case of the studied example of FIGS. 63 and 64.

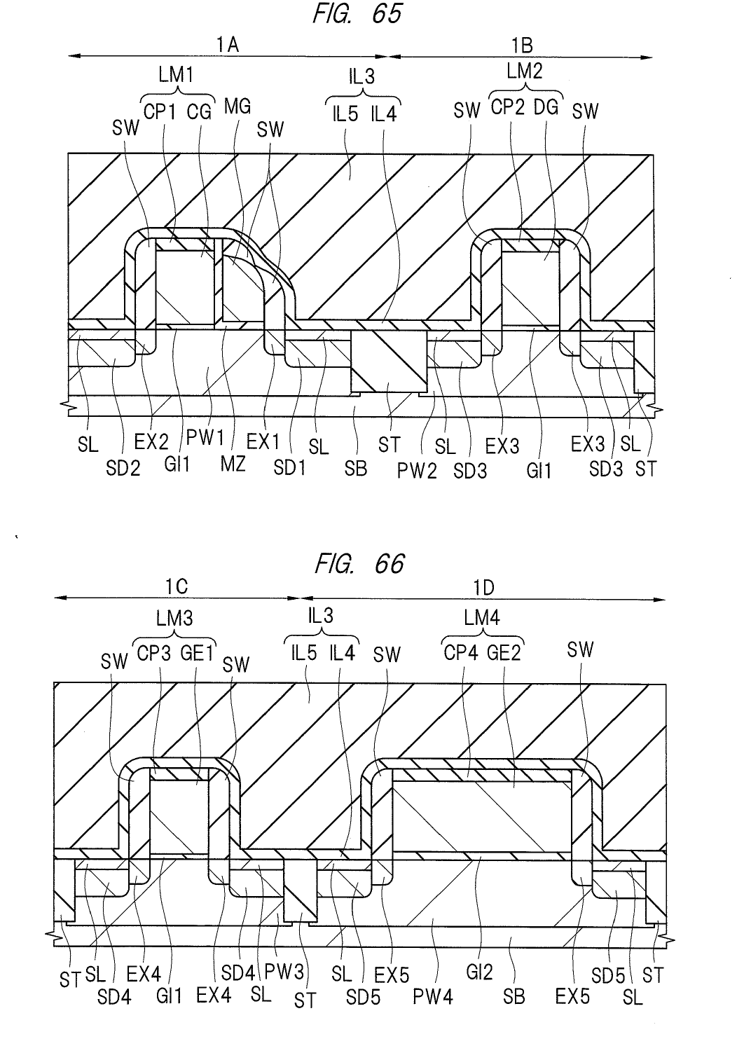

Then, the above-described Step S20 is performed also in the studied example to form the insulating film IL3 as the interlayer insulating film on the principal surface of the semiconductor substrate SB (on the whole principal surface thereof) as illustrated in FIGS. 65 and 66 so as to cover the memory gate electrode MG, the laminated bodies LM1, LM2, LM3 and LM4, and the sidewall spacer SW. Similarly to the above-described FIGS. 36 and 37, FIGS. 65 and 66 illustrate a case that the insulating film IL3 is formed a laminated film including the insulating film IL4 and the insulating film IL5 on the insulating film IL4, the insulating film IL4 being preferably formed of the silicon nitride film, and the insulating film IL5 being preferably formed of the silicon oxide film. Note that the surface irregularity or the level difference reflected by the memory gate electrode MG, the laminated bodies LM1, LM2, LM3 and LM4, the sidewall spacer SW, or others may be formed in some cases on the upper surface of the insulating film IL3 at the stage of forming the insulating film IL3 in Step S20. However, after the polishing process of Step S21, the upper surface of the insulating film IL3 is flattened.

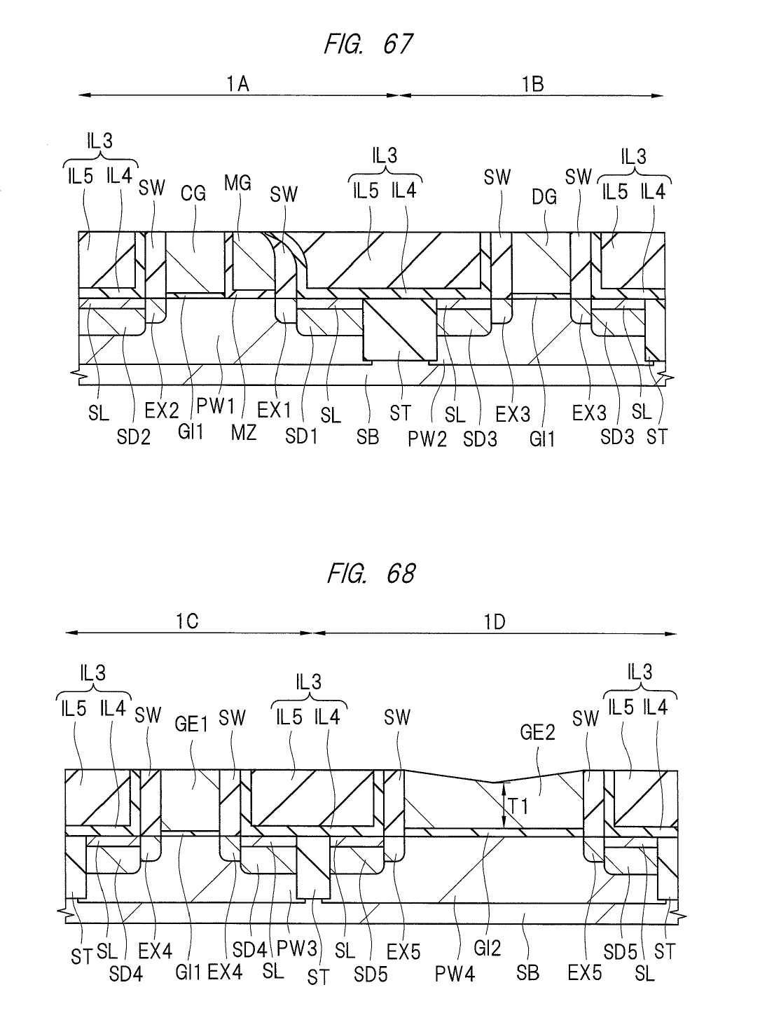

Then, also in the studied example, the upper surface of the dummy gate electrode DG is exposed as illustrated in FIGS. 67 and 68 by performing the above-described Step S21 so as to polish the upper surface of the insulating film IL3 by using the CMP method or others. At this time, when the insulating film IL3 is polished in order to expose the dummy gate electrode DG, the control gate electrode CG, the gate electrode GE1, and the gate electrode GE2 are exposed. In addition, the memory gate electrode MG may be also exposed in some cases.

In the studied example, each upper surface of the dummy gate electrode DG, the control gate electrode CG, the gate electrode GE1 and the gate electrode GE2 is exposed by polishing the insulating film IL3, cap insulating films CP1, CP2, CP3 and CP4 in the polishing process of above-described Step S21. However, at this time, the dishing is easy to be generated in the gate electrode GE2.

In the polishing process using the CMP method or others, if there are large area patterns made of the same material as each other, the dishing is easy to be generated in the large area patterns. Then, the gate electrode GE2 is larger in the dimension in the gate length direction and in the area than the dummy gate electrode DG, the control gate electrode CG and the gate electrode GE1. Therefore, the dishing is easier to be generated in the gate electrode GE2 than the dummy gate electrode DG, the control gate electrode CG and the gate electrode GE1.

When the dishing is caused in the gate electrode GE2 in the polishing process of Step S21, the upper surface of the gate electrode GE2 has a center part side hollowed more than an outer peripheral part side, and a thickness of the center part of the gate electrode GE2 is thinner (smaller) than a thickness of the outer peripheral part of the gate electrode GE2. This is because the center part side of the upper surface of the gate electrode GE2 has been polished excessively more than the outer peripheral part side thereof in the polishing process of Step S21.

Then, also in the studied example, the above-described Step S22 is performed to etch and remove the dummy gate electrode DG. By removing the dummy gate electrode DG, the trench TR is formed. At this time, also in the studied example, the control gate electrode CG, the memory gate electrode MG, the gate electrode GE1 and the gate electrode GE2 are not to be etched by using the above-described photoresist pattern PR2.

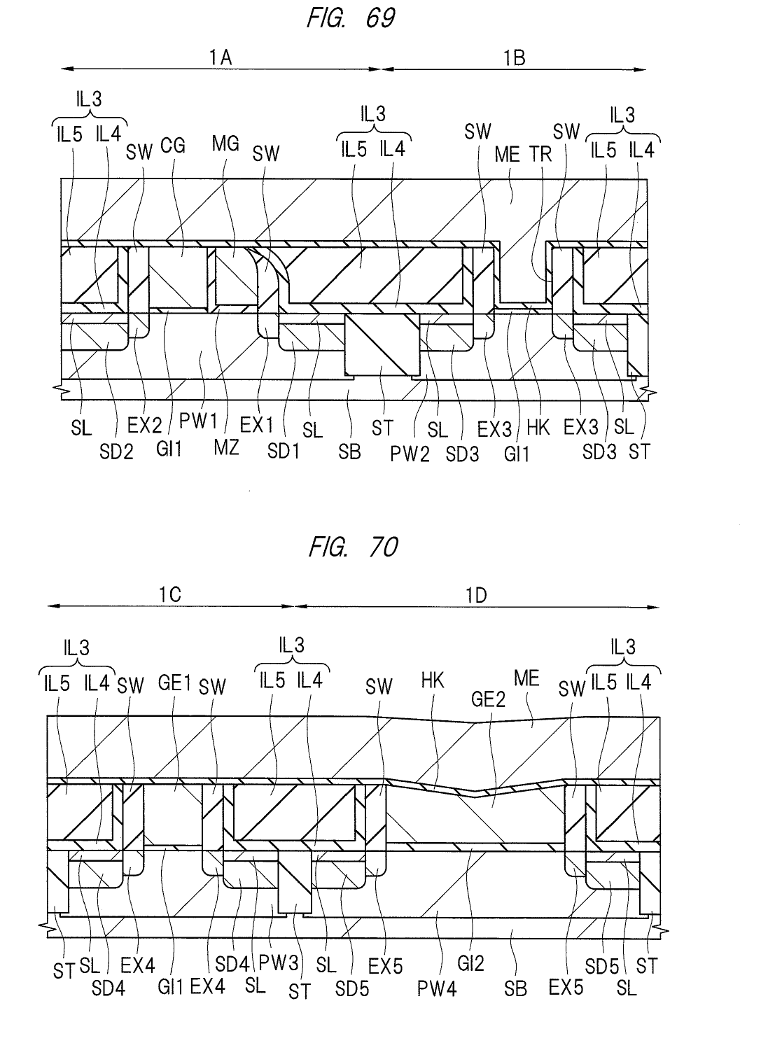

Then, also in the studied example, the above-described Step S23 is performed to form the insulating film HK on the semiconductor substrate SB, that is, on the insulating film IL3 including the inside (the bottom part and the sidewall) of the trench TR. Then, also in the studied example, the above-described Step S24 is performed to form the metal film ME on the semiconductor substrate SB, that is, on the insulating film HK so as to fill the inside of the trench TR. In this manner, the structures of FIGS. 69 and 70 are obtained.

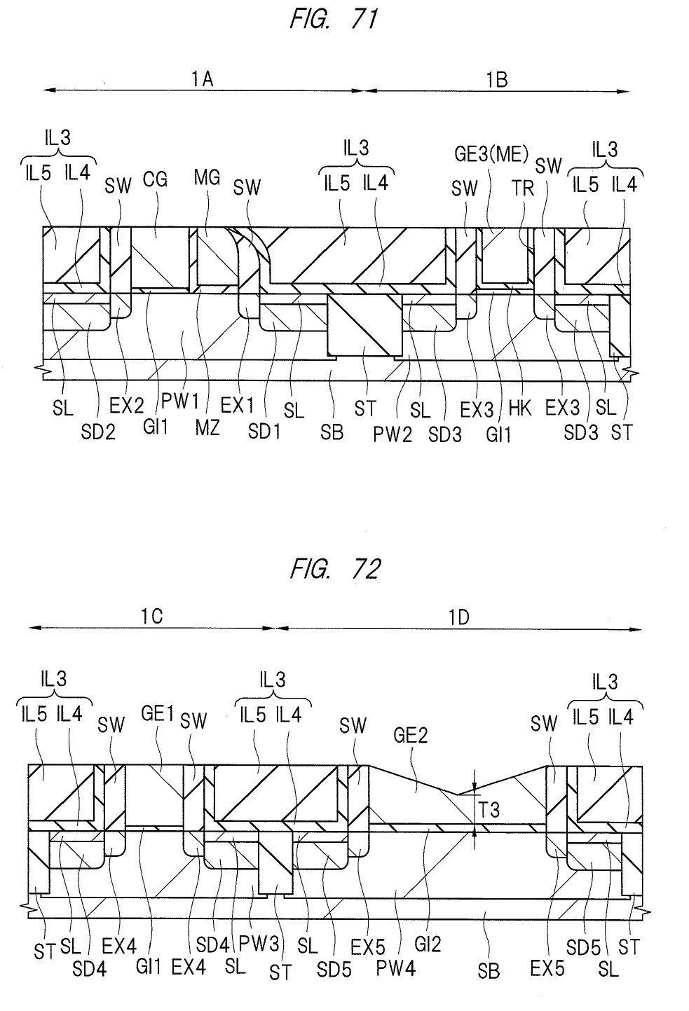

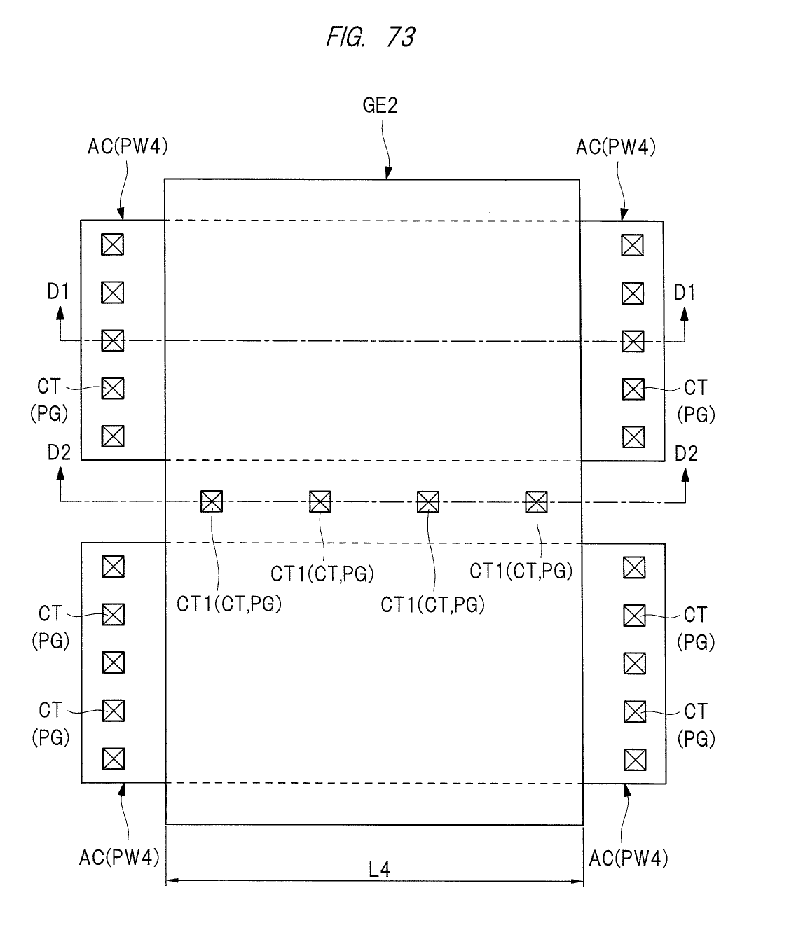

Then, also in the studied example, the above-described Step S25 is performed to polish and remove the unnecessary metal film ME and insulating film HK outside the trench TR by using the CMP method or others. In this manner, as illustrated in FIGS. 71 and 72, the insulating film HK and the metal film ME are left and embedded inside the trench TR so that the gate electrode GE3 is formed of the metal film ME embedded inside the trench TR.

After that, also in studied example, the above-described Step S26 is performed to form the above-described insulating film IL6, the above-described Step S27 is performed to form the above-described contact hole CT, the above-described Step S28 is performed to form the above-described plug, and the above-described Step S29 is performed to form the above-described insulating film IL7 and wiring M1. However, the illustration of them is omitted here.

In the studied example, in the polishing process of above-described Step S25, the gate electrode GE3 is formed of the metal film ME embedded inside the trench TR by polishing the metal film ME and the insulating film HK, and besides, each upper surface of the control gate electrode CG, the gate electrode GE1 and the gate electrode GE2 is exposed. At this time, the dishing is easy to be generated in the gate electrode GE2. A reason why the dishing is easy to be caused in the gate electrode GE2 in the polishing process of Step S25 is the same as the reason why the dishing is easy to be generated in the gate electrode GE2 in the polishing process of Step S21.

When the dishing is caused in the gate electrode GE2 in the polishing process of Step S25, the center part side of the upper surface of the gate electrode GE2 is further hollowed, and the thickness of the center part of the gate electrode GE2 is further thinner (smaller) than the thickness of the outer peripheral part of the gate electrode GE2. This is because the center part side of the upper surface of the gate electrode GE2 is polished excessively more than the outer peripheral part side thereof in the polishing process of Step S25.

That is, when the dishing is caused in the gate electrode GE2 in the polishing process of Step S21, the thickness of the center part of the gate electrode GE2 is thinner than the thickness of the outer peripheral part of the gate electrode GE2. And, when the polishing process of Step S25 is performed, the dishing in the gate electrode GE2 is further promoted, and the thickness of the center part of the gate electrode GE2 is further thinner, and therefore, a difference between the thickness of the center part of the gate electrode GE2 and the thickness of the outer peripheral part thereof is larger. That is, in both of the polishing process of Step S21 and the polishing process of Step S25, the center part side of the upper surface of the gate electrode GE2 is polished excessively more than the outer peripheral part side thereof, and therefore, the dishing in the gate electrode GE2 is extremely large.

When the dishing is caused in the gate electrode GE2, a resistance of the gate electrode GE2 is increased by the influence of the thin thickness of the gate electrode GE2, and there is a risk of reduction in an operation speed. This risk reduces a performance of the manufactured semiconductor device. In addition, when the dishing in the gate electrode GE2 is large, a part whose total thickness portion is polished and removed is caused in the gate electrode GE2, and there is also a risk of disconnection of the gate electrode. GE2. This risk reduces a manufacturing yield of the semiconductor device. Therefore, when the polishing process is performed, it is desired not to cause the dishing in the gate electrode as much as possible.

In addition, the dishing is easier to be generated in the gate electrode GE2 as a planar dimension of the gate electrode GE2 is larger. In the metal gate transistor and the low breakdown voltage MISFET, the gate length of the gate electrode is not so large as being, for example, about several tens of nm. However, in the high breakdown voltage MISFET, the gate length of the gate electrode is extremely large sometimes as being 100 nm or larger, for example, about 700 nm. Application of such a gate electrode as having the large gate length to the gate electrode GE2 causes a high possibility of the dishing in the gate electrode GE2.

<Regarding Principal Characteristics and Effects>

Next, principal characteristics and effects of the present embodiment will be described.

In the present embodiment, after forming the gate electrode GE2 (first gate electrode) for the MISFET Q3 (first MISFET) and the dummy gate electrode DG for the MISFET Q1 (second MISFET) on the semiconductor substrate SB, the insulating film DB (first film) is partially formed on the gate electrode GE2 (first gate electrode). Then, after forming the insulating film IL3 on the semiconductor substrate SB in Step S20 so as to cover the dummy gate electrode DG, the gate electrode GE2 and the insulating film DB, the dummy gate electrode DG is exposed by polishing the insulating film IL3 in Step S21. Then, the dummy gate electrode DG is removed, and the conductive film (here, metal film ME) is formed on the insulating film IL3 so as to fill the trench TR which is the region where the dummy gate electrode DG has been removed. Then, the conductive film (here, metal film ME) outside the trench TR is removed by polishing this conductive film (here, metal film ME) in Step S25 but the conductive film (here, metal film ME) is left inside the trench TR, so that the gate electrode GE3 (second gate electrode) for the MISFET Q1 (second MISFET) is formed. Then, in the process of polishing the insulating film IL3 in Step S21, the insulating film IL3 is polished under the condition having the smaller polishing speed of the insulating film DB (first film) than the polishing speed of the insulating film IL3.

As described in the studied example, there is the risk of the dishing in the gate electrode GE2 in the polishing process (that is, polishing process of Step S21) for exposing the dummy gate electrode DG and the polishing process (that is, polishing process of Step S25) for forming the gate electrode GE3 (second gate electrode). In the present embodiment, in order to prevent the dishing in the gate electrode GE2, the insulating film DB (first film) is partially formed on the gate electrode GE2 (first gate electrode).

The reason why the dishing is generated in a certain pattern in the polishing process using the CMP method or others is that the center part side of this pattern is polished excessively more than the outer peripheral part side thereof, and therefore, the dishing is easier to be generated as this pattern is larger. Therefore, if a dishing prevention pattern is partially provided on a pattern having the risk of the dishing so that the polishing is suppressed on the dishing prevention pattern, the excessively-polished part is difficult to be generated in the pattern having the risk of the dishing, and therefore, the dishing is difficult to be generated therein. However, if a dishing prevention pattern having the same area as that of the whole pattern having the risk of the dishing is provided thereon, the dishing is generated in the dishing prevention pattern itself in the polishing process, and this does not cause the prevention of the dishing in the pattern having the risk of the dishing as a result. Therefore, if there is the pattern having the risk of the dishing, it is effective to partially (locally) provide the dishing prevention pattern on that pattern. In the present embodiment, the pattern having the risk of the dishing corresponds to the gate electrode GE2, and the dishing prevention pattern corresponds to the insulating film DB.

Accordingly, in the present embodiment, the insulating film DB is partially (locally) formed on the gate electrode GE2, and besides, the insulating film IL3 is polished under the condition (polishing condition) having the smaller polishing speed of the insulating film DB than the polishing speed of the insulating film IL3 in the polishing process Step S21. Therefore, in the polishing process of Step S21, the polishing in the part where the insulating film DB has been formed is suppressed. In this manner, in the polishing process of Step S21, the excessively-polished part is difficult to be generated in the gate electrode GE2, and therefore, the dishing is difficult to be generated in the gate electrode GE2.

In the case of the above-described studied example that the insulating film DB is not formed on the gate electrode GE2 as different from the present embodiment, the dishing is easy to be caused in the gate electrode GE2 in the polishing process of Step S21 and the polishing process of Step S25. On the other hand, in the case that the insulating film DB is provided so as to cover the whole gate electrode GE2 (in this case, the area of the insulating film DB is equal to or larger than the area of the gate electrode GE2) as different from the present embodiment, the dishing is generated in this insulating film DB in the polishing of Step S21, and this is difficult to cause of the prevention of the dishing in the gate electrode GE2 after the polishing process of Step S25 is finished.

In contrast, in the present embodiment, the insulating film DB is partially formed on the gate electrode GE2. That is, the gate electrode GE2 is not totally covered by the insulating film DB but has a part covered by the insulating film DB and a part not covered by the insulating film DB. That is, in a planar view, the gate electrode GE2 has a part overlapping with the insulating film DB and a part not overlapping with the insulating film DB. Therefore, in the polishing process of Step S21, the dishing is difficult to be generated in the insulating film DB, and besides, the polishing in the part where the insulating film DB has been formed is suppressed, so that the excessively-polished part is difficult to be generated in the gate electrode GE2, and therefore, the dishing is difficult to be generated in the gate electrode GE2.

At a stage of finish of the polishing process of Step S21, the present embodiment and the above-described studied example are compared with each other in the thickness of the gate electrode GE2. In the above-described studied example, the minimum value of the thickness of the gate electrode GE2 at the stage of finish of the polishing process of Step S21 is assumed to be the minimum thickness “T1”. Here, the minimum thickness T1 is a thickness of the thinnest part of the gate electrode GE2. This minimum thickness T1 is illustrated in the above-described FIG. 68. When the dishing is generated in the gate electrode GE2, the gate electrode GE2 has the small thickness at the center part (center part in a planar view), and therefore, the minimum thickness T1 corresponds to a thickness in the vicinity of the center part of the gate electrode GE2. Note that the thickness of the gate electrode GE2 corresponds to a thickness (dimension) in a substantially perpendicular direction to the principal surface of the semiconductor substrate SB.

On the other hand, in the present embodiment, the minimum value of the thickness of the gate electrode GE2 at the stage of finish of the polishing process of Step S21 is assumed to be the minimum thickness “T2”. Here, the minimum thickness T2 is a thickness of the thinnest part of the gate electrode GE2. This minimum thickness T2 is illustrated in the above-described FIG. 39 and FIG. 41. In the present embodiment, by partially forming the insulating film DB on the gate electrode GE2, the dishing in the gate electrode GE2 is prevented, and besides, the minimum thickness T2 of the gate electrode GE2 can be larger than the above-described minimum thickness T1 (that is, T2>T1). That is, when the polishing process of Step S21 is performed until the dummy gate electrode DG is exposed in the present embodiment and the above-described studied example, the minimum thickness T2 of the gate electrode GE2 in the present embodiment is larger than the minimum thickness T1 of the gate electrode GE2 in the above-described studied example (T2>T1).

Therefore, in the present embodiment, by forming the insulating film DB partially on the gate electrode GE2, the dishing in the gate electrode GE2 is prevented in the polishing process of Step S21, and besides, the minimum thickness T2 of the gate electrode GE2 can be large.

In addition, in the above-described studied example, the dishing is generated in the gate electrode GE2 in the polishing process of Step S21, and a degree of the dishing in the gate electrode GE2 is increased in the polishing process of Step S25. On the other hand, in the present embodiment, because the dishing in the gate electrode GE2 can be prevented in the polishing process of Step S21, the dishing is not generated in the gate electrode GE2 at the stage of finish of the polishing process of Step S25, or the degree of the dishing can be smaller than that of the above-described studied example at the stage even when the dishing has been generated.

At the stage of finish of the polishing process of Step S25, the present embodiment and the above-described studied example are compared with each other in the thickness of the gate electrode GE2. In the above-described studied example, the minimum value of the thickness of the gate electrode GE2 at the stage of finish of the polishing process of Step S25 is assumed to be the minimum thickness “T3”. Here, the minimum thickness T3 is a thickness of the thinnest part of the gate electrode GE2. This minimum thickness T3 is illustrated in the above-described FIG. 72. When the dishing is generated in the gate electrode GE2, the center part (center part in a planar view) of the gate electrode GE2 is thin in the thickness, and therefore, the minimum thickness T3 corresponds to the thickness in the vicinity of the center part of the gate electrode GE2. In the above-described studied example, the stage of finish of the polishing process of Step S25 is larger than the stage of finish of the polishing process of Step S21 in the degree of the dishing in the gate electrode GE2. And, the minimum thickness T3 is smaller than the above-described minimum thickness T1 (that is, T3<T1).

On the other hand, in the present embodiment, the minimum value of the thickness of the gate electrode GE2 at the stage of finish of the polishing process of Step S25 is assumed to be the minimum thickness T4. Here, the minimum thickness T4 is a thickness of the thinnest part of the gate electrode GE2. This minimum thickness T4 is illustrated in the above-described FIG. 51. In the present embodiment, by partially forming the insulating film DB on the gate electrode GE2, the minimum thickness T2 of the gate electrode GE2 at the stage of finish of the polishing process of Step S21 can be larger than the minimum thickness T1 in the case of the above-described studied example (that is, T2>T1). Therefore, even when the gate electrode GE2 is polished in the polishing process of Step S25, the minimum thickness T4 of the gate electrode GE2 at the stage of finish of the polishing process of Step S25 can be larger than the minimum thickness T3 in the case of the above-described studied example (that is, “T4>T3”). That is, while the minimum thickness T4 of the gate electrode GE2 at the stage of finish of the polishing process of Step S25 in the present embodiment is equal to or smaller than the minimum thickness T2 (that is, T4≦T2), the minimum thickness T4 can be larger (that is, T4>T3) than the minimum thickness T3 in the above-described studied example.

Therefore, in the present embodiment, the dishing in the gate electrode GE2 at the stage of finish of the polishing process of Step S25 can be suppressed or prevented further than the above-described studied example, and the thickness (more particularly, the minimum thickness T4) of the gate electrode GE2 at the stage of finish of the polishing process of Step S25 can be larger than the above-described studied example. Therefore, the increase in the resistance of the gate electrode GE2 due to the thin gate electrode GE2 can be suppressed or prevented. Therefore, the performance of the semiconductor device can be improved. For example, an operation speed of the MISFET having the gate electrode GE2 can be improved. In addition, the disconnection of the gate electrode GE2 due to the thin gate electrode GE2 can be prevented. Therefore, the manufacturing yield of the semiconductor device can be improved.

In addition, in the present embodiment, by partially forming the insulating film DB on the gate electrode GE2, even when the gate electrode GE2 is polished by the polishing process of Step S21, a part of the gate electrode GE2 which is positioned immediately below the insulating film DB is suppressed in the polished amount lower (has the polished amount lower) than those of other parts. Therefore, at the stage of finish of the polishing process of Step S21, the upper surface of the gate electrode GE2 is not flattened but is easy to be in a state that a region where the insulating film DB has been formed (that is, the region positioned immediately below the insulating film DB) is swollen. However, even in such a state, when the polishing process of Step S25 is performed, the upper surface of the gate electrode GE2 is closer to be flat by polishing the upper surface of the gate electrode GE2 than that at the stage of finish of the polishing process of Step S21.

In addition, an adverse influence is difficult to be caused even when the upper surface of the gate electrode GE2 is not flattened at the stage of finish of the polishing process of Step S25 but is in the state having the swollen region where the insulating film DB has been formed at the stage. On the other hand, when the dishing is generated in the gate electrode GE2 as seen in the above-described studied example, the adverse influence is large. This is because the increase in the resistance of the gate electrode GE2 or the disconnection thereof is concerned by the thin gate electrode GE2 whereas such a concern is not caused by a thick gate electrode GE2. That is, while a problem is caused by excessively polishing the gate electrode GE2, the problem is not caused by suppressing the polishing of the gate electrode GE2. Therefore, in the present embodiment, the partial formation of the insulating film DB on the gate electrode GE2 suppresses or prevents the excessive polishing of the gate electrode GE2.

In addition, the gate electrode GE is preferably the metal gate electrode. In this manner, the performance of the MISFET having the gate electrode GE3 can be improved. Therefore, the performance of the semiconductor device can be improved.

In addition, in order to form the gate electrode GE3 as the metal gate electrode, it is required to form the above-described metal film ME as a single layer film made of a metal film having one layer or as a laminated film having a metal film in the lowest layer. When the metal film ME is formed as the laminated film obtained by stacking a plurality of layers, a metal film is required for the lowest layer. However, layers except for the lowest layer may be regardless whether the metal film or not the metal film, and a polycrystalline silicon film can be also used. Note that the metal film described here is a conductive film showing metal conductivity, and includes not only a single metal film (pure metal film) and an alloy film but also a metal compound film showing metal conductivity (such as a nitride metal film and a carbide metal film).

In addition, in the present embodiment, after forming the source/drain region on the semiconductor substrate SB at Step S14 and Step S16, the dummy gate electrode DG is removed at Step S22, and the gate electrode GE3 which is the metal gate electrode is formed on the region (corresponding to the above-described trench TR) where the dummy gate electrode DG has been removed. Therefore, the gate electrode GE3 which is the metal gate electrode is formed after the activation annealing (corresponding to the thermal process of the above-described Step S17) performed after forming the source/drain region, and therefore, such a high temperature load as the activation annealing is not applied to the metal gate electrode, so that the characteristics of the MISFET using the metal gate electrode for the gate electrode can be improved, or variation in the characteristics can be suppressed.

In addition, an effect is large in the present embodiment when the present embodiment is applied to a case that the dimension (corresponding to the above-described dimension L4) of the gate electrode GE2 (first gate electrode) in the gate length direction is larger than the dimension (corresponding to the above-described dimension L2) of the dummy gate electrode DG in the gate length direction. In addition, an effect is large in the present embodiment when the present embodiment is applied to a case that the area (area in a planar view) of the gate electrode GE2 (first gate electrode) is larger than the area (area in a planar view) of the dummy gate electrode DG. This is because the phenomenon of the dishing generated in a certain pattern is easier to be caused as the pattern is larger in the polishing process using the CMP method or others. That is, in the above-described studied example, the possibility of the dishing generated in the gate electrode GE2 is higher as the dimension of the gate electrode GE2 is larger in the polishing process of Step S21 and the polishing process of Step S25. On the other hand, in the present embodiment, even when the gate electrode GE2 is large, the dishing generated in the gate electrode GE2 can be suppressed or prevented by partially forming the insulating film DB on the gate electrode GE2. Therefore, the effect is extremely large in the present embodiment when the present embodiment is applied to the case of the large dimension of the gate electrode GE2. In this viewpoint, an effect is large in the present embodiment when the present embodiment is applied to a case that the dimension (corresponding to the above-described dimension L4) of the gate electrode GE2 in the gate length direction is larger than the dimension (corresponding to the above-described dimension L2) of the dummy gate electrode DG in the gate length direction. In addition, an effect is large in the present embodiment when the present embodiment is applied to a case that the area (area in a planar view) of the gate electrode GE2 is larger than the area (area in a planar view) of the dummy gate electrode DG. In addition, an effect is large in the present embodiment when the present embodiment is applied to a case that the dimension (corresponding to the above-described dimension L4) of the gate electrode GE2 in the gate length direction is 500 nm or larger.

In addition, the present embodiment, when applied to a case where the gate electrode GE2 and the dummy gate electrode DG are formed by the silicon film PS1 which is in the same layer as those described above, is large in an effect. When the gate electrode GE2 and the dummy gate electrode DG are formed by the silicon film PS1 which is in the same layer as those, the formed gate electrode GE2 and formed dummy gate electrode PG will have almost the same height. Therefore, when the dummy gate electrode DG is made to be exposed by the polishing process of Step S21, the gate electrode GE2 is also exposed, and there is a risk where the dishing is generated on the gate electrode GE2. As compared with that, in the present embodiment, even when the height of the gate electrode GE2 is almost the same as that of the dummy gate electrode DG, the dishing being generated on the gate electrode GE2 can be controlled or prevented by forming the insulating film DB partially on the gate electrode GE2. In addition, the dummy gate electrode DG becomes easy to be removed exactly by the dummy gate electrode DG being formed by the silicon film. In addition, the reliability of the MISFET Q3 having the gate electrode GE2 can be enhanced by the gate electrode GE2 being formed by the silicon film.

In addition, while the insulating film DB for preventing the dishing is formed on the gate electrode GE2 in the present embodiment, it is preferred not to form this insulating film DB on the dummy gate electrode DG. In this manner, the upper surface of the dummy gate electrode DG can be exposed exactly in the polishing process of Step S21, and the dummy gate electrode DG can be removed exactly in Step S22. In addition, the gate electrode GE3 can be formed exactly on the region (corresponding to the above-described trench TR) where the dummy gate electrode DG has been removed.

In addition, in Step S22, it is preferred not to remove the gate electrode GE2, the control gate electrode CG and the memory gate electrode MG but preferred to remove the dummy gate electrode DG. In this manner, the gate electrode GE3 can be formed exactly in the region (corresponding to the above-described trench TR) where the dummy gate electrode DG has been removed, and besides, failure (for example, the increase in the gate resistance or others) accompanied by the removal of the gate electrode GE1, the gate electrode GE2, the control gate electrode CG and the memory gate electrode MG can be prevented.

In addition, in the present embodiment, after removing the dummy gate electrode DG in Step S22 and before forming the conductive film (here, metal film ME) for forming the gate electrode GE3 in Step S24, the insulating film HK which is the high dielectric constant insulating film is preferably formed in Step S23. In this manner, the gate insulating film of the MISFET Q1 having the gate electrode GE3 can be formed as the high dielectric constant gate insulating film. By such a formation, a physical film thickness of the gate insulating film can be increased more than that in the case that the high dielectric constant gate insulating film is not applied, and therefore, such an advantage as reducing a leakage current can be obtained.

In addition, in the present embodiment, the cap insulating film CP1 is formed on the control gate electrode CG, the cap insulating film CP2 is formed on the dummy gate electrode DG, the cap insulating film CP3 is formed on the gate electrode GE1, and the cap insulating film CP4 is formed on the gate electrode GE2. However, the formation of these cap insulating films CP1, CP2, CP3 and CP4 can be also eliminated. When the formation of the cap insulating films CP1, CP2, CP3 and CP4 is eliminated, the process of forming the insulating film IL1 in the above-described Step S6 may be eliminated. In that case, in Step S7, while the control gate electrode CG is formed of the patterned silicon film PS1, the cap insulating film CP1 is not formed on the control gate electrode CG, and the above-described laminated film LF1 does not include the insulating film IL1. In addition, in that case, in the above-described Step S13, while each of the dummy gate electrode DG and the gate electrodes GE1 and GE2 is formed of the patterned silicon film PS1, the cap insulating films CP2, CP3 and CP4 are not formed thereon.

Since the cap insulating film CP4 is formed on the gate electrode GE2 when the cap insulating films CP1, CP2, CP3 and CP4 are formed, the above-described insulating film DB is not formed in contact with the gate electrode GE2, but the insulating film DB is formed on the cap insulating film CP4 on the gate electrode GE2. That is, the insulating film DB is formed in contact with the cap insulating film CP4 on the gate electrode GE2 but not in contact with the gate electrode GE2. That is, the insulating film DB is formed on the gate electrode GE2 via the cap insulating film CP4. On the other hand, when the formation of the cap insulating films CP1, CP2, CP3 and CP4 is eliminated, the cap insulating film CP4 is not formed on the gate electrode GE2, and therefore, the above-described insulating film DB is formed directly on the gate electrode GE2, so that the insulating film DB is contact with the gate electrode GE2.

When the cap insulating films CP1, CP2, CP3 and CP4 are formed, the cap insulating film CP2 is formed on the dummy gate electrode DG, and therefore, not only the insulating film IL3 but also the cap insulating film CP2 on the dummy gate electrode DG are polished and removed in the polishing process of Step S21, so that the dummy gate electrode DG is exposed. That is, in the polishing process of Step S21, not only the insulating film IL3 but also the cap insulating films CP1, CP2, CP3 and CP4 are polished. On the other hand, when the formation of cap insulating films CP1, CP2, CP3 and CP4 is eliminated, the cap insulating film CP2 is not formed on the dummy gate electrode DG, and therefore, the insulating film IL3 is polished and removed in the polishing process of Step S21, so that the dummy gate electrode DG is exposed.

The present embodiment can be applied to both of the case that the cap insulating films CP1, CP2, CP3 and CP4 are formed and the case that they are not formed.

However, when the cap insulating films CP1, CP2, CP3, and CP4 are formed, the following effects can be obtained. That is, when the cap insulating film CP1, CP2, CP3 and CP4 are formed, the formation of the metal silicide layer SL on the control gate electrode CG, on the dummy gate electrode DG, on the gate electrode GE1, and on the gate electrode GE2 can be prevented when the metal silicide layer SL is formed on the source/drain region in the above-described Step S19. Therefore, in the polishing process of Step S21, the polishing of the metal silicide layer SL is prevented. When the metal silicide layer SL is polished in the polishing process, there is a risk of scratches. By forming the cap insulating films CP1, CP2, CP3 and CP4, the formation of the metal silicide layer on control the gate electrode CG, on the dummy gate electrode DG, on the gate electrode GE1, and on the gate electrode GE2 can be prevented, and therefore, the scratches can be prevented exactly from being generated in the polishing process of Step S21.

In addition, in the present embodiment, not only the gate electrode GE2 (first gate electrode) for the MISFET Q3 and the dummy gate electrode DG for the MISFET Q1 but also the gate electrode GE1 (third gate electrode) for the MISFET Q2 (third MISFET) are formed on the semiconductor substrate SB. The dimension (corresponding to the above-described dimension L3) of the gate electrode GE1 in the gate length direction is small than the dimension (corresponding to the above-described dimension L4) of the gate electrode GE2 in the gate length direction. While the above-described insulating film DB is formed on the gate electrode GE2 in the above-described Step S18, the above-described insulating film DB is not formed on the gate electrode GE1.

Since the dimension (corresponding to the above-described dimension L3) of the gate electrode GE1 in the gate length direction is small than the dimension (corresponding to the above-described dimension L4) of the gate electrode GE2 in the gate length direction, the problem of the dishing is difficult to be generated in the gate electrode GE1 even when there is the concern about the dishing in the gate electrode GE2. Therefore, for the gate electrode GE2 which has the large dimension in the gate length direction and in which the problem of the dishing is easy to be caused, the dishing is suppressed or prevented by forming the above-described insulating film DB on the gate electrode GE2. On the other hand, for the gate electrode GE1 which has the small dimension in the gate length direction and in which the problem of the dishing is difficult to be caused, the above-described insulating film DB is not to be formed on the gate electrode GE1. In this manner, the performance of the semiconductor device can be improved, and the manufacturing yield thereof can be improved, by taking an appropriate action for each of the gate electrode GE1 and the gate electrode GE2.

In addition, the gate electrode GE2 (first gate electrode), the dummy gate electrode DG, and the gate electrode GE1 (third gate electrode) are formed of the silicon film PS1 in the same layer as those described above. In this manner, the number of manufacturing processes for the semiconductor device can be reduced, and the semiconductor device can be easily manufactured. In the polishing process of Step S21, the dummy gate electrode DG is exposed, and besides, the gate electrode GE1 is also exposed.

When the gate electrode GE2, the dummy gate electrode DG, and the gate electrode GE1 are formed of the silicon film PS1 in the same layer as those described above, the formed gate electrode GE2, the formed dummy gate electrode DG, and the formed gate electrode GE1 are almost the same as each other in a height. Therefore, when the dummy gate electrode DG is exposed in the polishing process of Step S21, the gate electrode GE1 is also exposed. However, since the dimension (corresponding to the above-described dimension L3) of the gate electrode GE1 in the gate length direction is smaller than the dimension (corresponding to the above-described dimension L4) of the gate electrode GE2 in the gate length direction, the problem of the dishing is difficult to be caused in the gate electrode GE1 even when the gate electrode GE1 is exposed in Step S21. On the other hand, for the gate electrode GE2 having the large dimension in the gate length direction, the dishing in the gate electrode GE2 can be suppressed or prevented by partially forming the insulating film DB on the gate electrode GE2. In addition, by forming the dummy gate electrode DG by the silicon film, the dummy gate electrode DG is easy to be removed exactly in Step S22. In addition, by forming the gate electrode GE2 and the gate electrode GE1 by the silicon film, the reliability of the MISFET Q3 having the gate electrode GE2 and the MISFET Q2 having the gate electrode GE1 can be improved.

In addition, in the present embodiment, the insulating film DB is partially formed on the gate electrode GE2, and this insulating film DB is functioned as the dishing prevention pattern. Therefore, in the polishing process of Step S21, it is required to polish the insulating film IL3 under the condition (polishing condition) that the polishing speed of the insulating film DB (first film) is smaller than the polishing speed of the insulating film IL3. The polishing speed can be adjusted by, for example, polishing liquid (slurry) to be used or others.

When the insulating film IL3 is the single film (monolayer film), the insulating film DB is formed of a different material from that of the insulating film IL3, and the insulating film IL3 may be polished in Step S21 under the condition that the polishing speed of the insulating film DB is smaller than the polishing speed of the single film forming the insulating film IL3. For example, when the insulating film IL3 is the single film of a silicon oxide film, the insulating film DB is formed of a material except for silicon oxide (for example, silicon nitride), and the polishing process of Step S21 may be performed under the condition (polishing condition) that the polishing speed of the insulating film DB (silicon nitride film) is smaller than the polishing speed of the insulating film IL3 (silicon oxide film).

In addition, when the insulating film IL3 is formed of the laminated film including the insulating film IL4 and the insulating film IL5 which is formed on the insulating film IL4 and which is thicker than the insulating film IL4, the insulating film DB is formed of a different material from that of the insulating film IL5, and the insulating film IL3 may be polished in Step S21 under a condition that the insulating film DB is more difficult to be polished than the insulating film IL5.

In addition, when the insulating film IL3 is formed of the laminated film including the silicon nitride film and the silicon oxide film which is formed on the silicon nitride film and which is thicker than the silicon nitride film (that is, when the insulating film IL4 is formed of the silicon nitride film, and the insulating film IL5 is formed of the silicon oxide film), the insulating film IL3 may be polished in Step S21 under a condition that the insulating film DB is more difficult to be polished than the silicon oxide film (insulating film IL5).

In addition, when the insulating film IL3 is formed of the laminated film including the silicon nitride film (insulating film IL4) and the silicon oxide film which is formed on the silicon nitride film and which is thicker than the silicon nitride film, and besides, when the insulating film DB is made of silicon nitride, the insulating film IL3 may be polished in Step S21 under a condition that the silicon nitride (insulating films DB and IL4) is more difficult to be polished than the silicon oxide film (insulating film IL5).

When the insulating film IL3 is formed of the laminated film obtained by stacking the plurality of insulating films, it is preferred to polish the insulating film IL3 in Step S21 under a condition that the polishing speed of the insulating film DB is smaller than an average of a polishing speed of the laminated film. In addition, when the insulating film IL3 is formed of the laminated film obtained by stacking the plurality of insulating films, it is preferred to polish the insulating film IL3 in Step S21 under a condition that the polishing speed of the insulating film DB is smaller than a polishing speed of a main insulating film in the laminated film (the main insulating film corresponding to the thickest insulating film of the plurality of insulating films forming the laminated film).

In this manner, the insulating film DB partially formed on the gate electrode GE2 can exactly functioned as the dishing prevention pattern. Note that more difficulty in polishing an item “B” than polishing an item “A” corresponds to the smaller polishing speed of the item “B” than the polishing speed of the item “A”.

In addition, in the polishing process of Step S21, it is more preferred to perform the polishing under the condition that the polishing speed of the insulating film DB is smaller than the polishing speed of the gate electrode GE2, so that the dishing prevention effect in the gate electrode GE2 by providing the insulating film DB can be further enhanced.

In addition, since the insulating film DB is partially formed on the gate electrode GE2, the gate electrode GE2 has a part positioned immediately below the insulating film DB and a part not positioned immediately below the insulating film DB at the stage of formation of the insulating film DB. Therefore, in the polishing process of Step S21, at least a part of the gate electrode GE2 is exposed. However, even when the gate electrode GE2 is not exposed in the polishing process of Step S21, it is only required to expose the dummy gate electrode DG, and failure in terms of the manufacturing process is not caused.

In addition, the insulating film DB is functioned as the dishing prevention pattern, and does not essentially need the insulation property, and therefore, may be not made of the insulating material. However, the insulating film DB is more preferably made of the insulating material (that is, has the insulation property). In this manner, even when the unnecessary material is left in the formation of the insulating film DB, such as when the unnecessary part of the above-described insulating film IL2 is not completely removed and is left, the failure is difficult to be caused since the residues are made of not the conductive material but the insulating material. Therefore, the reliability of the semiconductor device can be improved. In addition, the manufacturing process of the semiconductor device is easy to be managed.

In addition, each of the control gate electrode CG and the memory gate electrode MG is preferably made of silicon. This reason is as follows. That is, for the nonvolatile memory, charge storage characteristics are important. When the metal gate electrode is used for the control gate electrode CG and the memory gate electrode MG forming the memory cell of the nonvolatile memory, there is a concern about reduction in the charge storage characteristics since a metal of the metal gate electrode is diffused to the charge storage film (here, insulating film MZ). By using a silicon gate electrode made of silicon for the control gate electrode CG and the memory gate electrode MG, such a concern is not caused, so that the reliability of the memory cell of the nonvolatile memory can be improved.

In addition, the present embodiment describes the case of forming the nonvolatile memory, the metal gate transistor (here, MISFET Q1), the MISFET (here, MISFET Q3) where the insulating film DB which is the dishing prevention pattern is formed, and the MISFET (here, MISFET Q2) where the insulating film DB which is the dishing prevention pattern is not formed, on the same semiconductor substrate SB.

As another embodiment, the MISFET (here, MISFET Q2) where the insulating film DB which is the dishing prevention pattern is not formed may be eliminated in some cases. In that case, the MISFET (here, MISFET Q2) where the insulating film DB which is the dishing prevention pattern is not formed may be replaced by the metal gate transistor (here, MISFET Q1). That is, a MISFET except for the nonvolatile memory and the MISFET (here, MISFET Q3) where the insulating film DB which is the dishing prevention pattern is formed can be also as the metal gate transistor (here, MISFET Q1).

In addition, as still another embodiment, the formation of the nonvolatile memory may be eliminated in some cases. In that case, the laminated bodies LM2, LM3 and LM4 may be formed by forming the silicon film PS1 in the above-described Step S5 and forming the insulating film IL1 in the above-described Step S6, and then, patterning the laminated film LF1 in the above-described Step S13 with eliminating the above-described Steps S7 to S12. After that, the above-described Step S15 (the process of forming the sidewall spacer) and subsequent processes are performed.

In addition, as still another embodiment, the formation of the nonvolatile memory may be eliminated, and besides, the MISFET (here, MISFET Q2) where the insulating film DB which is the dishing prevention pattern is not formed may be eliminated. In that case, the laminated bodies LM2 and LM4 may be formed by forming the silicon film PS1 in the above-described Step S5 and forming the insulating film IL1 in the above-described Step S6, and then, patterning the laminated film LF in the above-described Step S13 with eliminating the above-described Steps S7 to S12. After that, the above-described Step S15 (the process of forming the sidewall spacer) and subsequent processes are performed.

### Second Embodiment

The above-described first embodiment has described that the insulating film DB is partially formed on the gate electrode GE2. However, in the present second embodiment, a specific example of arrangement of the insulating film DB on the gate electrode GE2 will be described.

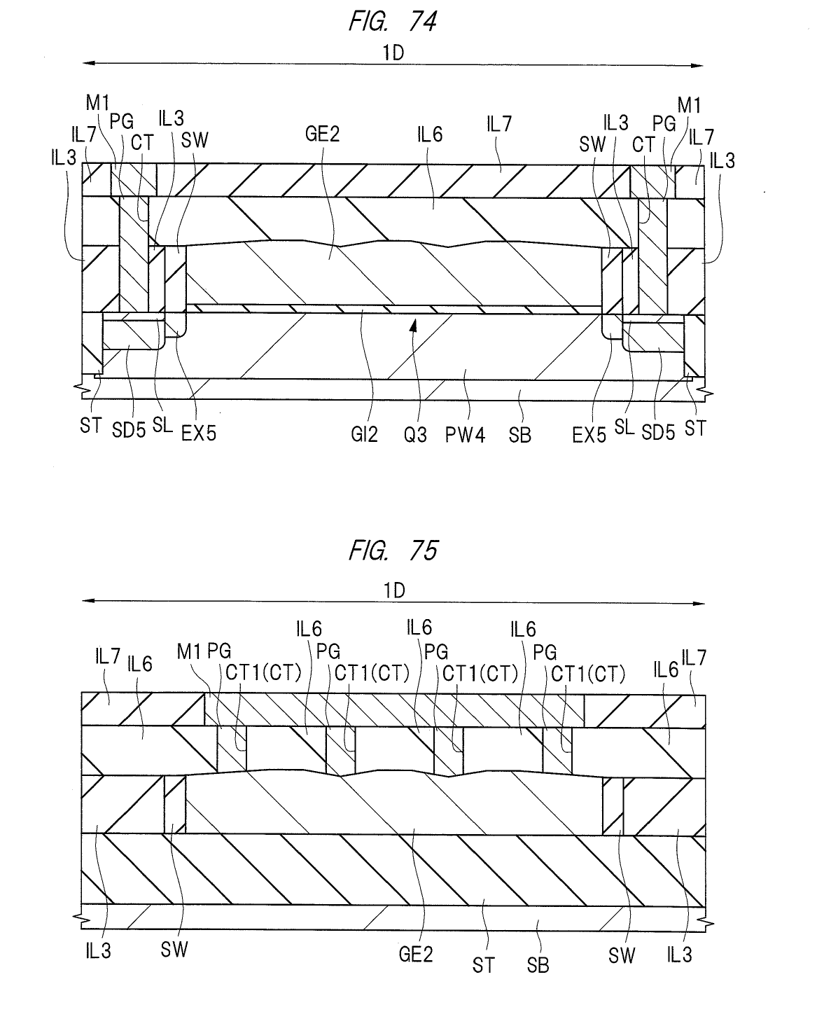

FIG. 73 is a plan view of a principal part of the semiconductor device of the present second embodiment, and illustrates a plan view of the high breakdown voltage MISFET formation region 1D. In addition, FIGS. 74 and 75 are cross-sectional views of a principal part of the semiconductor device of the present second embodiment in which a cross-sectional view of a line D1-D1 in FIG. 73 almost corresponds to FIG. 74, and a cross-sectional view of a line D2-D2 in FIG. 73 almost corresponds to FIG. 75. Note that the cross-sectional views of FIGS. 74 and 75 illustrate the insulating film IL3 simply as the insulating film IL3 without dividing it into the above-described insulating film IL4 and the above-described insulating film IL5 for simplification. However, the insulating film IL3 can be also as the same laminated film as that of the above-described first embodiment.

Since the manufacturing processes of the semiconductor device of the present second embodiment are the same as those of the above-described first embodiment, repetitive descriptions will be omitted here. In addition, the present second embodiment is the same as the above-described first embodiment in the configurations of the memory formation region 1A, the metal gate transistor formation region 1B, and the low breakdown voltage MISFET formation region 1C, and therefore, the illustration and description thereof are omitted here, and only the high breakdown voltage MISFET formation region 1D will be illustrated and described.

Also in the present second embodiment, the configuration of the MISFET Q3 in the high breakdown voltage MISFET formation region 1D is basically the same as that of the above-described first embodiment.

That is, as illustrated in FIGS. 73 to 75, the semiconductor substrate SB in the high breakdown voltage MISFET formation region 1D has the active region AC defined by the element isolation region ST, the p-type well PW4 is formed in the active region AC. And, the gate electrode GE2 is formed on the semiconductor substrate SB. In a planar view, the gate electrode GE2 has a part which overlaps with the active region AC and a part which does not overlap therewith, and the active region AC has a part which overlaps with the gate electrode GE2 and a part which does not overlap therewith. In the case of FIG. 73, the gate electrode GE2 is formed so as to bridge between two active regions AC in the planar view. The insulating film GI2 which is functioned as the gate insulating film is interposed between the gate electrode GE2 and the active region AC (p-type well PW4). In addition, in the active region AC (p-type well PW4), the n⁻-type semiconductor region EX5 and n⁺-type semiconductor region SD5 forming the source/drain region with the LDD structure are formed. On the n⁺-type semiconductor region SD5, the metal silicide layer SL is formed.

The gate electrode GE2 is in a state that the gate electrode GE2 is embedded into the insulating film IL3 via the sidewall spacer SW, and the insulating film IL6 is formed on the insulating film IL3 including on the gate electrode GE2. The insulating film IL7 is formed on the insulating film IL6, and the wiring M1 is embedded into the wiring trench of the insulating film IL7. The contact hole CT which penetrates through the insulating film IL6 and the insulating film IL3 is formed on the n⁺-type semiconductor region SD5, the plug PG is embedded into this contact hole CT, and the n⁺-type semiconductor region SD5 is electrically connected with the wiring M1 via this plug PG. In addition, the contact hole CT (CT1) which penetrates through the insulating film IL6 is formed on the gate electrode GE2, the plug PG is embedded into this contact hole CT (CT1), and the gate electrode GE2 is electrically connected with the wiring M1 via this plug PG. The contact hole CT formed on the gate electrode GE2 is assumed to be referred to as a contact hole CT1 with denoting a symbol CT1. Therefore, the contact hole CT1 is formed on the gate electrode GE2, and can be described as the contact hole CT in which the plug PG used for the connection with the gate electrode GE2 is embedded.

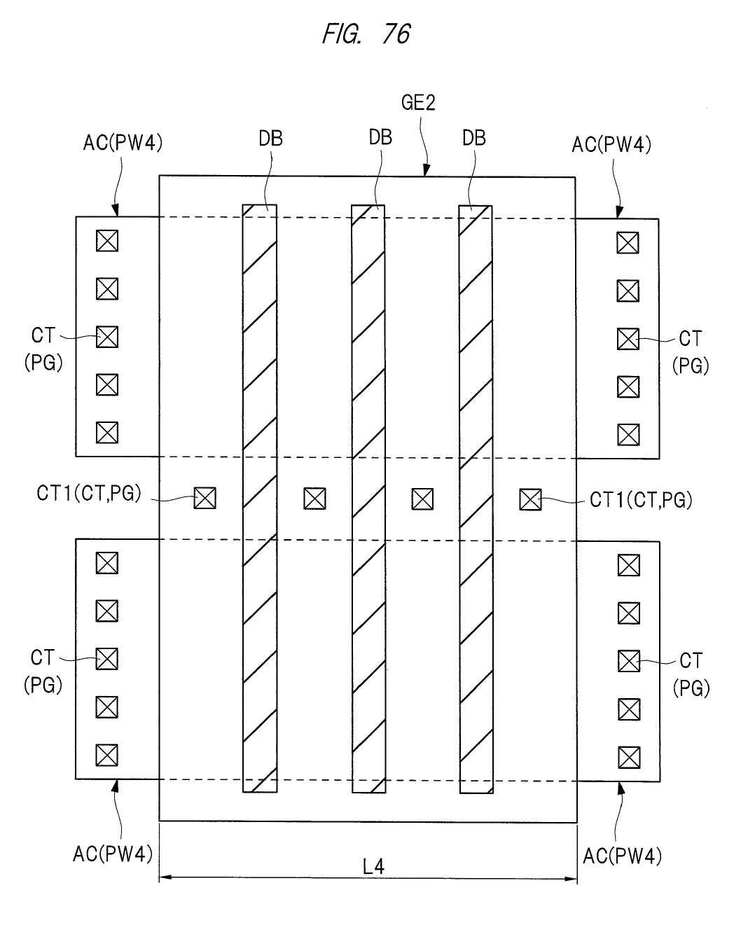

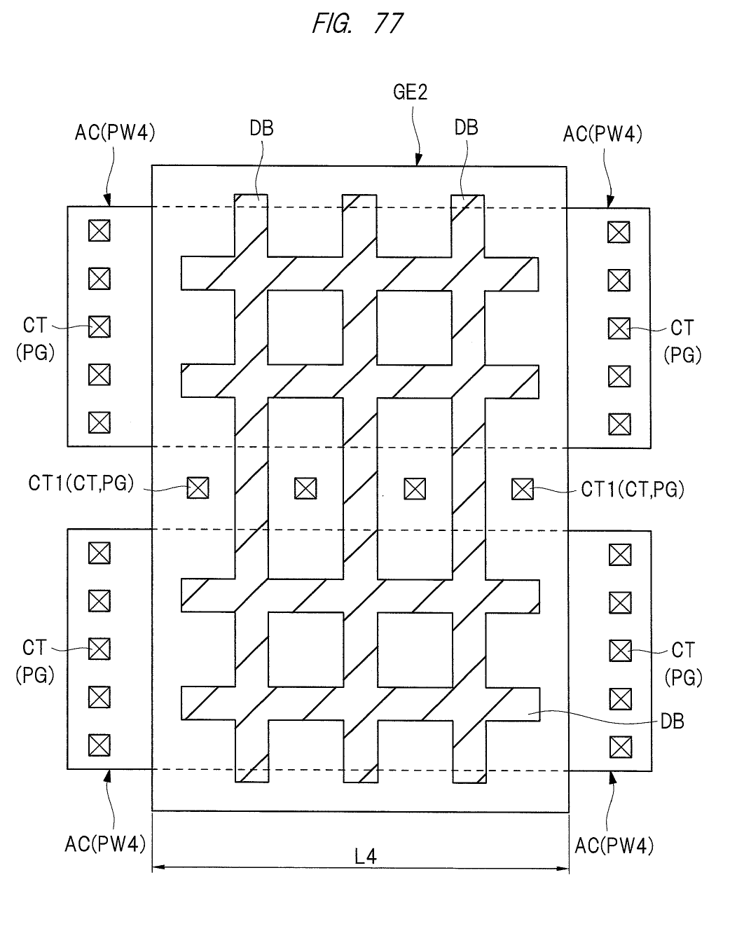

FIGS. 76 and 77 are plan views of a principal part in the manufacturing process of the semiconductor device of the present second embodiment, and illustrate the same plane region as that of FIG. 73. However, FIGS. 76 and 77 illustrate a stage of formation of the insulating film DB in the above-described Step S18. Although the contact hole CT and the plug PG have not been formed yet at the stage of formation of the insulating film DB in Step S18, FIGS. 76 and 77 also illustrate the contact hole CT and the plug PG to be formed later for easily understanding. In addition, while FIGS. 76 and 77 are plan views, hatching is added to the insulating film DB for easily understanding. Note that the patterns (planar shapes) of the insulating film DB formed on the gate electrode GE2 are different between FIG. 76 and FIG. 77.

As described in the above-described first embodiment, in the above-described Step S18, the insulating film DB is not formed so as to cover the whole gate electrode GE2, but is formed partially on the gate electrode GE2 in a planar view. That is, the gate electrode GE2 has a part covered by the insulating film DE and a part not covered by the insulating film DB in the planar view. That is, when the insulating film DB is formed in Step S18, the gate electrode GE2 has a part where the insulating film DB is formed and a part where the insulating film DB is not formed. In other words, when the insulating film DB is formed in Step S18, the gate electrode GE2 has a part positioned immediately below the insulating film DB and a part not positioned immediately below the insulating film DB. Note that the insulating film DE is formed on the cap insulating film CP4 when the cap insulating film CP4 is formed on the gate electrode GE2.

The specific example of the formation region of the insulating film DB is illustrated in FIG. 76 and FIG. 77. Note that the patterns (planar shapes) of the insulating film DB described below with reference to FIG. 76 and FIG. 77 are patterns (planar shapes) in the planar view. In addition, a gate width is the gate width of the gate electrode GE2 where the insulating film DB is arranged, and a gate length is the gate length of that gate electrode GE2.

First, a case of FIG. 76 will be described. The insulating film DB formed on the gate electrode GE2 in Step S18 can be formed to have, for example, a pattern as illustrated in FIG. 76.

That is, the planar shape of the insulating film DE can be formed as, for example, a linear pattern (planar shape). In that case, a dimension in an extending direction is larger than a dimension in a direction perpendicular to the extending direction. In the case of FIG. 76, the insulating film DB having the linear pattern extends in a gate width direction (gate width direction of the gate electrode GE2). The dimension in the extending direction of the insulating film DB having the linear pattern has a magnitude occupying a part larger than half of the dimension of the gate electrode GE2 (here, dimension thereof in the gate width direction), that is, a magnitude larger than a half of the dimension of the gate electrode GE2 (here, dimension thereof in the gate width direction).

In addition, a plurality of the insulating films DB each having the linear pattern can be also arranged on the gate electrode GE2. In this case, they can be arranged so as to be adjacent to each other in the direction perpendicular to the extending direction of the linear pattern. In the case of FIG. 76, the insulating films DB each having the linear pattern extending in the gate width direction are arranged so as to be adjacent to each other in the gate length direction. That is, in the case of FIG. 76, the insulating film DB having a stripe-shaped pattern is formed on the gate electrode GE2. In addition, three insulating films DB each having the linear pattern are arranged so as to be adjacent to each other in FIG. 76. However, the number of the arrangement can be changed if needed. In addition, when three or more insulating films DB each having the linear pattern are arranged on one gate electrode GE2, intervals among insulating films DB each having the linear pattern are preferably almost equal to each other.

Next, a case of FIG. 77 will be described. The insulating film DB formed on the gate electrode GE2 at Step S18 can be formed to have, for example, a pattern as illustrated in FIG. 77.

That is, the planar shape of the insulating film DB can be as, for example, a lattice-shaped pattern (planar shape). In the case of FIG. 77, the insulating film DB having the lattice-shaped pattern formed by intersection of a plurality of linear patterns extending in the gate width direction of the gate electrode GE2 with a plurality of linear patterns extending in the gate length direction of the gate electrode GE2 is formed on the gate electrode GE2.

As seen in the cases of FIG. 76, and FIG. 77, over the whole upper surface of the gate electrode GE2 in the planar view, it is preferred to almost equally arrange the regions where the insulating film DB is formed and the regions where the insulating film DB is not formed. In addition, in the planar view, a total area of the insulating film DB2 formed on the gate electrode GE2 can be set to be less than a half of an area of the gate electrode GE2.

The pattern of the insulating film DB formed on the gate electrode GE2 can be variously changed. However, it is preferred to devise as follows for a formation position of the contact hole CT1 and a formation position of the insulating film DB.

That is, as commonly seen in both of FIG. 76 and FIG. 77, it is preferred not to overlap the formation position of the insulating film DB in Step S18 with the formation position of the contact hole CT1 in the above-described Step S27 in the planar view. That is, it is preferred not to overlap the formation position of the contact hole CT1 formed on the gate electrode GE2 in the above-described Step S27 with the position where the insulating film DB has been formed in Step S18 in the planar view. That is, it is preferred to form the contact hole CT1 in Step S27 on the gate electrode GE2 in the part which has not been overlapped with the insulating film DB in the planar view when the insulating film DB is formed in Step S18. In this manner, when the contact hole CT1 is formed at Step S27, even when a part of the insulating film DE is left on the gate electrode GE2, the contact hole CT1 is formed at the position which does not overlap the residual part of the insulating film DB, and therefore, adverse influence of the residual part of the insulating film DB on the formation of the contact hole CT1 can be prevented. Therefore, the contact hole CT1 can be formed more exactly on the gate electrode GE2. Therefore, the reliability of the semiconductor device can be improved. In addition, the manufacturing yield of the semiconductor device can be improved.

### Third Embodiment

The present third embodiment will describe a case of formation of the dishing prevention pattern (insulating film DB) and a silicide block film (insulating film DB2) which prevents the metal silicide layer SL from being formed, by the same film in the same process.

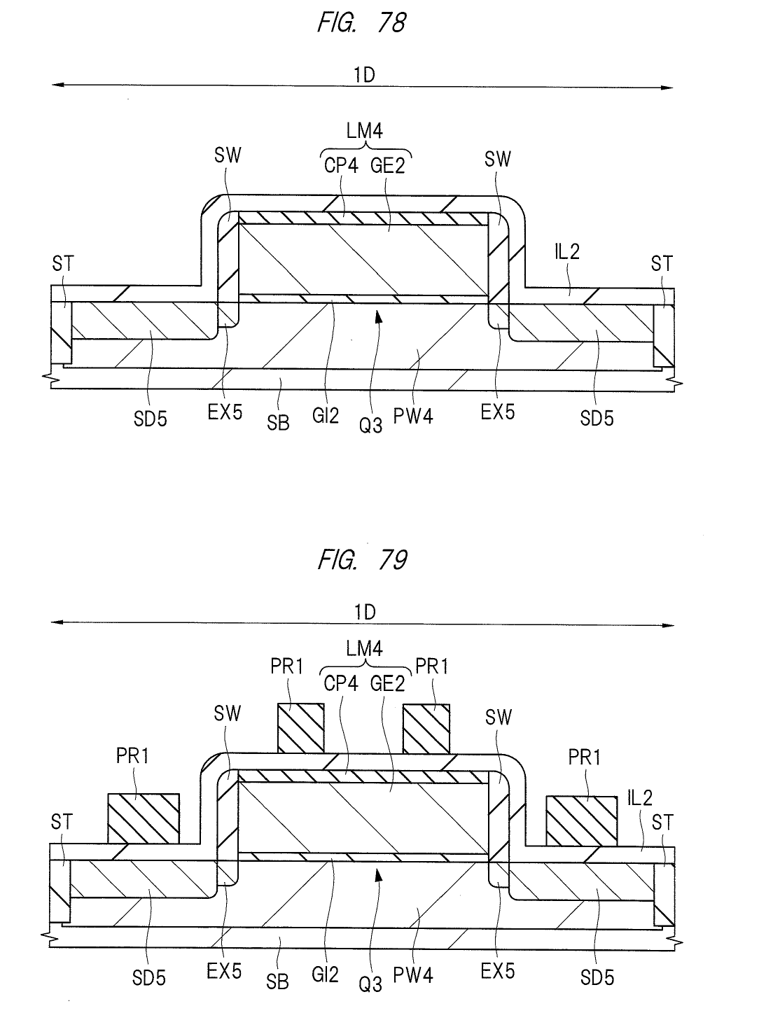

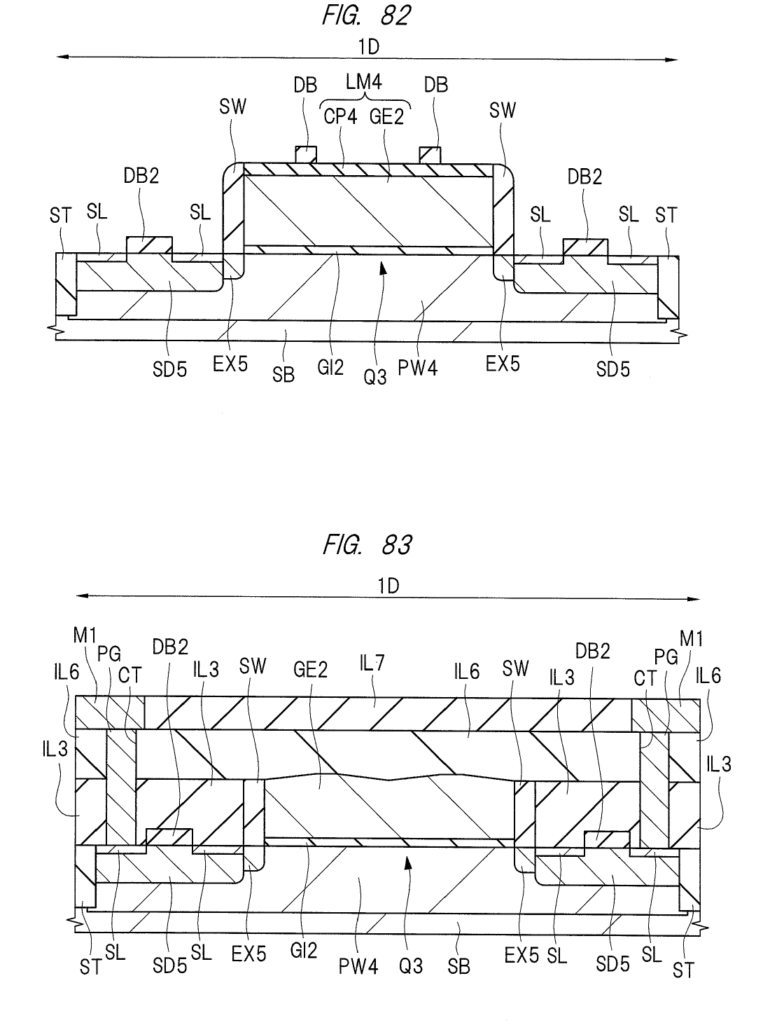

FIGS. 78 to 83 are cross-sectional views of a principal part in a manufacturing process of a semiconductor device of the present third embodiment, each of which illustrates a cross-sectional view of the high breakdown voltage MISFET formation region 1D. Note that the cross-sectional view of FIG. 83 illustrates the insulating film IL3 simply as the insulating film IL3 without dividing it into the above-described insulating film IL4 and the above-described insulating film IL5 for simplification. However, the insulating film IL3 can be also as the same laminated film as that of the above-described first embodiment.

Since the manufacturing processes of the semiconductor device of the present third embodiment except for the formation process of the insulating film DB in Step S18 and the formation process of the metal silicide layer SL in Step S19 are the same as those of the above-described first embodiment, repetitive descriptions will be omitted here. In addition, the present third embodiment is the same as the above-described first embodiment in the manufacturing processes of the memory formation region 1A, the metal gate transistor formation region 1B, and the low breakdown voltage MISFET formation region 1C, and therefore, the illustration and description thereof are omitted here, and only the high breakdown voltage MISFET formation region 1D will be illustrated and described.

Also in the present third embodiment, processes prior to the above-described Step S18 (the formation process of the insulating film DB) are performed. Then, the formation process of the insulating film DB in Step S18 is performed as follows.

That is, first, also in the present third embodiment as similar to the above-described first embodiment, the insulating film IL2 is formed (deposited) on the principal surface (on the whole principal surface) of the semiconductor substrate SB so as to cover the memory gate electrode MG, the laminated bodies LM1, LM2, LM3 and LM4, and the sidewall spacer SW as illustrated in FIG. 78. Then, as illustrated in FIG. 79, the photoresist pattern PR1 is formed on the insulating film IL2 as a resist pattern by using the photolithography method. FIG. 79 is a cross-sectional view of the high breakdown voltage MISFET formation region 1D at a stage of formation of the photoresist pattern PR1, and corresponds to the same process stage as those of the above-described FIGS. 28 and 29.

The present third embodiment is different from the above-described first embodiment in a formation position of the photoresist pattern PR1. That is, in the above-described first embodiment, the photoresist pattern PR1 is formed in the region where the insulating film DB is to be formed in the high breakdown voltage MISFET formation region 1D. On the other hand, in the present third embodiment, the photoresist pattern PR1 is formed in the region where the insulating film DB is to be formed and the region where the insulating film DB2 is to be formed in the high breakdown voltage MISFET formation region 1D. That is, the third embodiment is different from the above-described first embodiment in that the photoresist pattern PR1 is formed also in the region where the insulating film DB2 is to be formed.

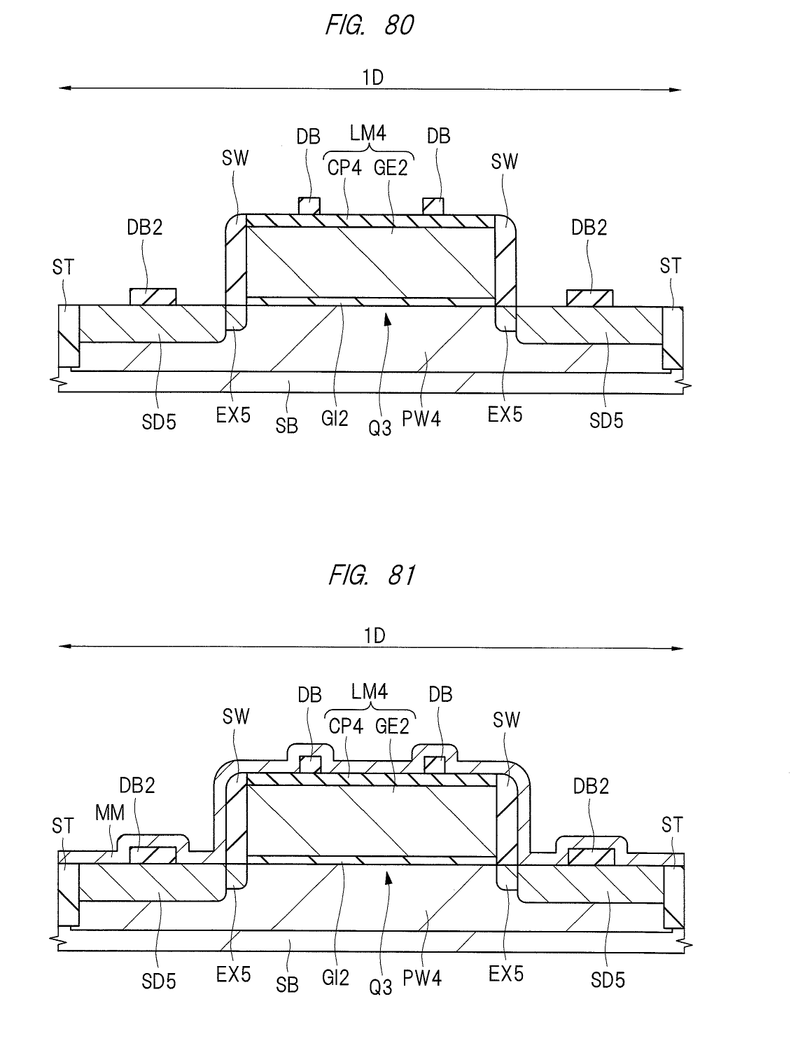

Then, by etching and patterning the insulating film IL2 by using the photoresist pattern PR1 as an etching mask, the insulating film DB made of the patterned insulating film IL2 and the insulating film DB2 made of the patterned insulating film IL2 are formed. Also in the present third embodiment, the etching at this time can be performed as similar to that of the above-described first embodiment except for forming not only the insulating film DB but also the insulating film DB2. After that, the photoresist pattern PR1 is removed. FIG. 80 illustrates this stage. FIG. 80 corresponds to the same process stage as those of the above-described FIGS. 30 and 31. In this manner, in the present third embodiment, the process of forming the insulating film DB in Step S18 is performed.

Also in the present third embodiment, the insulating film DB is formed on the laminated body LM4, and this insulating film DB in the present third embodiment is the same as that of the above-described first embodiment, and therefore, the repetitive description is omitted here.

However, in the present third embodiment, the insulating film DB2 is also formed in Step S18. This insulating film DB2 is functioned as the silicide block film for preventing the formation of the metal silicide layer SL. The present third embodiment and the above-described first embodiment are different from each other in that this insulating film DB2 is formed. In the case of FIG. 80, the insulating film DB2 is partially formed on the n⁺-type semiconductor region SD5 for the source/drain. That is, the insulating film DB2 is formed on not the whole n⁺-type semiconductor region SD5 but a part of the n⁺-type semiconductor region SD5, and the n⁺-type semiconductor region SD5 has a part covered by the insulating film DB2 and a part not covered by the insulating film DB2 in a region not covered by the sidewall spacer SW.

Next, the formation process of the metal silicide layer SL in Step S19 is performed as follows.

That is, as illustrated in FIG. 81, the metal film MM is formed (deposited) on the whole principal surface of the semiconductor substrate SB including on the upper surface (surface) of the n⁺-type semiconductor regions SD1, SD2, SD3, SD4 and SD5 so as to cover the memory gate electrode MG, the laminated bodies LM1, LM2, LM3 and LM4, and the sidewall spacer SW. FIG. 81 corresponds to the same process stage as those of the above-described FIGS. 32 and 33. At this stage, the present third embodiment is different from the above-described first embodiment in that the insulating film DB2 is interposed between the metal film MM and the n⁺-type semiconductor region SD5 since the insulating film DB2 is partially formed on the n⁺-type semiconductor region SD5 in the present third embodiment. That is, in the present third embodiment, while the part not covered by the insulating film DB2 on the upper surface of the n⁺-type semiconductor region SD5 contacts the metal film MM, the part covered by the insulating film DB2 therein does not contact the metal film MM.

Next, by applying the thermal process to the semiconductor substrate SB, each upper layer part (surface layer part) of the n⁺-type semiconductor regions SD1, SD2, SD3, SD4 and SD5 is reacted to the metal film MM. In this manner, as illustrated in FIG. 82, the metal silicide layer SL is formed on each upper part (upper surface, surface, upper layer part) of the n⁺-type semiconductor regions SD1, SD2, SD3, SD4 and SD5. After that, the unreacted metal film MM is removed by the wet etching or others. FIG. 82 illustrates the cross-sectional view at this stage. FIG. 82 corresponds to the same process stage as those of the above-described FIGS. 34 and 35. In addition, after removing the unreacted metal film MM, a thermal process can be further performed.

At this stage, the present third embodiment is different from the above-described first embodiment in that, in the present third embodiment, the metal silicide layer SL is formed on not the whole upper surface of the n⁺-type semiconductor region SD5 but only the part not covered by the insulating film DB2 in the upper surface of the n⁺-type semiconductor region SD5 since the insulating film DB2 is partially formed on the n⁺-type semiconductor region SD5. That is, in the present third embodiment, while the metal silicide layer SL is formed on the part not covered by the insulating film DB2 in the upper surfaces of the n⁺-type semiconductor region SD5, the metal silicide layer SL is not formed on the part covered by the insulating film DB2.

The present third embodiment is the same as the above-described first embodiment also in the following processes. That is, the above-described insulating film IL3 is formed in the above-described Step S20, the polishing process of the above-described Step S21 is performed, the above-described dummy gate electrode DG is removed in the above-described Step S22, the above-described insulating film HK is formed in the above-described Step S23, the above-described metal film ME is formed in the above-described Step S24, and the polishing process of the above-described Step S25 is performed. Then, the above-described insulating film IL6 is formed in the above-described Step S26, the above-described contact hole CT is formed in the above-described Step S27, the above-described plug PG is formed in the above-described Step S28, and the above-described insulating film IL7 and the above-described wiring M1 are formed in the above-described Step S29. In this manner, a structure of FIG. 83 is obtained. FIG. 83 corresponds to the same process stage as those of the above-described FIGS. 58 and 59.

In the present third embodiment, when the insulating film DB as the dishing prevention pattern is formed on the laminated body LM4 in Step S18, the insulating film DB2 as the silicide block film for preventing the formation of the metal silicide layer SL is also formed. This insulating film DB2 is formed in a region where the formation of the metal silicide layer SL is desirably prevented when the metal silicide layer SL is formed in Step S19. That is, if there is an exposed part of a silicon region (Si substrate region and polysilicon region) at an immediately prior stage to the formation of the metal film MM, the metal silicide layer SL is adversely formed in the exposed part, and therefore, the insulating film DB2 is to be formed in the exposed part of the silicon region (Si substrate region and polysilicon region) in the region where the metal silicide layer SL is not desirably formed. In this manner, the metal silicide layer SL desirably cannot be formed in the silicon region (Si substrate region and polysilicon region) covered by the insulating film DB2.

For example, as illustrated in FIG. 80, the insulating film DB2 is formed on a part of the n⁺-type semiconductor region SD5 which is the source/drain region. In this manner, when the metal silicide layer SL is formed in Step S19, the metal silicide layer SL desirably cannot be formed in the n⁺-type semiconductor region SD5 of the part where the insulating film DB2 has been formed (that is, in the part of the n⁺-type semiconductor region D5 covered by the insulating film DB2) as illustrated in FIG. 82.

By forming the insulating film DB2 is formed on the part of the n⁺-type semiconductor region SD5 which is the source/drain region of the MISFET Q3 for the high breakdown voltage but not forming the metal silicide layer SL on the n⁺-type semiconductor region SD5 of the part where the insulating film DB2 has been formed by that formation of the insulating film DB2, the breakdown voltage of the MISFET Q3 can be improved.

That is, when the metal silicide layer SL is formed on the whole n⁺-type semiconductor region SD5, the n⁻-type semiconductor region EX5 adjacent to the n⁺-type semiconductor region SD5 and the plug PG (hereinafter, referred to as plug PG on the n⁺-type semiconductor region SD5) embedded into the contact hole CT formed on the n⁺-type semiconductor region SD5 are electrically connected with each other via the metal silicide layer SL at a low resistance. However, in order to increase the breakdown voltage of the MISFET Q3, it may be better in some cases to secure a resistance between the n⁻-type semiconductor region EX5 adjacent to the n⁺-type semiconductor region SD5 and the plug PG on the n⁺-type semiconductor region SD5 to some extent. Therefore, according to the application of the present third embodiment, by forming the metal silicide layer SL on not the whole n⁺-type semiconductor region SD5 but only partially the n⁺-type semiconductor region SD5, the resistance between the n⁻-type semiconductor region EX5 adjacent to the n⁺-type semiconductor region SD5 and the plug PG on the n⁺-type semiconductor region SD5 can be secured to some extent, so that the breakdown voltage of the MISFET Q3 can be improved.

In addition, as illustrated in FIG. 83, it is preferred to form the metal silicide layer SL at a position where the contact hole CT is to be formed in the upper surface of the n⁺-type semiconductor region SD5 by not forming the insulating film DB2 in a region where the contact hole CT to be formed. In this manner, the plug PG on the n⁺-type semiconductor region SD5 can contact the metal silicide layer SL formed on the upper surface of the n⁺-type semiconductor region SD5. And, in viewing in the gate length direction of the gate electrode GE2, it is preferred to provide a region where the formation of the metal silicide layer SL is prevented, by forming the insulating film DB2 between the n⁻-type semiconductor region EX5 and the metal silicide layer SL to which the plug PG on the n+ semiconductor region SD5 is connected.

In addition, in the present third embodiment, the insulating film DB as the dishing prevention pattern and the insulating film DB2 as the silicide block film are also formed by using the common insulating film IL2. Therefore, the number of manufacturing processes of the semiconductor device can be reduced.

In the foregoing, the invention made by the present inventors has been concretely described based on the embodiments. However, it is needless to say that the present invention is not limited to the foregoing embodiments and various modifications and alterations can be made within the scope of the present invention.

What is claimed is:

1. A method of manufacturing a semiconductor device, comprising the steps of:
(a) preparing a semiconductor substrate;
(b) forming a first gate electrode for a first MISFET and a dummy gate electrode for a second MISFET on the semiconductor substrate;
(c) partially forming a first film on the first gate electrode;
(d) forming an insulating film on the semiconductor substrate so as to cover the first gate electrode, the dummy gate electrode and the first film;
(e) exposing the dummy gate electrode by polishing the insulating film;
(f) after the step of (e), removing the dummy gate electrode;
(g) forming a conductive film on the insulating film so as to fill a trench which is a region where the dummy gate electrode has been removed in the step of (f); and
(h) forming a second gate electrode for the second MISFET by polishing the conductive film so as to remove the conductive film outside the trench and leaving the conductive film inside the trench,
wherein, in the step of (e), the insulating film is polished under a condition that a polishing speed of the first film is smaller than a polishing speed of the insulating film.

2. The method of manufacturing the semiconductor device according to claim 1,
wherein a dimension of the first gate electrode in a gate length direction is larger than a dimension of the dummy gate electrode in a gate length direction.

3. The method of manufacturing the semiconductor device according to claim 2,
wherein an area of the first gate electrode is larger than an area of the dummy gate electrode.

4. The method of manufacturing the semiconductor device according to claim 3,
wherein the second gate electrode is a metal gate electrode.

5. The method of manufacturing the semiconductor device according to claim 4,
wherein, in the step of (c), the first film is not formed on the dummy gate electrode.

6. The method of manufacturing the semiconductor device according to claim 1,
wherein, in the step of (f), the first gate electrode is not removed.

7. The method of manufacturing the semiconductor device according to claim 1,
wherein the first gate electrode and the dummy gate electrode are formed of a silicon film in the same layer.

8. The method of manufacturing the semiconductor device according to claim 1,
wherein the first film is made of an insulating material.

9. The method of manufacturing the semiconductor device according to claim 1 further comprising, after the step of (f) and before the step of (g), the step of
(f1) forming a high dielectric constant insulating film on the insulating film including on a bottom part of the trench and a sidewall of the trench,
wherein, in the step of (g), the conductive film is formed on the high dielectric constant insulating film so as to fill the trench, and,
in the step of (h), by polishing the conductive film and the high dielectric constant insulating film, the conductive film and the high dielectric constant insulating film outside the trench are removed, and the conductive film and the high dielectric constant insulating film inside the trench are left.

10. The method of manufacturing the semiconductor device according to claim 1,
wherein the insulating film formed in the step of (d) is formed of a laminated film including a silicon nitride film and a silicon oxide film on the silicon nitride film, and,
in the step of (e), the insulting film is polished under a condition that the first film is more difficult to be polished than the silicon oxide film.

11. The method of manufacturing the semiconductor device according to claim 10,
wherein the first film formed in the step of (c) is made of silicon nitride, and,
in the step of (e), the insulting film is polished under a condition that the silicon nitride is more difficult to be polished than silicon oxide.

12. The method of manufacturing the semiconductor device according to claim 1,
wherein, in the step of (b), a first laminated body including the first gate electrode and a first cap insulating film on the first gate electrode, and a second laminated body including the dummy gate electrode and a second cap insulating film on the dummy gate electrode, are formed on the semiconductor substrate,
in the step of (c), the first film is partially formed on the first laminated body,
in the step of (d), the insulating film is formed on the semiconductor substrate so as to cover the first laminated body, the second laminated body and the first film, and,
in the step of (e), the dummy gate electrode is exposed by polishing the insulating film and the second cap insulating film.

13. The method of manufacturing the semiconductor device according to claim 1,
wherein, in the step of (b), a third gate electrode for a third MISFET is also formed on the semiconductor substrate,
in the step of (c), the first film is not formed on the first gate electrode and the third gate electrode,
in the step of (d), the insulating film is formed on the semiconductor substrate so as to cover the first gate electrode, the dummy gate electrode, the third gate electrode and the first film, and
a dimension of the third gate electrode in a gate length direction is smaller than a dimension of the first gate electrode in a gate length direction.

14. The method of manufacturing the semiconductor device according to claim 13,
wherein the first gate electrode, the dummy gate electrode and the third gate electrode are formed of a silicon film in the same layer, and,
in the step of (e), the third gate electrode is also exposed.

15. The method of manufacturing the semiconductor device according to claim 1, further comprising, after the step of (b) and before the step of (c), the step of:
(b1) forming a first source/drain region for the first MISFET and a second source/drain region for the second MISFET on the semiconductor substrate.

16. The method of manufacturing the semiconductor device according to claim 15, further comprising, after the step of (c) and before the step of (d), the step of:
(c1) forming a metal silicide layer on the first source/drain region and the second source/drain region.

17. The method of manufacturing the semiconductor device according to claim 16,
wherein, in the step of (c), the first film is also formed on a part of the second source/drain region, and,
in the step of (c1), the metal silicide layer is not formed on the second source/drain region of a part where the first film is formed.
